(19) United States
(12) Patent Application Publication
(10) Pub. No.: US 2023/0232703 A1
(43) Pub. Date: Jul. 20, 2023

(54) LIGHT EMITTING ELEMENT AND ORGANOMETALLIC COMPOUND FOR THE SAME

(71) Applicant: Samsung Display Co., Ltd., Yongin-si (KR)

(72) Inventors: YOONKYOO LEE, Seoul (KR); JIN-WON SUN, Seoul (KR); CHANGWOONG CHU, Hwaseong-si (KR)

(21) Appl. No.: 17/976,605

(22) Filed: Oct. 28, 2022

(30) Foreign Application Priority Data
Jan. 20, 2022 (KR) 10-2022-0008400

(51) Int. Cl. H01L 51/00; C09K 11/06; C07F 15/00

(52) U.S. Cl. CPC H01L 51/0087; C09K 11/06; H01L 51/0072; H01L 51/0067; C07F 15/0086; H01L 51/0073; H01L 51/0094; H01L 51/5012

(57) ABSTRACT

A light emitting element that includes a first electrode, a second electrode on the first electrode, and an emission layer between the first electrode and the second electrode is provided. The emission layer includes an organometallic compound represented by Formula 1. The light emitting element exhibits long lifespan properties.

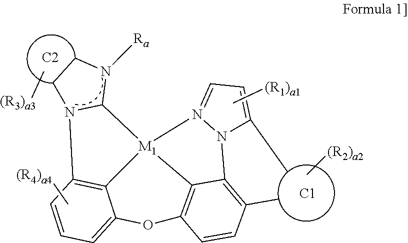

### CROSS-REFERENCE TO RELATED APPLICATION

This application claims priority to and the benefit of Korean Patent Application No. 10-2022-0008400, filed on Jan. 20, 2022, the entire content of which is hereby incorporated by reference.

### BACKGROUND

### 1. Field

Aspects of one or more embodiments of the present disclosure relate to a light emitting element and an organometallic compound utilized for the same.

### 2. Description of the Related Art

As image display devices, organic electroluminescence display devices and/or the like have been recently actively developed. The organic electroluminescence display devices and/or the like are display devices including self-luminescence light emitting elements in which holes and electrons injected from a first electrode and a second electrode recombine in an emission layer, and thus a luminescent material in the emission layer emits light to accomplish display (e.g., to display an image).

For application of light emitting elements in display devices, there is a desired, demand and requirement for both a high efficiency and a long lifespan, and the development of materials, for light emitting elements, capable of stably attaining such characteristics is being continuously researched (e.g., sought).

### SUMMARY

An aspect of one or more embodiments of the present disclosure is directed toward a light emitting element with an improved lifespan.

An aspect of one or more embodiments of the present disclosure is directed toward an organometallic compound, which is a material for a light emitting element having long lifespan properties.

Additional aspects will be set forth in part in the description which follows and, in part, will be apparent from the description, or may be learned by practice of the presented embodiments of the disclosure.

An embodiment of the present disclosure provides a light emitting element including a first electrode, a second electrode on the first electrode, and an emission layer between the first electrode and the second electrode and including an organometallic compound represented by Formula 1.

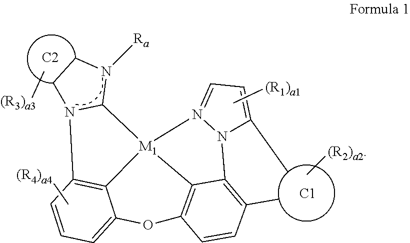

In Formula 1, M₁ may be Pt or Pd, Rₐ may be a substituted or unsubstituted aryl group having 6 to 30 ring-forming carbon atoms, C1 ring group and C2 ring group may each independently be a substituted or unsubstituted aryl group having 6 to 30 ring-forming carbon atoms, a1 may be an integer from 0 to 2, a2 and a3 may each independently be an integer from 0 to 4, a4 may be an integer from 0 to 3, and R₁ to R₄ may each independently be a hydrogen atom, a deuterium atom, a substituted or unsubstituted alkyl group having 1 to 20 carbons, a substituted or unsubstituted aryl group having 6 to 30 ring-forming carbon atoms, or a substituted or unsubstituted heteroaryl group having 2 to 30 ring-forming carbon atoms, and/or form a ring by being coupled to an adjacent group, wherein R₁ and R₂ are coupled to each other to form a ring.

In an embodiment, Formula 1 may be represented by Formula 1-1.

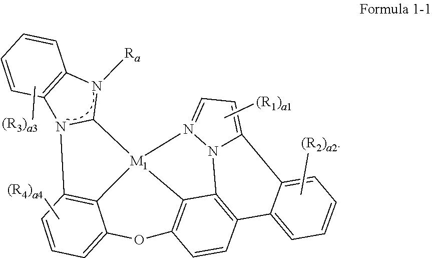

In Formula 1-1, M₁, a1 to a4, R₁ to R₄, and Rₐ may each independently be the same as defined in Formula 1.

In an embodiment, Formula 1-1 may be represented by Formula 1-1A.

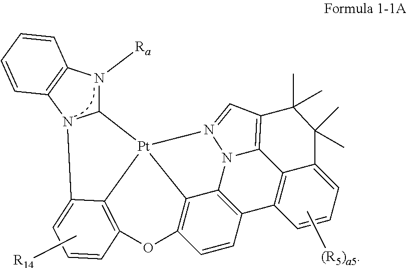

In Formula 1-1A, a5 may be an integer from 0 to 3, R₅ may be a hydrogen atom, a deuterium atom, a substituted or unsubstituted alkyl group having 1 to 30 carbons, a substituted or unsubstituted aryl group having 6 to 30 ring-forming carbon atoms, or a substituted or unsubstituted heteroaryl group having 2 to 30 ring-forming carbon atoms, R₁₄ may be a hydrogen atom, a deuterium atom, or a substituted or unsubstituted alkyl group having 1 to 10 carbon atoms, and Rₐ may be the same as defined in Formula 1-1.

In an embodiment, in Formula 1-1A, R₅ may be represented by any one selected from among R5-1 to R5-3.

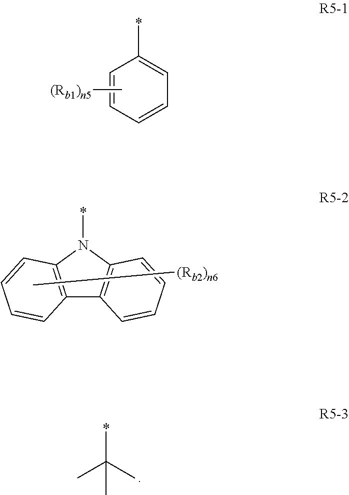

In R5-1, n5 may be an integer from 0 to 5, in R5-2, n6 may be an integer from 0 to 8, and in R5-1 to R5-2, R_{b1} and R_{b2} may each independently be a hydrogen atom, a deuterium atom, a substituted or unsubstituted alkyl group having 1 to 30 carbon atoms, or a substituted or unsubstituted aryl group having 6 to 30 ring-forming carbon atoms.

In an embodiment, in Formula 1, R₃ and R₄ may be coupled to each other to form a ring.

In an embodiment, in Formula 1, Rₐ may be represented by Formula RAA.

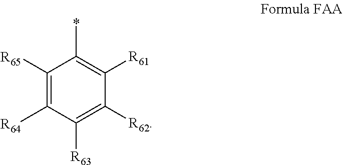

In Formula RAA, R₆₁ to R₆₅ may each independently be a hydrogen atom, a deuterium atom, a substituted or unsubstituted methyl group, a substituted or unsubstituted t-butyl group, or a substituted or unsubstituted phenyl group.

In an embodiment, the emission layer may emit phosphorescent light.

In an embodiment, the emission layer may include a hole transporting host, an electron transporting host, and a dopant, wherein the dopant may include the organometallic compound.

In an embodiment, the emission layer may further include a thermally activated delayed fluorescence compound.

In an embodiment, the hole transporting host may include a compound represented by Formula T-1.

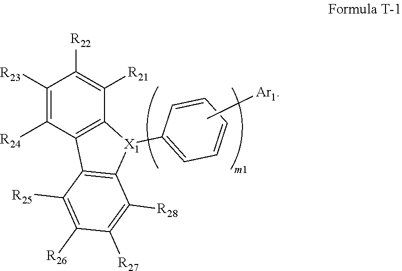

In Formula T-1, X₁ may be CR₂₉ or N, m1 may be an integer from 0 to 2, R₂₁ to R₂₉ may each independently be a hydrogen atom, a deuterium atom, a substituted or unsubstituted aryl group having 6 to 60 ring-forming carbon atoms, or a substituted or unsubstituted heteroaryl group not including N as a ring-forming atom and having 2 to 60 ring-forming carbon atoms, and Ar₁ may be a substituted or unsubstituted aryl group having 6 to 60 ring-forming carbon atoms, or a substituted or unsubstituted heteroaryl group including N as a ring-forming atom and having 2 to 60 ring-forming carbon atoms.

In an embodiment, the electron transporting host may include a compound represented by Formula T-2.

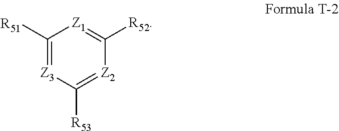

In Formula T-2, Z₁ to Z₃ may each independently be CR₂₉ or N, R₅₁ to R₅₄ may each independently be a hydrogen atom, a deuterium atom, a cyano group, a substituted silyl group, a substituted or unsubstituted aryl group having 6 to 30 ring-forming carbon atoms, or a substituted or unsubstituted heteroaryl group having 2 to 30 ring-forming carbon atoms, and/or form a ring by being coupled to an adjacent group.

In an embodiment of the present disclosure, an organometallic compound represented by Formula 1 is provided.

### BRIEF DESCRIPTION OF THE DRAWINGS

The accompanying drawings are included to provide a further understanding of the present disclosure, and are incorporated in and constitute a part of this disclosure. The drawings illustrate example embodiments of the present disclosure and, together with the description, serve to explain (assist in the understanding) principles of the present disclosure. In the drawings:

FIG. 1 is a plan view showing a display device according to an embodiment;

FIG. 2 is a cross-sectional view showing a portion corresponding to line I-I′ of FIG. 1;

FIG. 3 is a cross-sectional view schematically showing a light emitting element of an embodiment;

FIG. 4 is a cross-sectional view schematically showing a light emitting element of an embodiment;

FIG. 5 is a cross-sectional view schematically showing a light emitting element of an embodiment;

FIG. 6 is a cross-sectional view schematically showing a light emitting element of an embodiment;

FIG. 7 is a cross-sectional view showing a display device according to an embodiment;

FIG. 8 is a cross-sectional view showing a display device according to an embodiment;

FIG. 9 is a cross-sectional view showing a display device according to an embodiment; and

FIG. 10 is a cross-sectional view showing a display device according to an embodiment.

### DETAILED DESCRIPTION

The present disclosure may be modified in many suitable alternate forms, and specific embodiments will be exemplified in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

In the present disclosure, when an element (or a region, a layer, a portion, etc.) is referred to as being “on,” “connected to,” or “coupled to” another element, it refers to the element that may be directly on/connected to/coupled to the other element, or that a third element may be disposed therebetween.

Like reference numerals refer to like elements. Also, in the drawings, the thickness, the ratio, and the dimensions of elements may be exaggerated for an effective description of technical contents. The term “and/or” includes any and all combinations of one or more of which associated elements may define.

It will be understood that, although the terms “first,” “second,” etc. may be utilized herein to describe one or more suitable elements, these elements should not be limited by these terms. These terms are only utilized to distinguish one element from another. For example, a first element may be referred to as a second element, and a second element may also be referred to as a first element in a similar manner without departing the scope of rights of the present disclosure. The terms of a singular form may include plural forms unless the context clearly indicates otherwise.

In some embodiments, terms such as “below,” “lower,” “above,” “upper,” and/or the like are utilized to describe the relationship of the elements shown in the drawings. The terms are utilized as a relative concept and are described with reference to the direction indicated in the drawings.

It should be understood that the term “comprise,” “include,” or “have” is intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) utilized herein have the same meaning as commonly understood by one of ordinary skill in the art to which the present disclosure pertains. It is also to be understood that terms such as terms defined in commonly utilized dictionaries should be interpreted as having meanings consistent with the meanings in the context of the related art, and should not be interpreted in too ideal a sense or an overly formal sense unless explicitly defined herein.

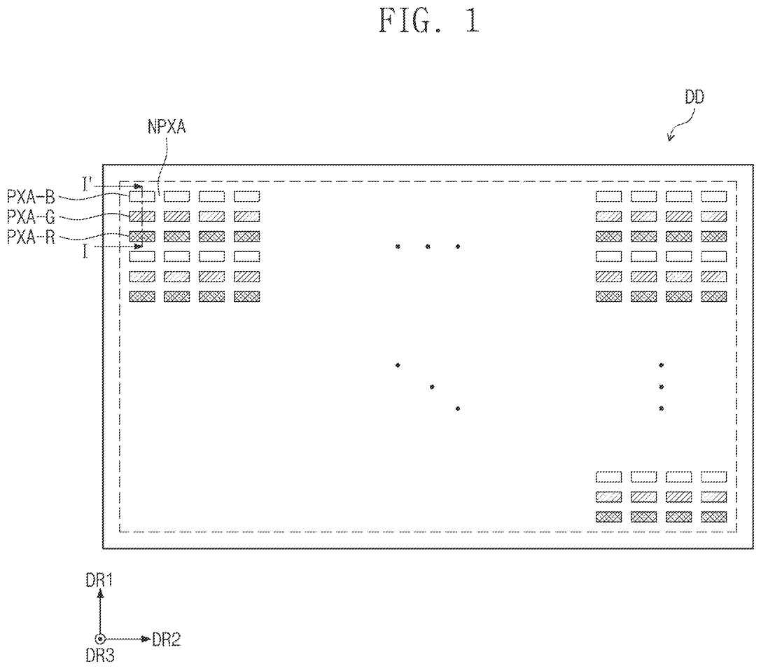

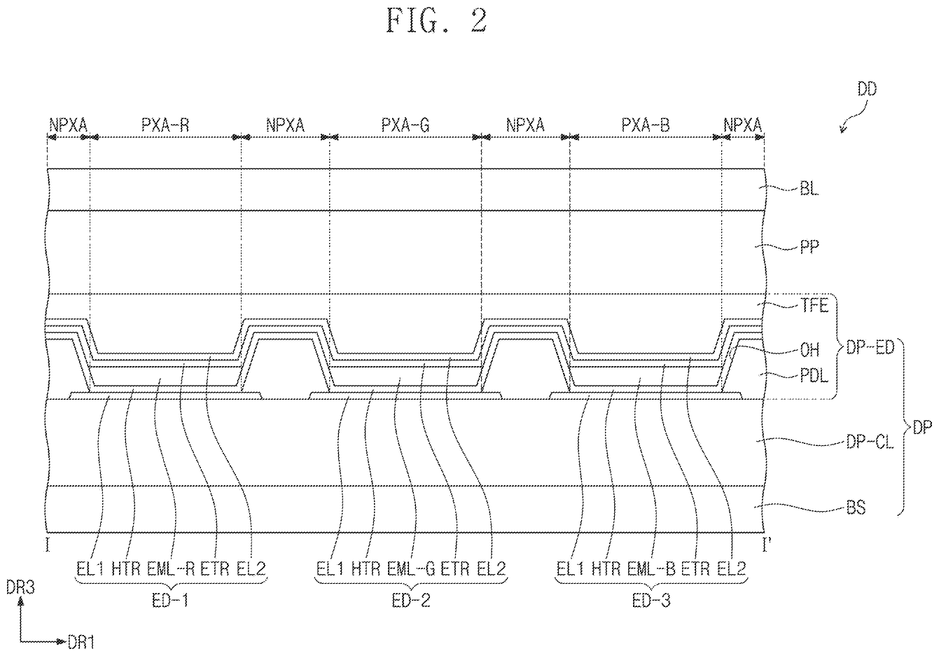

Hereinafter, with reference to the accompanying drawings, embodiments of the present disclosure will be described in more detail. FIG. 1 is a plan view showing an embodiment of a display device DD. FIG. 2 is a cross-sectional view of the display device DD of an embodiment. FIG. 2 is a cross-sectional view showing a portion corresponding to line I-I′ of FIG. 1.

The display device DD may include a display panel DP and an optical layer PP on the display panel DP. The display panel DP may include light emitting elements ED-1, ED-2, and ED-3. The display device DD may include a plurality of the light emitting elements ED-1, ED-2, and ED-3. The optical layer PP may be on the display panel DP to control reflective light in the display panel DP caused by external light. The optical layer PP may include, for example, a polarizing layer or a color filter layer. The optical layer PP may not be provided in the display device DD of an embodiment.

On the optical layer PP, a base substrate BL may be disposed. The base substrate BL may be a member which provides a base surface on which the optical layer PP is disposed. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In some embodiments, the base substrate BL may not be provided.

The display device DD according to an embodiment may further include a filling layer. The filling layer may be between a display element layer DP-ED and the base substrate BL. The filling layer may be an organic material layer. The filling layer may include at least one of an acrylic resin, a silicone-based resin, or an epoxy resin.

The display panel DP may include a base layer BS, a circuit layer DP-CL provided on the base layer BS, and the display element layer DP-ED. The display element layer DP-ED may include a pixel definition film PDL, the light emitting elements ED-1, ED-2, and ED-3 disposed between the pixel definition film PDL, and an encapsulation layer TFE on the light emitting elements ED-1, ED-2, and ED-3.

The base layer BS may be a member which provides a base surface on which the display element layer DP-ED is disposed. The base layer BS may be a glass substrate, a metal substrate, a plastic substrate, and/or the like. However, the embodiment of the present disclosure is not limited thereto, and the base layer BS may be an inorganic layer, an organic layer, or a composite material layer.

In an embodiment, the circuit layer DP-CL is on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display element layer DP-ED.

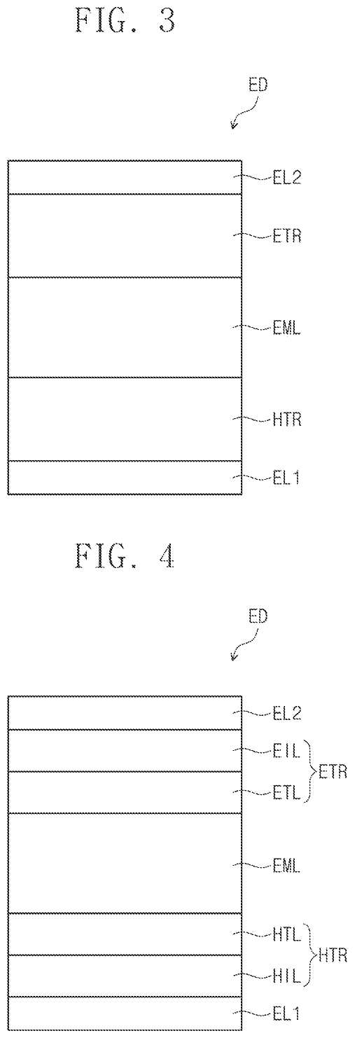

Each of the light emitting elements ED-1, ED-2, and ED-3 may have a structure of a light emitting element ED of an embodiment in accordance with FIG. 3 to FIG. 6 to be described in more detail. Each of the light emitting elements ED-1, ED-2, and ED-3 may include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed inside an opening OH defined on the pixel definition film PDL, and the hole transport region HTR, the electron transport region ETR, and the second electrode EL2 are provided as a common layer throughout the light emitting elements ED-1, ED-2, and ED-3. However, the embodiment of the present disclosure is not limited thereto. In an embodiment, the hole transport region HTR and the electron transport region ETR may be patterned and provided inside the opening OH defined on the pixel definition film PDL. For example, in an embodiment, the hole transport region HTR, the emission layers EML-R, EML-G, and EML-B, the electron transport region ETR, and/or the like of the light emitting elements ED-1, ED-2, and ED-3 may be patterned and provided by an ink-jet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be a single layer or a plurality of layers stacked. The encapsulation layer TFE may include at least one insulation layer. The encapsulation layer TFE according to an embodiment may include at least one inorganic film (hereinafter, an encapsulation inorganic film). In some embodiments, the encapsulation layer TFE may include at least one organic film (hereinafter, an encapsulation organic film) and at least one encapsulation inorganic film.

The encapsulation inorganic film may protect (reduce contact with moisture/oxygen) the display element layer DP-ED from moisture/oxygen, and the encapsulation organic film may protect (reduce contact with foreign materials) the display element layer DP-ED from foreign materials such as dust particles. The encapsulation inorganic film may include silicon nitride, silicon oxynitride, silicon oxide, titanium oxide, aluminum oxide, and/or the like, but is not limited thereto. The encapsulation organic film may include an acrylic compound, an epoxy-based compound, and/or the like. The encapsulation organic film may include a photopolymerizable organic material, but is not limited thereto.

The encapsulation layer TFE may be on the second electrode EL2, and may be disposed while filling the opening portion OH.

Referring to FIG. 1 and FIG. 2, the display device DD may include a non-light emitting region NPXA and light emitting regions PXA-R, PXA-G, and PXA-B. Each of the light emitting regions PXA-R, PXA-G, and PXA-B may be a region in which light generated from each of the light emitting elements ED-1, ED-2, and ED-3 is emitted. The light emitting regions PXA-R, PXA-G, and PXA-B may be spaced apart from each other (separated from each other) on a plane (e.g., in a plan view).

Each of the light emitting regions PXA-R, PXA-G, and PXA-B may be a region separated by the pixel definition film PDL. The non-light emitting regions NPXA are regions between adjacent light emitting regions PXA-R, PXA-G, and PXA-B, and may be regions corresponding to the pixel definition film PDL. In the present disclosure, each of the light emitting regions PXA-R, PXA-G, and PXA-B may correspond to a pixel. The pixel definition film PDL may separate the light emitting elements ED-1, ED-2, and ED-3. The emission layers EML-R, EML-G, and EML-B of the light emitting elements ED-1, ED-2, and ED-3 may be disposed in the opening OH defined on the pixel definition film PDL and separated.

The light emitting regions PXA-R, PXA-G, and PXA-B may be separated into a plurality of groups according to the color of light generated from the light emitting elements ED-1, ED-2, and ED-3. In the display device DD of an embodiment illustrated in FIG. 1 and FIG. 2, three light emitting regions PXA-R, PXA-G, and PXA-B which respectively emit red light, green light, and blue light are illustrated. For example, the display device DD of an embodiment may include a red light emitting region PXA-R, a green light emitting region PXA-G, and a blue light emitting region PXA-B separated from each other.

In the display device DD according to an embodiment, the plurality of light emitting elements ED-1, ED-2, and ED-3 may emit light of different wavelength regions. For example, in an embodiment, the display device DD may include a first light emitting element ED-1 which emits red light, a second light emitting element ED-2 which emits green light, and a third light emitting element ED-3 which emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, the embodiment of the present disclosure is not limited thereto. The first to third light emitting elements ED-1, ED-2, and ED-3 may emit light of the same wavelength region, or at least one thereof may emit light of a different wavelength region. For example, the first to third light emitting elements ED-1, ED-2, and ED-3 may all emit blue light (e.g., may each emit light in the blue wavelength range).

In the display device DD according to an embodiment, the light emitting regions PXA-R, PXA-G, and PXA-B may be arranged in a stripe shape. Referring to FIG. 1, a plurality of red light emitting regions PXA-R may be aligned with each other along the second direction axis DR2, a plurality of green light emitting regions PXA-G may be aligned with each along the second direction axis DR2, and a plurality of blue light emitting regions PXA-B may be aligned with each other along the second direction axis DR2. In some embodiments, the red light emitting region PXA-R, the green light emitting region PXA-G, and the blue light emitting region PXA-B may be alternately arranged in the order of the red light emitting region PXA-R, the green light emitting region PXA-G, and the blue light emitting region PXA-B along the first direction axis DR1. (DR3 is a third direction which is normal or perpendicular to the plane defined by the first direction DR1 and the second direction DR2).

FIG. 1 and FIG. 2 illustrate that areas of the light emitting regions PXA-R, PXA-G, and PXA-B are all substantially similar, but the embodiment of the present disclosure is not limited thereto. The areas of the light emitting regions PXA-R, PXA-G, and PXA-B may be different from each other depending on the wavelength region of emitted light. The areas of the light emitting regions PXA-R, PXA-G, and PXA-B may refer to areas when viewed on a plane defined by the first direction axis DR1 and the second direction axis DR2 (e.g., when viewed in a plan view).

The arrangement type or kind of the light emitting regions PXA-R, PXA-G, and PXA-B is not limited to what is illustrated in FIG. 1. The order in which the red light emitting region PXA-R, the green light emitting region PXA-G, and the blue light emitting region PXA-B are arranged may be provided in one or more suitable combinations depending on the characteristics of display quality required in the display device DD. For example, the arrangement form of the light emitting regions PXA-R, PXA-G, and PXA-B may be a PENTILE® configuration (for example, an RGBG matrix, an RGBG structure, or RGBG matrix structure) or a Diamond Pixel™ configuration (e.g., a display (e.g., an OLED display) containing red, blue, and green (RGB) light emitting regions arranged in the shape of diamonds. PENTILE® is a duly registered trademark of Samsung Display Co., Ltd. Diamond Pixel™ is a trademark of Samsung Display Co., Ltd.

In some embodiments, the areas of the light emitting regions PXA-R, PXA-G, and PXA-B may be different from each other. For example, in an embodiment, the area of the green light emitting region PXA-G may be smaller than the area of the blue light emitting region PXA-B, but the embodiment of the present disclosure is not limited thereto.

Hereinafter, FIG. 3 to FIG. 6 are each a cross-sectional view schematically showing a light emitting element according to an embodiment of the present disclosure. The light emitting element ED according to an embodiment may include a first electrode EL1, a hole transport region HTR, an emission layer EML, an electron transport region ETR, and a second electrode EL2 which are sequentially stacked.

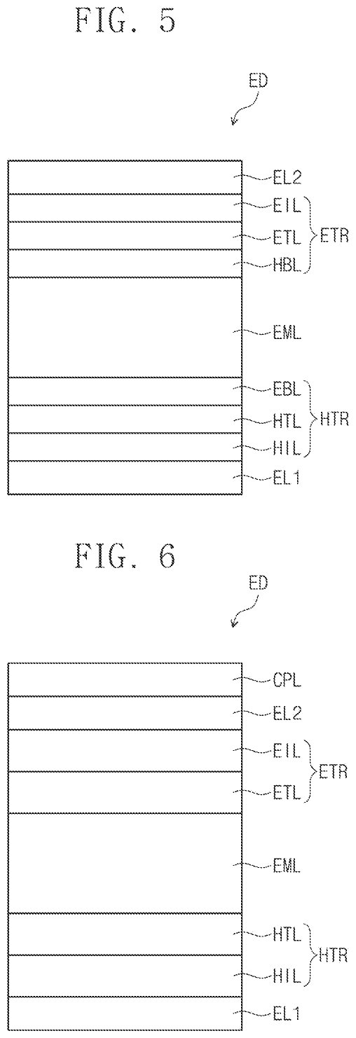

Compared to FIG. 3, FIG. 4 shows a cross-sectional view of a light emitting element ED of an embodiment in which the hole transport region HTR includes a hole injection layer HIL and a hole transport layer HTL, and the electron transport region ETR includes an electron injection layer EIL and an electron transport layer ETL. In some embodiments, compared to FIG. 3, FIG. 5 shows a cross-sectional view of a light emitting element ED of an embodiment in which the hole transport region HTR includes the hole injection layer HIL, the hole transport layer HTL, and an electron blocking layer EBL, and the electron transport region ETR includes the electron injection layer EIL, the electron transport layer ETL, and a hole blocking layer HBL. Compared to FIG. 4, FIG. 6 shows a cross-sectional view of a light emitting element ED of an embodiment including a capping layer CPL on the second electrode EL2.

The emission layer EML may include an organometallic compound of an embodiment. The organometallic compound may include Pt or Pd as a central metal, and the Pt or Pd may include four coupling lines. A phenyl group may be coupled to two of the four coupling lines, carbene imidazole may be coupled to one of the remaining two coupling lines, and pyrazole may be coupled to the other one of the remaining two coupling lines.

In the present disclosure, “substituted or unsubstituted” may refer to being substituted or unsubstituted with one or more substituents selected from the group including (e.g., consisting of) a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a hetero ring group. In some embodiments, each of the substituents illustrated above may be substituted or unsubstituted. For example, a biphenyl group may be an aryl group, and may be a phenyl group substituted with a phenyl group.

In the present disclosure, “form(s) a ring by being coupled to an adjacent group” may refer to forming a substituted or unsubstituted hydrocarbon ring or a substituted or unsubstituted hetero ring by being coupled to an adjacent group. The hydrocarbon ring may include an aliphatic hydrocarbon ring and an aromatic hydrocarbon ring. The hetero ring includes an aliphatic hetero ring and/or an aromatic hetero ring. The hydrocarbon ring and the hetero ring may be monocyclic or polycyclic. Also, a ring formed by being coupled to each other may be connected to another ring to form a spiro structure.

In the present disclosure, “an adjacent group” may refer to a substituent which is substituted with an atom directly connected to an atom with which the substituent is substituted, another substituent substituted with an atom with which the substituent is substituted, or a substituent which is three-dimensional structurally most adjacent to the corresponding substituent. For example, in 1,2-dimethylbenzene, two methyl groups may be interpreted as being “an adjacent group” to each other, and in 1,1-diethylcyclopentane, two ethyl groups may be interpreted as being “an adjacent group” to each other. In some embodiments, in 4,5-dimethylphenanthrene, two methyl groups may be interpreted as being “an adjacent group” to each other.

In the present disclosure, examples of the halogen atom include a fluorine atom, a chlorine atom, a bromine atom, and/or an iodine atom.

In the present disclosure, the alkyl group may be linear, branched, or cyclic. The number of carbon atoms of the alkyl group is 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantly group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, and an n-triacontyl group, and/or the like, but are not limited thereto.

In the present disclosure, the aryl group refers to any functional group or substituent derived from an aromatic hydrocarbon ring. The aryl group may be a monocyclic aryl group or a polycyclic aryl group. The number of ring-forming carbon atoms of the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a biphenylene group, a triphenylene group, a pyrenyl group, a benzofluoranthenyl group, a chrysenyl group, and/or the like, but are not limited thereto.

In the present disclosure, the heteroaryl group may include one or more of B, O, N, P, Si, and S as a hetero atom. When the heteroaryl group includes two or more hetero atoms, the two or more hetero atoms may be the same or different from each other. The heteroaryl group may be a monocyclic heterocyclic group or a polycyclic heterocyclic group. The number of ring-forming carbon atoms of the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazinyl group, a pyrazinyl group, a quinoline group, a quinazoline group, a quinoxaline group, a phenothiazine group, a phthalazine group, a pyrido pyrimidine group, a pyrido pyrazine group, a pyrazino pyrazine group, an isoquinoline group, an indole group, a carbazole group, an N-arylcarbazol group, an N-heteroarylcarbazole group, an N-alkylcarbazol group, a benzooxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilol group, a dibenzofuran group, and/or the like, but are not limited thereto.

In the present disclosure, the silyl group includes an alkylsilyl group and/or an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but are not limited thereto.

In the present disclosure, a direct linkage may refer to a single bond. In the present disclosure, “

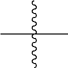

”, “ [symbol] ” indicates a position to be connected.

The organometallic compound of an embodiment may be represented by Formula 1. The light emitting element ED of an embodiment may include the organometallic compound represented by Formula 1.

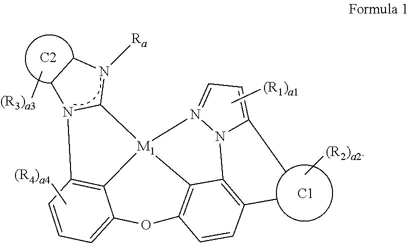

In Formula 1, M₁ may be Pt or Pd. Rₐ may be a substituted or unsubstituted aryl group having 6 to 30 ring-forming carbon atoms. For example, Rₐ may be a substituted or unsubstituted phenyl group.

In an embodiment, Rₐ may be represented by Formula RAA.

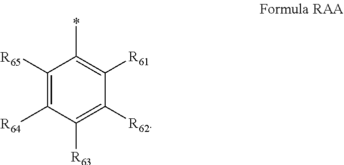

In Formula RAA, R₆₁ to R₆₅ may each independently be a hydrogen atom, a deuterium atom, a substituted or unsubstituted methyl group, a substituted or unsubstituted t-butyl group, or a substituted or unsubstituted a phenyl group. For example, two or three of R₆₁ to R₆₅ may be hydrogen atoms, and the rest (substituents that are not hydrogen atoms) thereof may each independently be a substituted or unsubstituted methyl group, a substituted or unsubstituted t-butyl group, or a substituted or unsubstituted a phenyl group. When at least one selected from among R₆₁ to R₆₅ is a substituted methyl group, the methyl group may be substituted with a deuterium atom. When at least one selected from among R₆₁ to R₆₅ is a substituted phenyl group, the substituted phenyl group may be substituted with a t-butyl group or a phenyl group.

For example, Rₐ may be represented by any one selected from among Ra-1 to Ra-8. Ra-1 and Ra-3 may each represent a phenyl group substituted with two phenyl groups, and Ra-2 and Ra-4 may each represent a phenyl group substituted with two t-butyl groups. Ra-5 may represent a phenyl group substituted with two biphenyl groups. Ra-6 may represent a phenyl group substituted with two phenyl groups, and one of the two phenyl groups is substituted with two t-butyl groups. Ra-7 may represent a phenyl group substituted with two phenyl groups and one t-butyl group. Ra-8 may represent a phenyl group substituted with two phenyl groups and one CD3. In Ra-8, D is a deuterium atom.

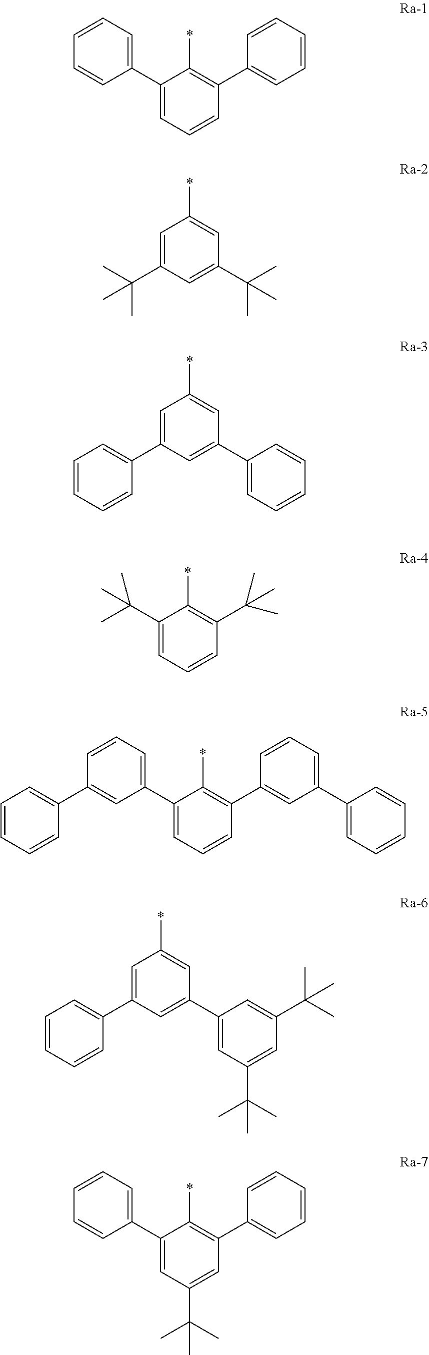

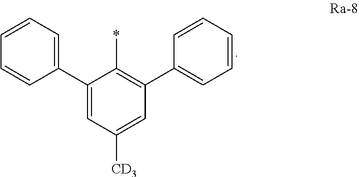 [SMILES: *c1c(-c2ccccc2)cc(C([2H])([2H])[2H])cc1-c1ccccc1]

In Formula 1, the C1 ring group and the C2 ring group may each independently be a substituted or unsubstituted aryl group having 6 to 30 ring-forming carbon atoms. For example, the C1 ring group and the C2 ring group may each independently be a substituted or unsubstituted phenyl group.

In Formula 1, a1 is an integer from 0 to 2, and when a1 is 2, a plurality of R₁ may be the same or at least one thereof may be different. In Formula 1, a2 and a3 may each independently be an integer from 0 to 4. When a2 is an integer of 2 or greater, a plurality of R₂ may be the same or at least one thereof may be different. When a3 is an integer of 2 or greater, a plurality of R₃ may be the same or at least one thereof may be different. In Formula 1, a4 may be an integer from 0 to 3. When a4 is an integer of 2 or greater, a plurality of R₄ may be the same or at least one thereof may be different.

R₁ to R₄ may each independently be a hydrogen atom, a deuterium atom, a substituted or unsubstituted alkyl group having 1 to 20 carbons, a substituted or unsubstituted aryl group having 6 to 30 ring-forming carbon atoms, or a substituted or unsubstituted heteroaryl group having 2 to 30 ring-forming carbon atoms, and/or form a ring by being coupled to an adjacent group. In an embodiment, R₁ and R₂ may be coupled to each other to form a ring, or R₃ and R₄ may be coupled to each other to form a ring.

For example, R₁ and R₂ may be isopropyl groups, and R₁ and R₂ may be coupled to each other to form a hydrocarbon ring group substituted with four methyl groups. The hydrocarbon ring group substituted with four methyl groups may be condensed with a pyrazole group including R₁ and C1 ring group.

In Formula 1, a4 may be 1, and R₄ may be a t-butyl group. When R₄ is a t-butyl group, in a ring group including R₄, the t-butyl group may be coupled to a carbon atom coupled with M₁ and to a carbon atom at a para position.

In an embodiment, Formula 1 may be represented by Formula 1-1. Formula 1 represents an embodiment in which the C1 ring group and the C2 ring group in Formula 1 are substituted or unsubstituted phenyl groups.

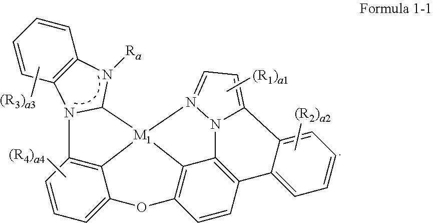

In Formula 1-1, a ring group including R₂ may correspond to C1 ring group in Formula 1. In Formula 1-1, a ring group including R₃ may correspond to C2 ring group in Formula 1. In Formula 1-1, the same contents/definitions as those described with reference to Formula 1 may be applied to M₁, a1 to a4, R₁ to R₄, and Rₐ.

In an embodiment, Formula 1-1 may be represented by Formula 1-1A. Formula 1-1A represents an embodiment in which R₁ and R₂ in Formula 1-1 are isopropyl groups, and R₁ and R₂ are coupled to each other to form a ring. In some embodiments, Formula 1-1A represents an embodiment in which M₁ in Formula 1-1 is Pt.

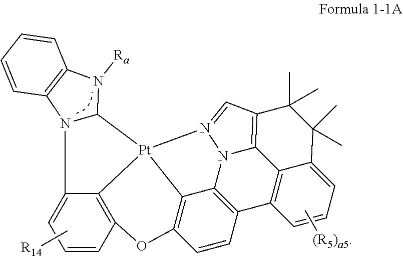

In Formula 1-1A, a5 may be an integer from 0 to 3. When a5 is an integer of 2 or greater, a plurality of R₅ may be the same or at least one thereof may be different. R₅ may be a hydrogen atom, a deuterium atom, a substituted or unsubstituted alkyl group having 1 to 30 carbons, a substituted or unsubstituted aryl group having 6 to 30 ring-forming carbon atoms, or a substituted or unsubstituted heteroaryl group having 2 to 30 ring-forming carbon atoms. For example, R₅ may be a substituted or unsubstituted phenyl group or a substituted or unsubstituted carbazole group.

In an embodiment, R₅ may be represented by any one selected from among R5-1 to R5-3. R5-1 represents a substituted or unsubstituted phenyl group, and R5-2 represents a substituted or unsubstituted carbazole group. R5-3 represents an unsubstituted t-butyl group.

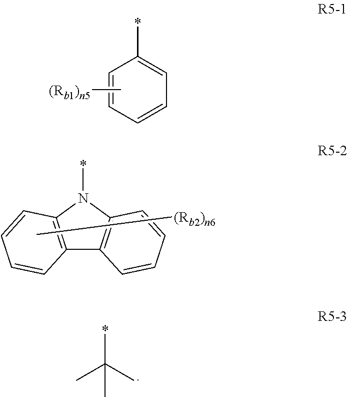

In R5-1, n5 may be an integer from 0 to 5. In R5-2, n6 may be an integer from 0 to 8. When n5 is an integer of 2 or greater, a plurality of R_{b1} may be the same or at least one thereof may be different. When n6 is an integer of 2 or greater, a plurality of R_{b2} may be the same or at least one thereof may be different. In R5-1 and R5-2, R_{b1} and R_{b2} may each independently be a hydrogen atom, a deuterium atom, a substituted or unsubstituted alkyl group having 1 to 30 carbon atoms, or a substituted or unsubstituted aryl group having 6 to 30 ring-forming carbon atoms. For example, R_{b1} and R_{b2} may be hydrogen atoms.

In Formula 1-1A, R₁₄ may be a hydrogen atom, a deuterium atom, or a substituted or unsubstituted alkyl group having 1 to 10 carbon atoms. For example, R₁₄ may be a t-butyl group. In Formula 1-1A, the same contents/definitions as those described with reference to Formula 1-1 may be applied to Rₐ.

Formula 1-1A may be represented by Formula 1-1AA. Formula 1-1AA shows the coupling position of R₁₄, and the coupling position of R₅ when a5 is 1, in Formula 1-1A.

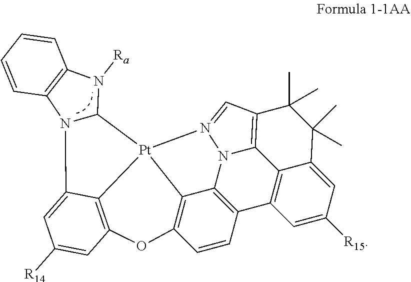

In Formula 1-1AA, the same contents/definitions as those described with reference to Formula 1-1A may be applied to R₁₄ and Rₐ. R₁₅ may be a hydrogen atom, a deuterium atom, a substituted or unsubstituted aryl group having 6 to 30 ring-forming carbon atoms, or a substituted or unsubstituted heteroaryl group having 2 to 30 ring-forming carbon atoms. R₁₅ may correspond to R₅ in Formula 1-1A.

The organometallic compound of an embodiment may be represented by any one selected from among compounds of Compound Group 1. The light emitting element ED of an embodiment may include any one selected from among compounds of Compound Group 1. In Compound Group 1, D is a deuterium atom.

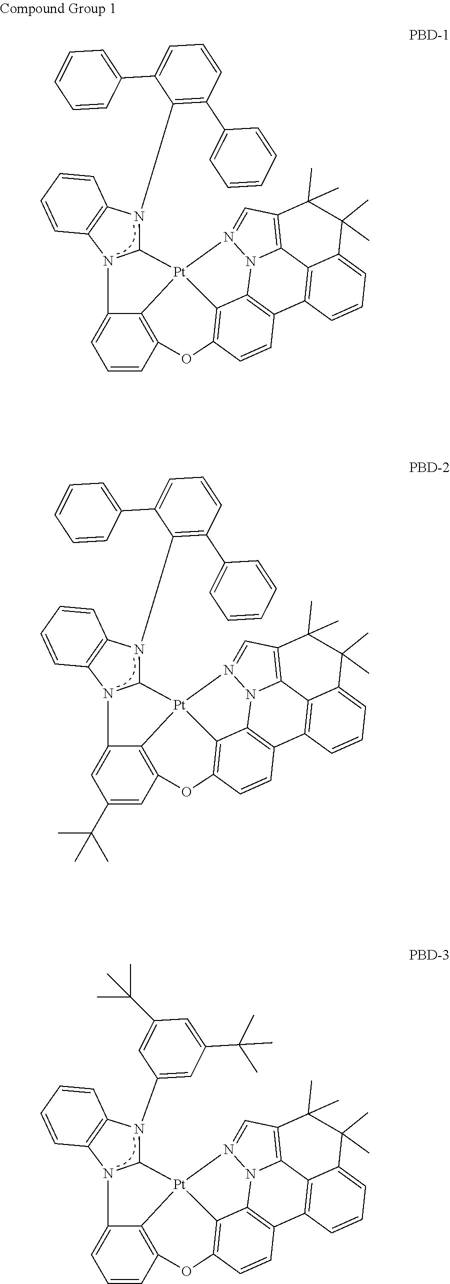

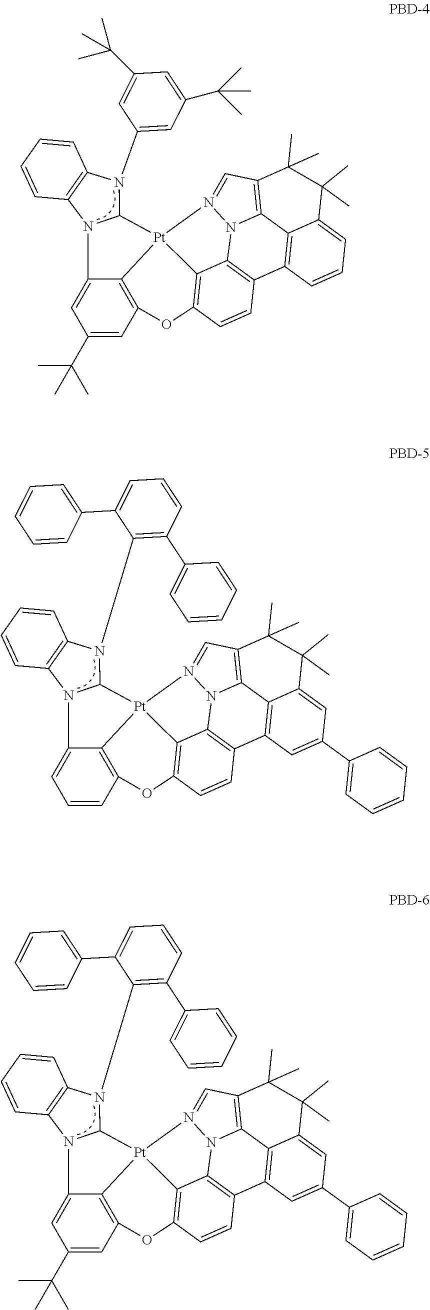

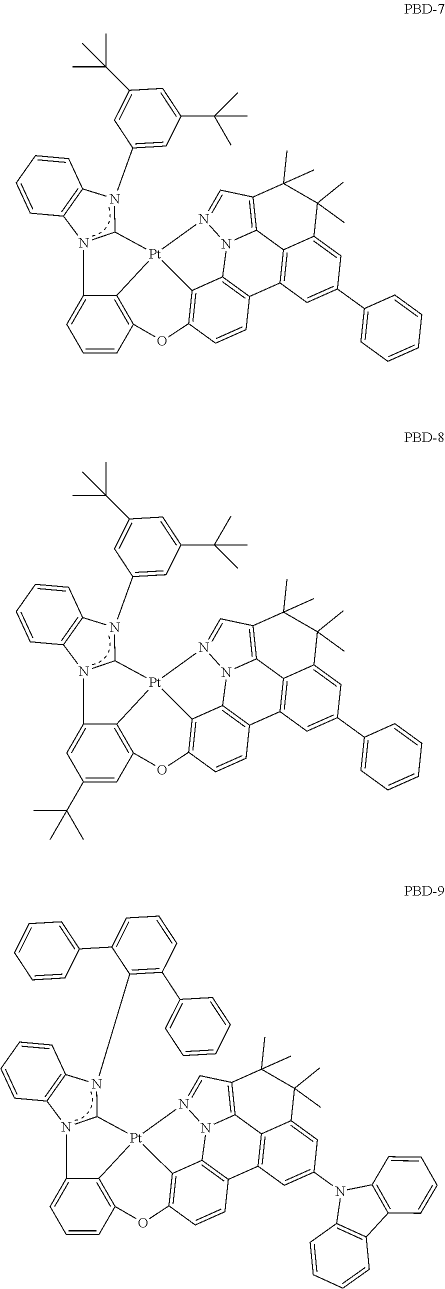

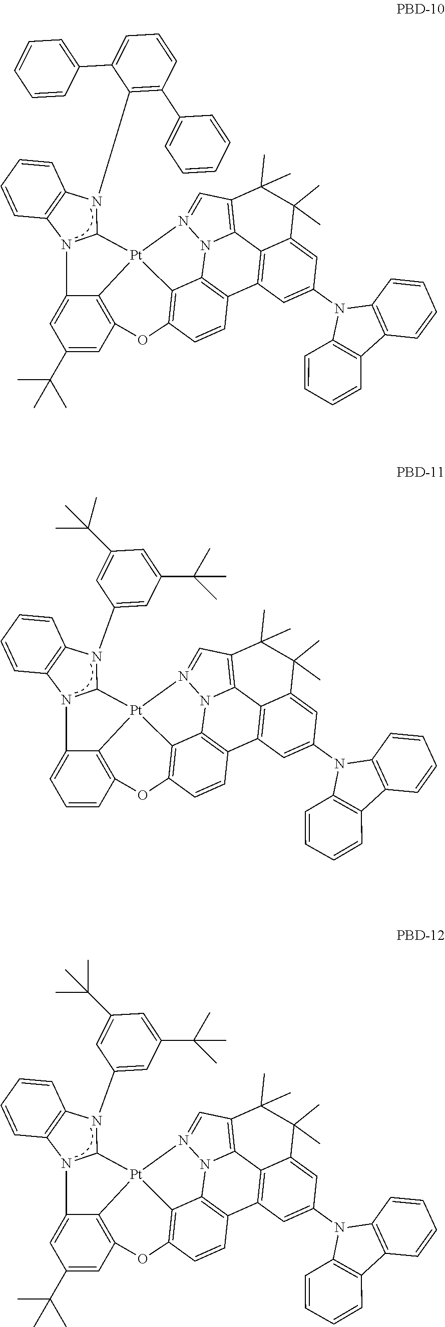

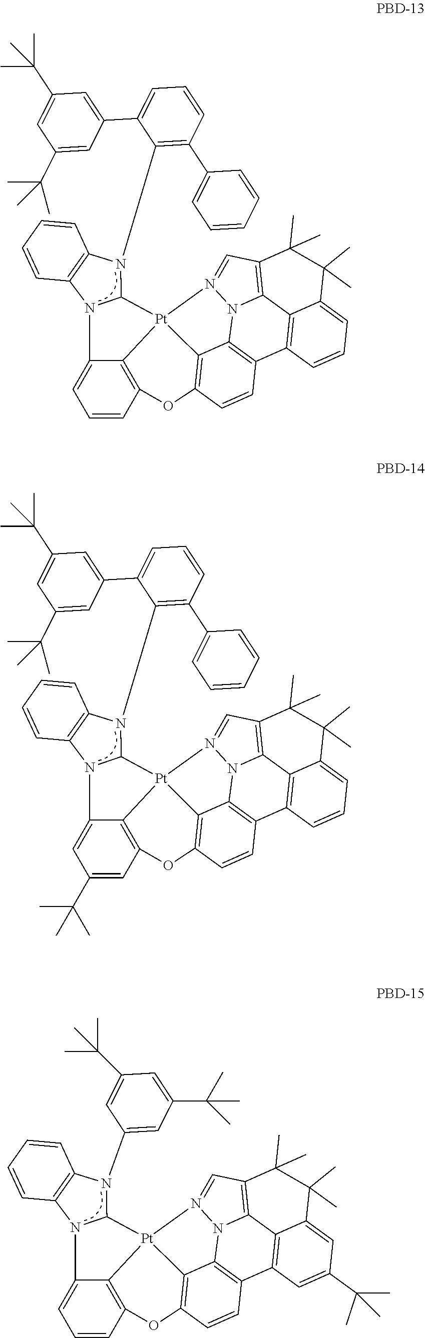

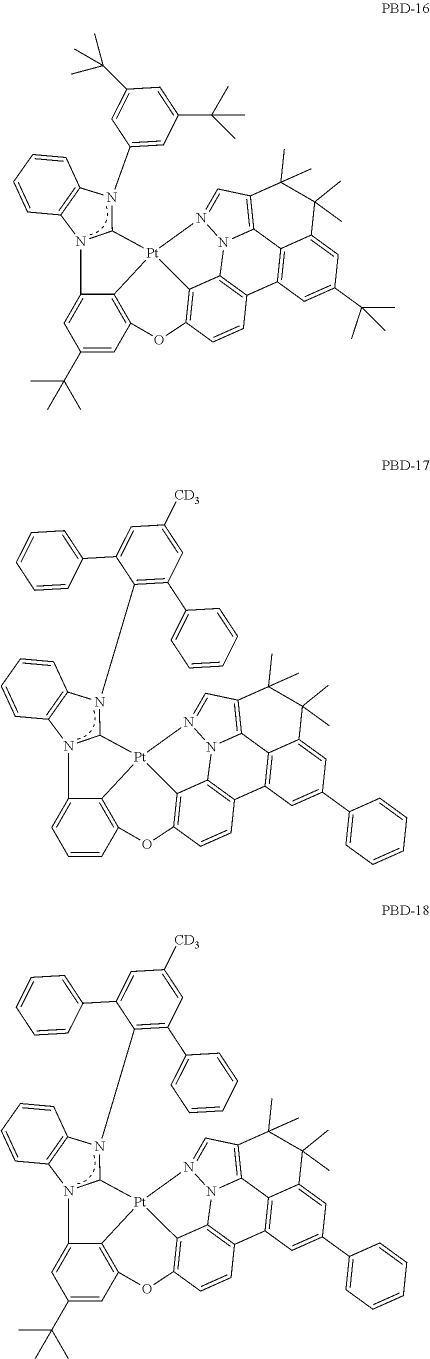

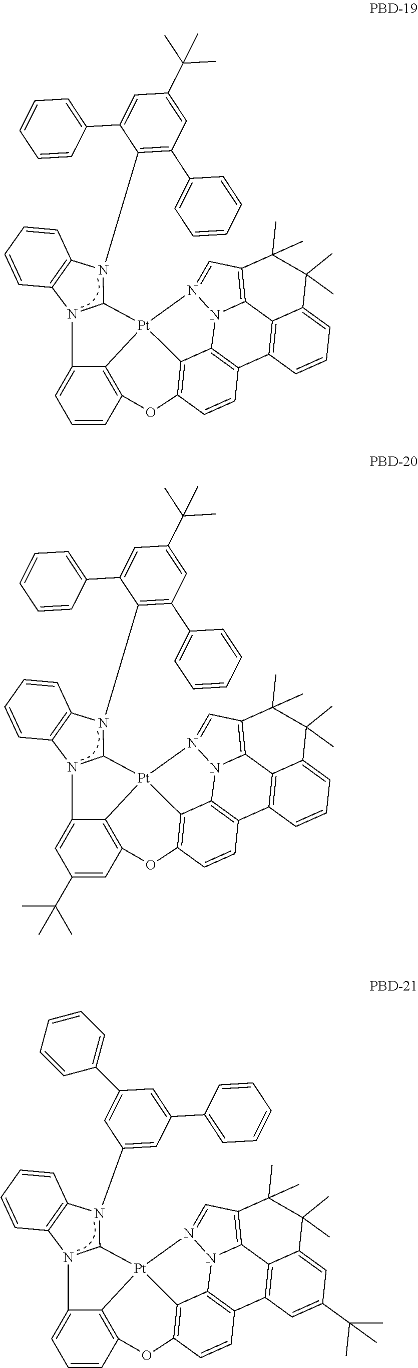

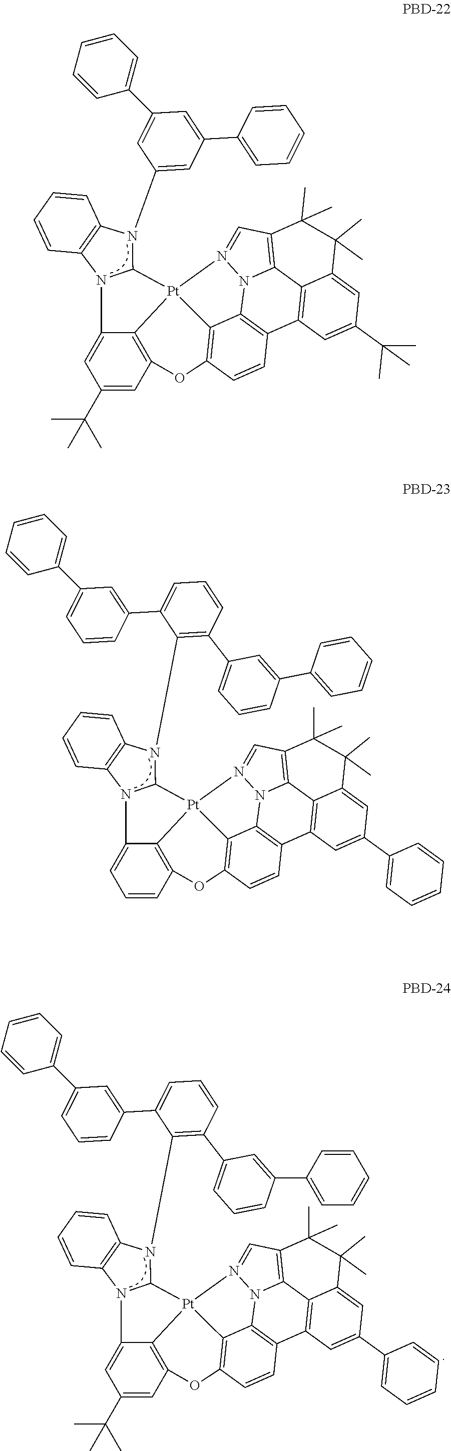

The emission layer EML may include the organometallic compound of an embodiment. The organometallic compound of an embodiment may include Pt or Pd as a central metal, and the central metal may be coupled with two substituted or unsubstituted phenyl groups, and coupled with a substituted carbene imidazole group and a substituted pyrazole group. A substituent of the substituted pyrazole group may be coupled to a substituent of an adjacent phenyl group to for a ring group, and the formed ring group may form a condensed ring with a pyrazole group and a phenyl group. The substituent of the substituted pyrazole group and the substituent of the adjacent phenyl group may be isopropyl groups. The condensed ring formed by the isopropyl group, the pyrazole group, and the phenyl group may be represented by Formula Z1.

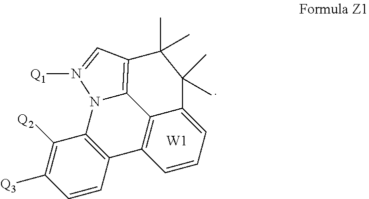

In Formula Z1, W1 ring group is a phenyl group adjacent to a pyrazole group. Q₁ and Q₂ are positions coupled to M₁ of Formula 1 described above, and Q₃ is a position coupled to an oxygen atom of Formula 1 described above. An organometallic compound including a condensed ring such as Formula Z1 is prevented or reduced from being warped, so that the stability of a material may be improved.

For example, the organometallic compound of an embodiment including Pt or Pd as a central metal and including a carbene imidazole group and a condensed ring represented by Formula Z1 may exhibit excellent or suitable material stability. Accordingly, the light emitting element ED including the organometallic compound of an embodiment may exhibit long lifespan properties.

In an embodiment, the emission layer EML may include a hole transporting host, an electron transporting host, and a dopant. The emission layer EML may include the organometallic compound of an embodiment as the dopant, and the organometallic compound of an embodiment may be a phosphorescent dopant. The emission layer EML including the organometallic compound of an embodiment as the dopant may emit phosphorescent light. For example, the organometallic compound of an embodiment may be a blue phosphorescent dopant.

In some embodiments, the emission layer EML may further include a thermally activated delayed fluorescence (TADF) compound. When the emission layer EML includes the organometallic compound of an embodiment and the thermally activated delayed fluorescence compound, the emission layer EML may emit phosphorescent light and/or fluorescent light.

The hole transporting host and the electron transporting host may form an exciplex. However, the embodiment of the present disclosure is not limited thereto, and the hole transporting host and the electron transporting host may not form an exciplex.

In an embodiment, the hole transporting host may include a substituted or unsubstituted fluorenyl group or a substituted or unsubstituted carbazole group. The emission layer EML may include a compound represented by Formula T-1 as the hole transporting host.

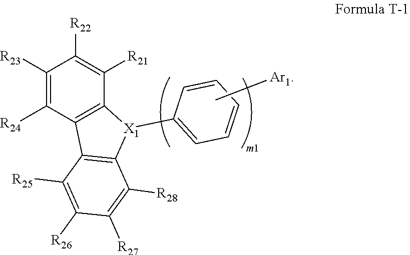

In Formula T-1, X₁ may be CR₂₉ or N. m1 may be an integer from 0 to 2. When X₁ is CR₂₉, a tricyclic condensed ring including X₁ as a ring-forming atom may be a fluorenyl group. When X₁ is N, a tricyclic condensed ring including X₁ as a ring-forming atom may be a carbazole group. When m1 is 0, Ar₁ may be coupled to X₁.

In Formula T-1, R₂₁ to R₂₉ may each independently be a hydrogen atom, a deuterium atom, a substituted or unsubstituted aryl group having 6 to 60 ring-forming carbon atoms, or a substituted or unsubstituted heteroaryl group not including N as a ring-forming atom and having 2 to 60 ring-forming carbon atoms. R₂₁ to R₂₉ may be a substituted or unsubstituted heteroaryl group including one or more of B, O, P, Si, and S as a ring-forming atom, and having 2 to 60 ring-forming carbon atoms.

Ar₁ may be a substituted or unsubstituted aryl group having 6 to 60 ring-forming carbon atoms, or a substituted or unsubstituted heteroaryl group including N as a ring-forming atom and having 2 to 60 ring-forming carbon atoms. For example, Ar₁ may be a substituted or unsubstituted carbazole group. For example, Ar₁ may be a carbazole group substituted with a dibenzofuran group or a phenyl group. However, this is merely an example, and the embodiments of the present disclosure are not limited.

In an embodiment, the hole transporting host may include any one selected from among compounds of Compound Group 2. The emission layer EML may include any one selected from among the compounds of Compound Group 2 as the hole transporting host.

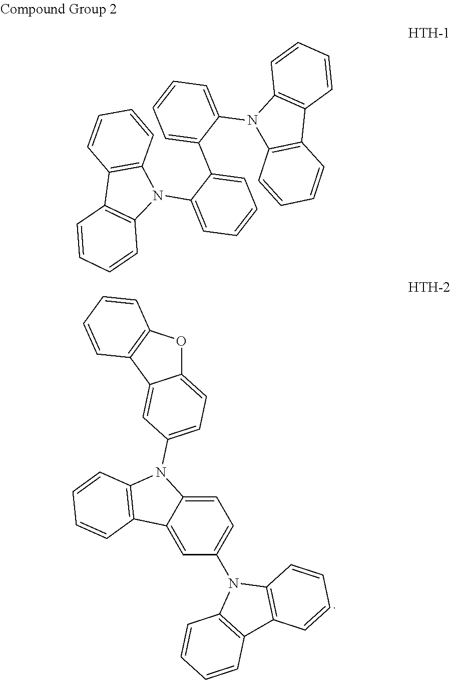

In an embodiment, the electron transporting host may include a substituted or unsubstituted phenyl group, a substituted or unsubstituted pyridine group, a substituted or unsubstituted pyrimidine group, or a substituted or unsubstituted triazine group. The emission layer EML may include a compound represented by Formula T-2 as the electron transporting host.

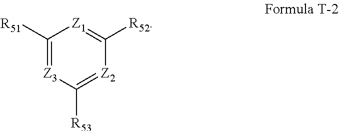

In Formula T-2, Z₁ to Z₃ may each independently be CR₅₄ or N. In Formula T-2, when Z₁ to Z₃ are CR₅₄, T-2 may be a substituted or unsubstituted phenyl group. In Formula T-2, when any one selected from among Z₁ to Z₃ is N, and the other two (those that at not N) thereof are CR₅₄, T-2 may be a substituted or unsubstituted pyridine group. In Formula T-2, when any two of Z₁ to Z₃ are N, and the other one thereof is CR₅₄, T-2 may be a substituted or unsubstituted pyrimidine group. In Formula T-2, when Z₁ to Z₃ are N, T-2 may be a substituted or unsubstituted triazine group.

R₅₁ to R₅₄ may each independently be a hydrogen atom, a deuterium atom, a cyano group, a substituted silyl group, a substituted or unsubstituted aryl group having 6 to 30 ring-forming carbon atoms, or a substituted or unsubstituted heteroaryl group having 2 to 30 ring-forming carbon atoms, and/or form a ring by being coupled to an adjacent group. For example, R₅₁ to R₅₃ may be a cyano group, a phenyl group substituted with a carbazole group, or a carbazole group substituted with a cyano group. In some embodiments, R₅₁ to R₅₃ may be a phenyl group substituted with a silyl group, or an unsubstituted phenyl group. At least one selected from among R₅₁ to R₅₄ may not be a hydrogen atom. However, this is merely an example, and the embodiments of the present disclosure are not limited thereto.

In an embodiment, the electron transporting host may include any one selected from among compounds of Compound Group 3. The emission layer EML may include any one selected from among the compounds of Compound Group 3 as the electron transporting host.

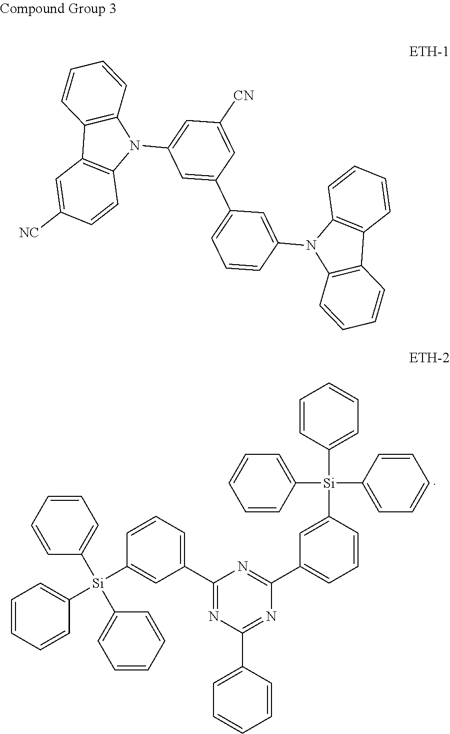 [SMILES: N#Cc1cc(-c2cccc(-n3c4ccccc4c4ccccc43)c2)cc(-n2c3ccccc3c3cc(C#N)ccc32)c1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

For example, the emission layer EML may have a thickness of about 100 Å to about 1000 Å, or about 100 Å to about 300 Å. The emission layer EML may have a single-layered structure having a single layer formed of a single material, a single-layered structure having a single layer formed of a plurality of different materials, or a multi-layered structure having a plurality of layers formed of a plurality of different materials.

The emission layer EML may include the organometallic compound of an embodiment. In some embodiments, the emission layer EML may further include compounds to be described in more detail.

The emission layer EML may include an anthracene derivative, a pyrene derivative, a fluoranthene derivative, a chrysene derivative, a dihydrobenz anthracene derivative, or a triphenylene derivative. For example, the emission layer EML may include an anthracene derivative or a pyrene derivative.

The emission layer EML may include a compound represented by Formula E-1. The compound represented by Formula E-1 may be utilized as a fluorescent host material.

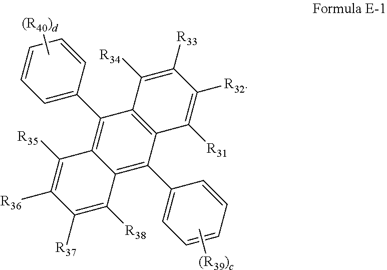

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted an alkenyl group having 1 to 10 carbon atoms, a substituted or unsubstituted aryl group having 6 to 30 ring carbon atoms, or a substituted or unsubstituted heteroaryl group having 2 to 30 ring carbon atoms, and/or form a ring by being coupled to an adjacent group. In Formula E-1, R₃₁ to R₄₀ may be coupled to an adjacent group to form a saturated hydrocarbon ring, unsaturated hydrocarbon ring, saturated hetero ring, or unsaturated hetero ring.

In Formula E-1, c and d may each independently be an integer from 0 to 5.

Formula E-1 may be represented by any one selected from among Compound E1 to Compound E19.

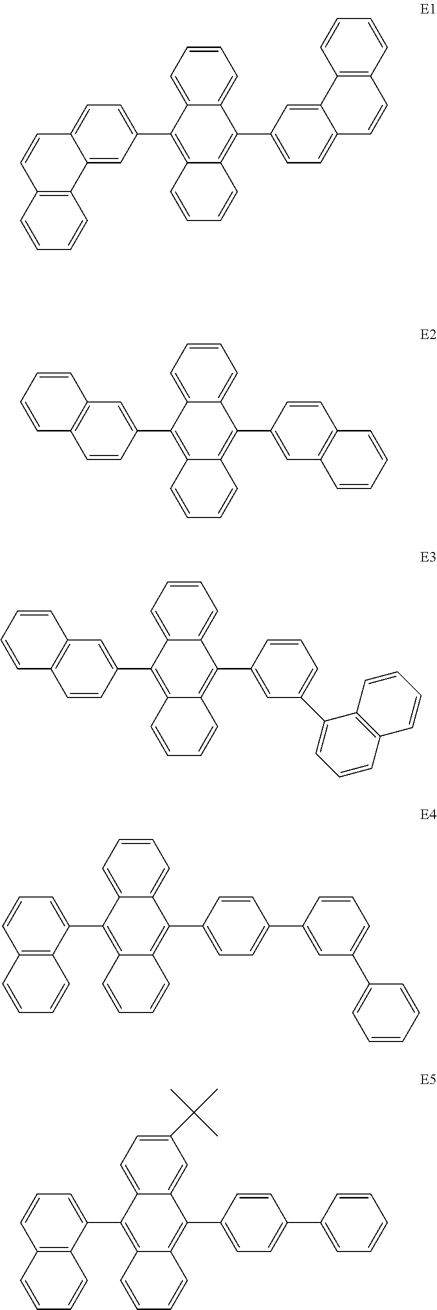

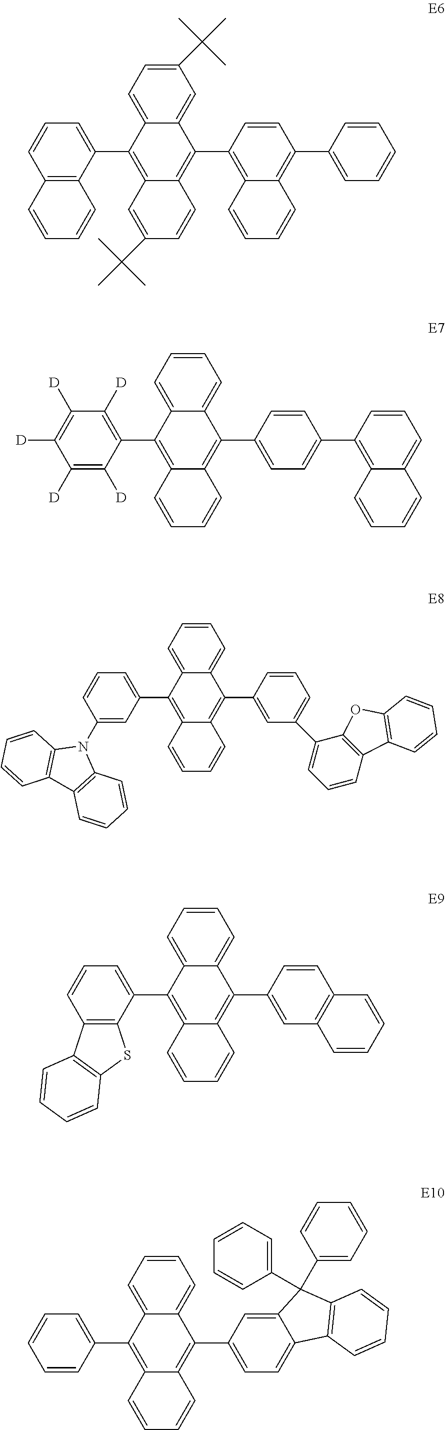

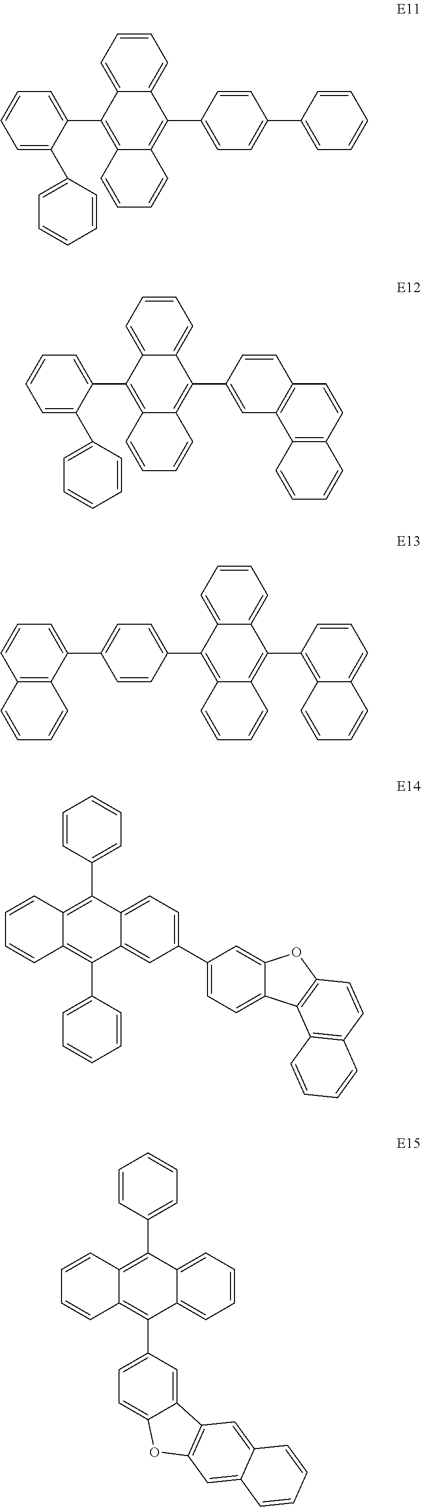

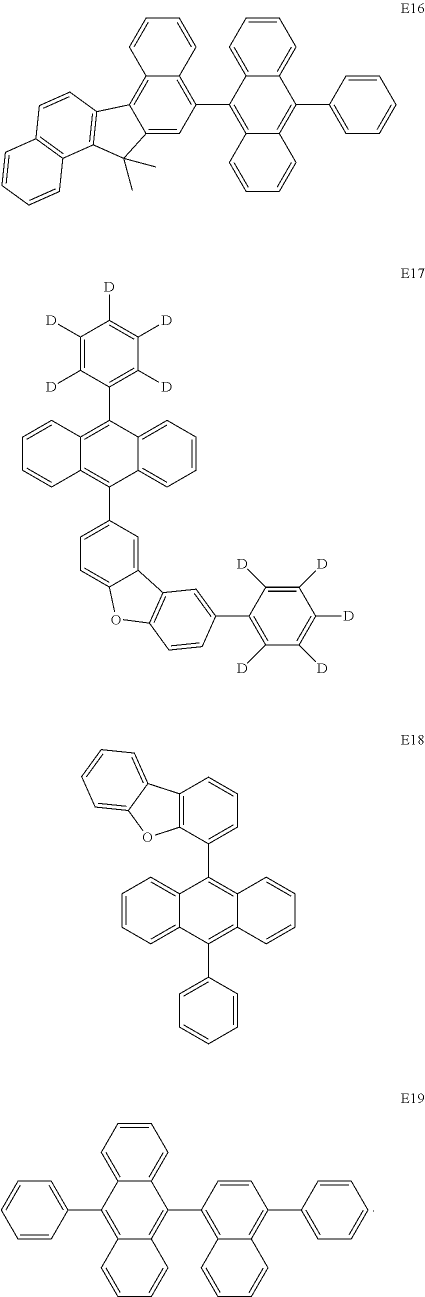

In an embodiment, the emission layer EML may include a compound represented by Formula E-2a or Formula E-2b. The compound represented by Formula E-2a or Formula E-2b may be utilized as a phosphorescent host material.

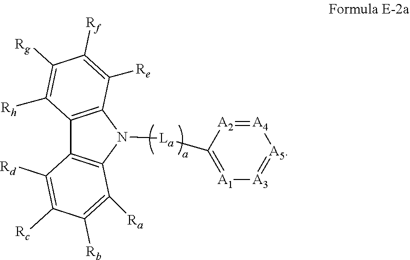

In Formula E-2a, a may be an integer from 0 to 10, Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is an integer of 2 or greater, a plurality of Las may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 10 carbons, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or form a ring by being coupled to an adjacent group. Rₐ to Rᵢ may be coupled to an adjacent group to form a hydrocarbon ring or a hetero ring including N, O, S, and/or the like as a ring-forming atom.

In Formula E-2a, two or three selected from among A₁ to A₅ may be N, and the rest (substituents that are not N) thereof may be CRᵢ.

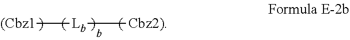

In Formula E-2b, Cbz1 and Cbz2 may each independently be an unsubstituted carbazole group, or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. b may be an integer from 0 to 10, and when b is an integer of 2 or greater, a plurality of L_{b}s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among compounds of Compound Group E-2. However, the compounds listed in Compound Group E-2 are merely examples. The compound represented by Formula E-2a or Formula E-2b is not limited to what is listed in Compound Group E-2.

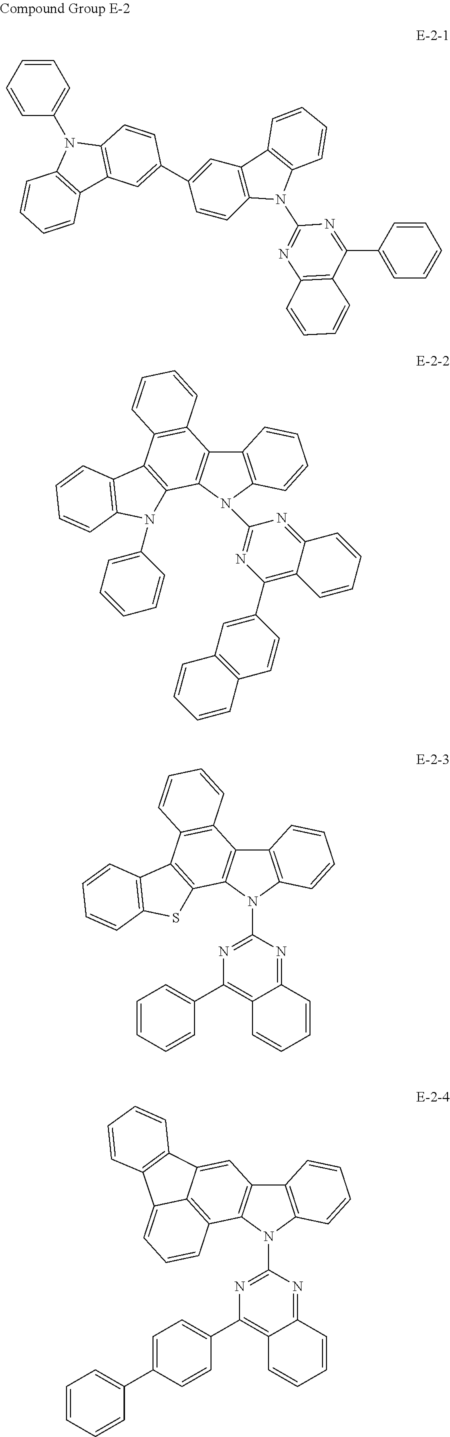 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1 ; c1ccc(-c2ccc(-c3nc(-n4c5ccccc5c5cc6c7c(cccc7c54)-c4ccccc4-6)nc4ccccc34)cc2)cc1]

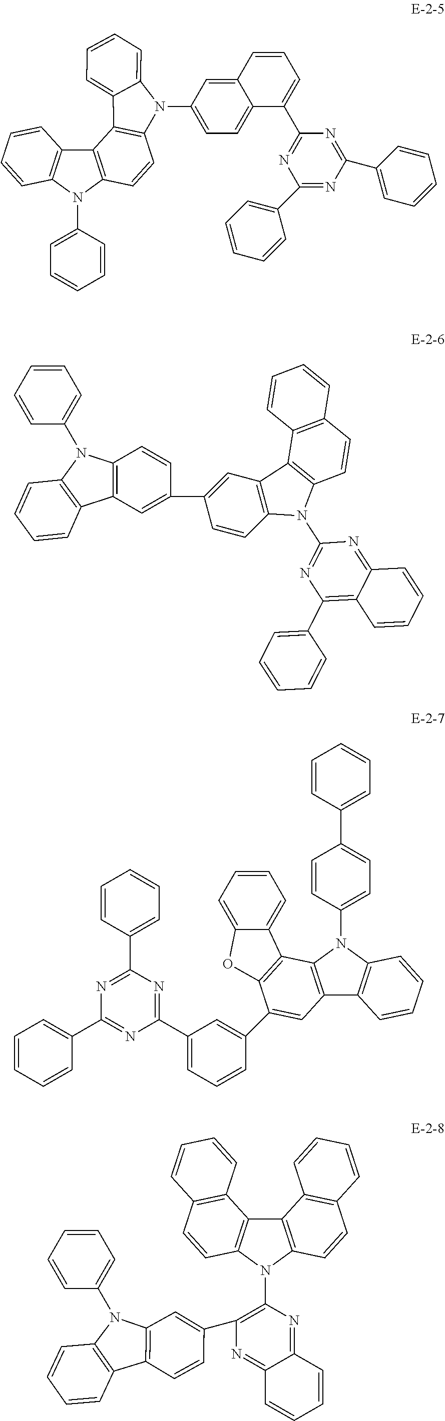 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

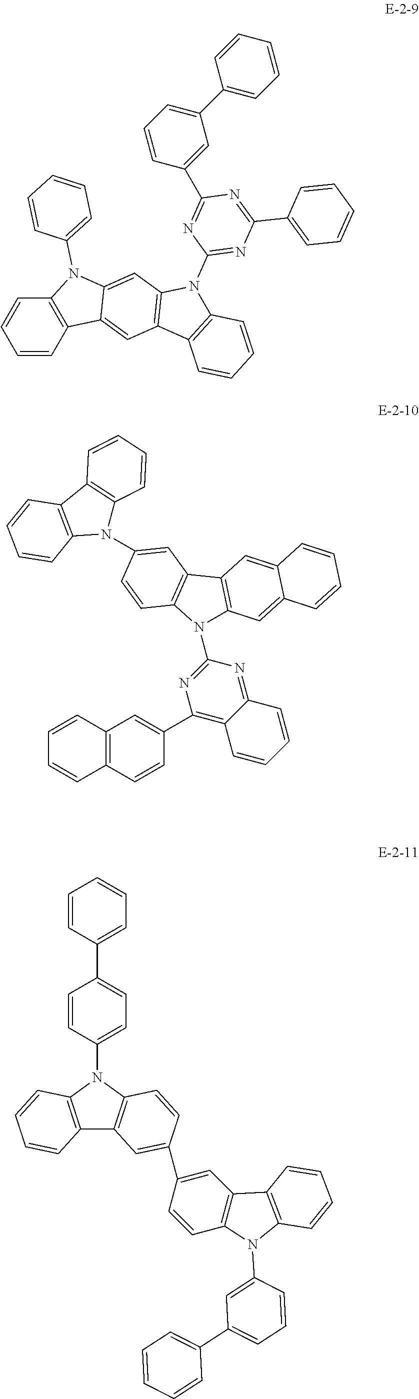 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

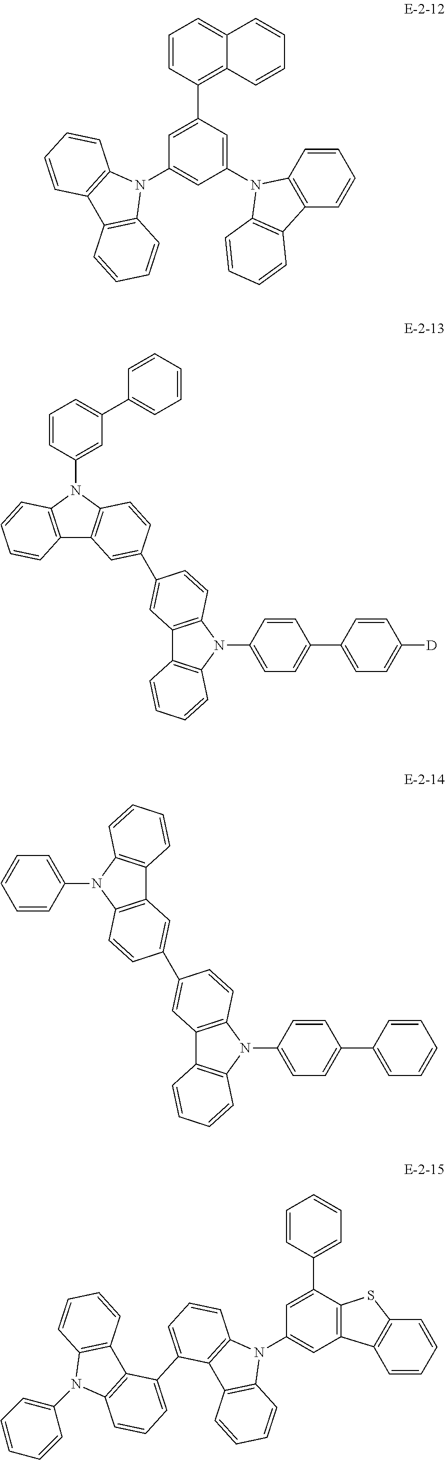 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

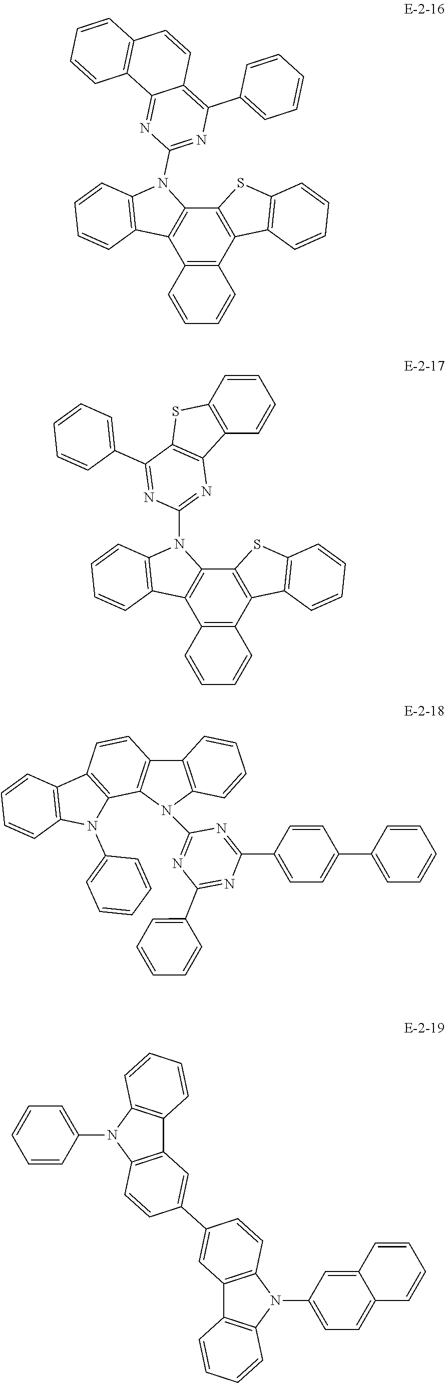 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

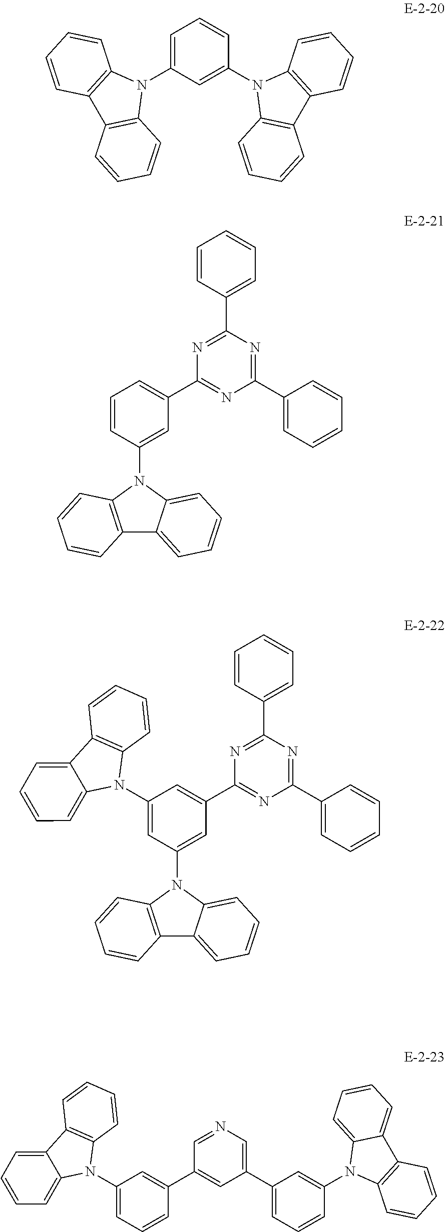 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

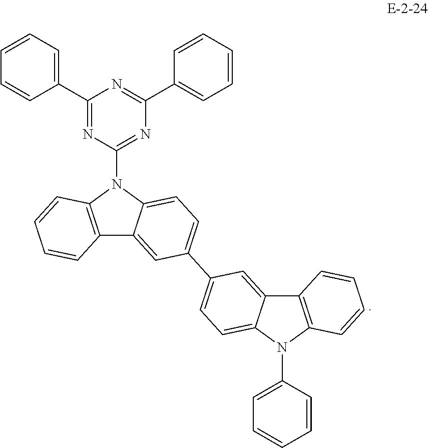 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a common material generally utilized/generally available in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, the embodiment of the present disclosure is not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), and/or the like may be utilized as a host material.

The emission layer EML may include a compound represented by Formula M-a. The compound represented by Formula M-a may be utilized as a phosphorescent dopant material.

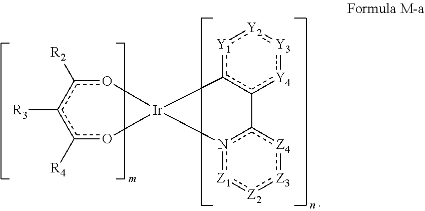

In Formula M-a, Y₁ to Y₄ and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbons, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or form a ring by being coupled to an adjacent group. In Formula M-a, m may be 0 or 1, and n may be 2 or 3. In Formula M-a, when m is 0, n is 3, and when m is 1, n is 2.

The compound represented by Formula M-a may be utilized as a phosphorescent dopant. The compound represented by Formula M-a may be represented by any one selected from among compounds M-a1 to M-a25. However, the compounds M-a1 to M-a25 are merely examples. The compound represented by Formula M-a is not limited to the compounds represented by M-a1 to M-a25.

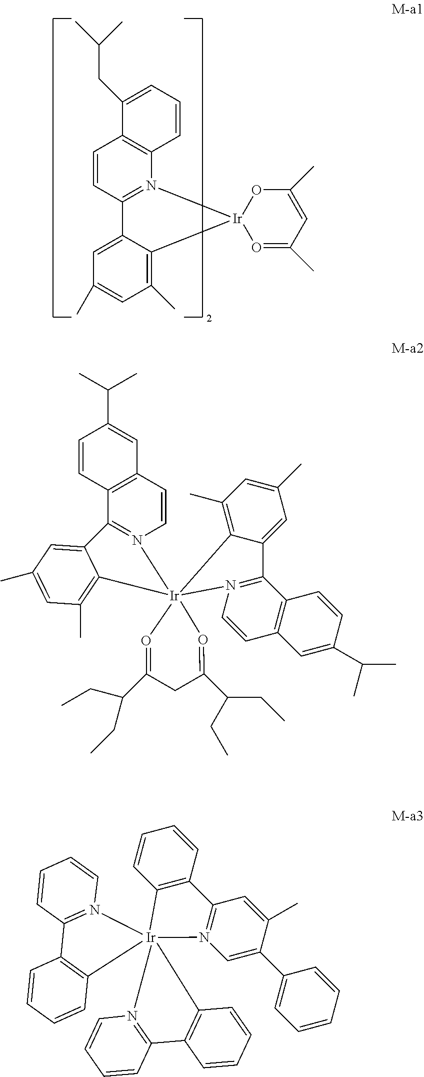

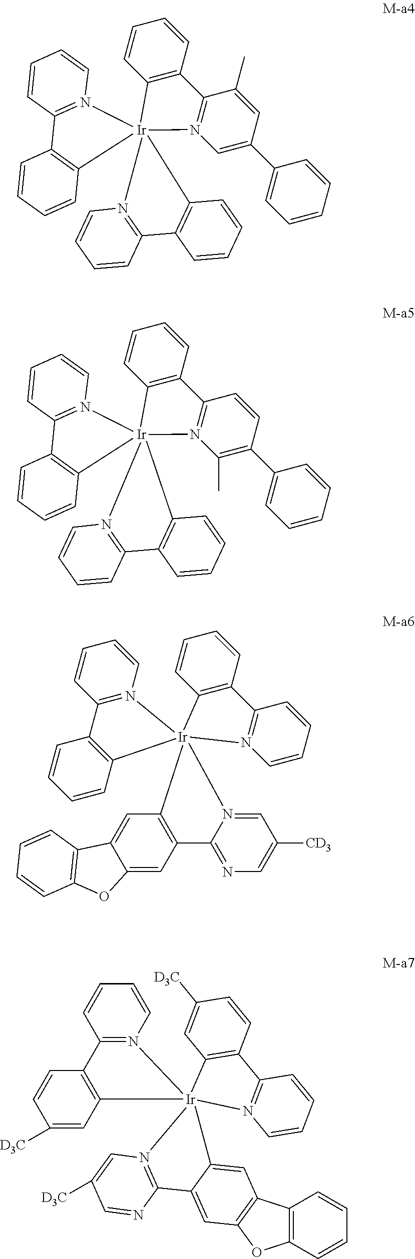

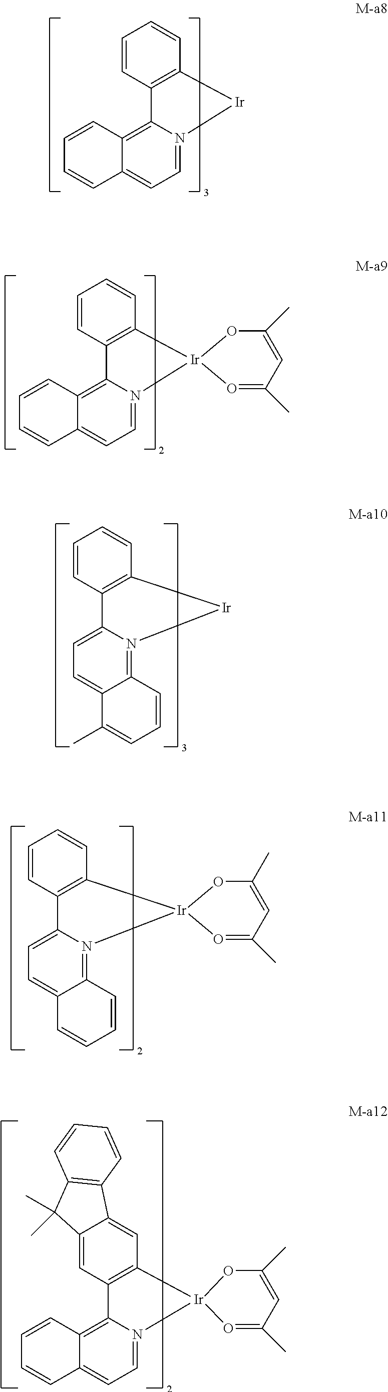

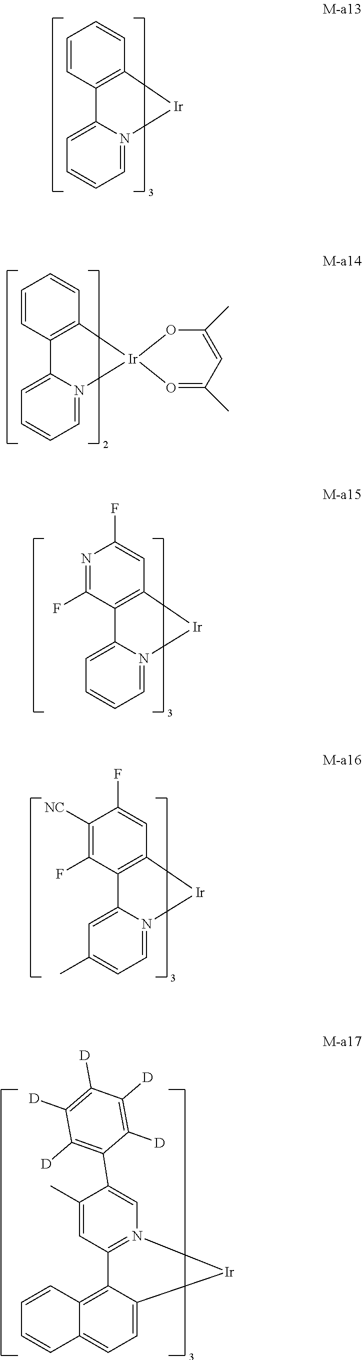

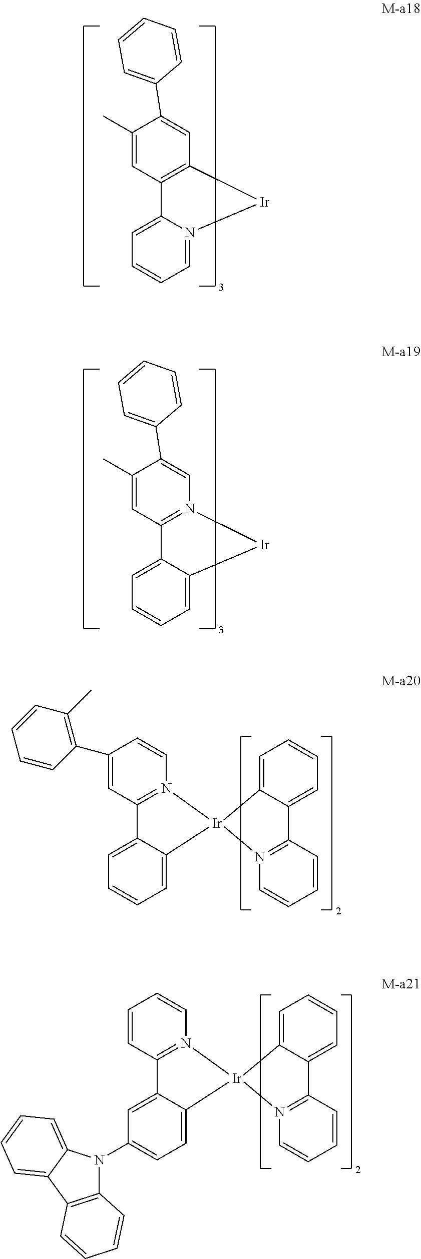

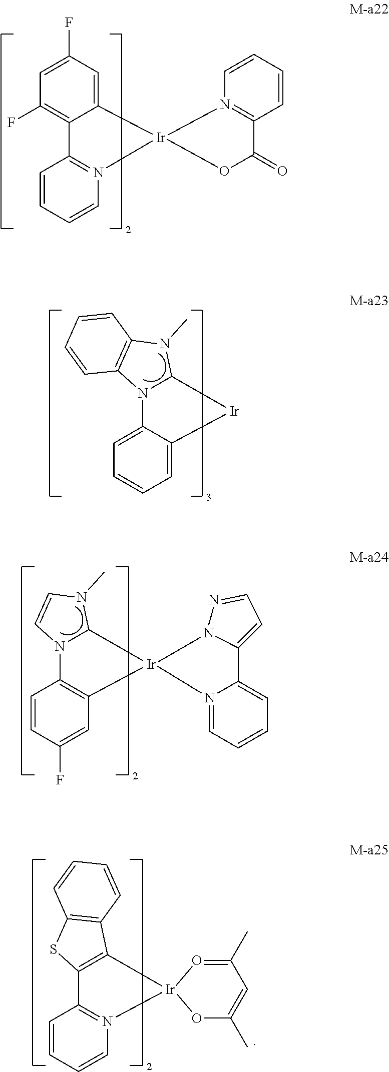

The compound M-a1 and/or the compound M-a2 may be utilized as a red dopant material, and/or the compound M-a3 to the compound M-a7 may be utilized as a green dopant material.

The emission layer EML may include any one selected from among a compound M-b-1 to a compound M-b-11. The compound M-b-1 to the compound M-b-11 may be utilized as a blue phosphorescent dopant or green phosphorescent dopant.

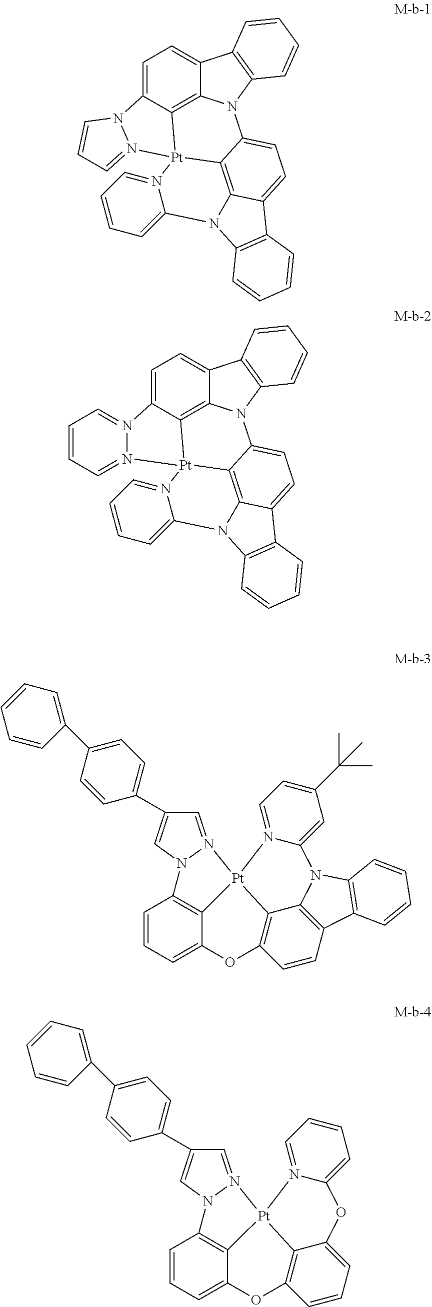

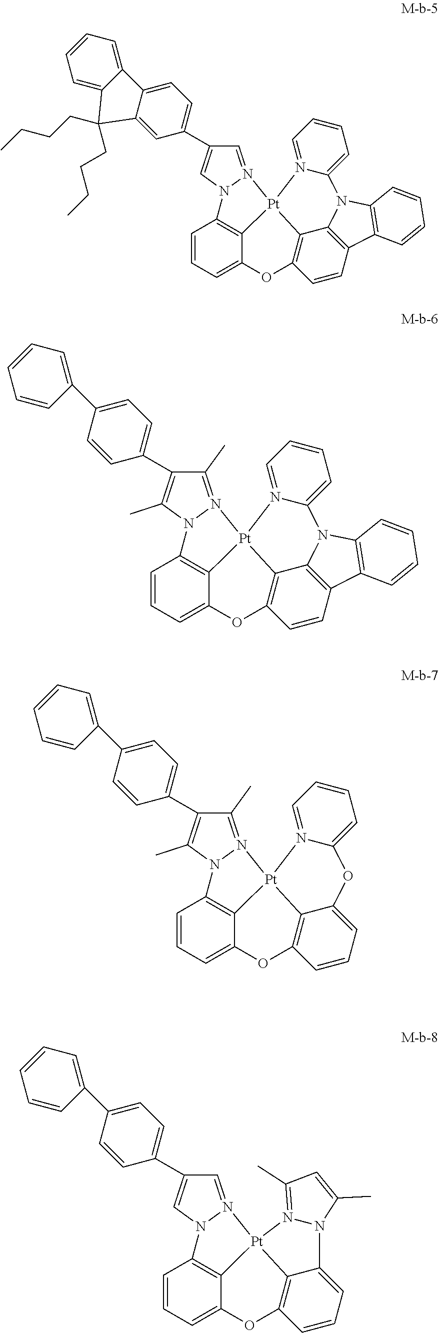

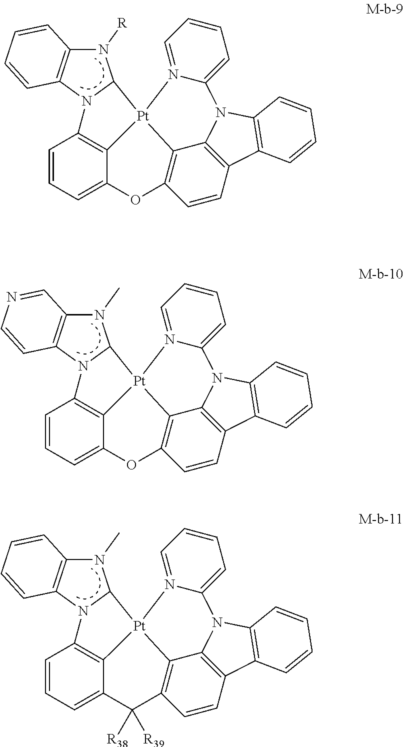

In the compounds above, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbons, a substituted or unsubstituted aryl group having 6 to 30 ring-forming carbon atoms, or a substituted or unsubstituted heteroaryl group having 2 to 30 ring-forming carbon atoms.

The emission layer EML may include a compound represented by any one selected from among Formula F-a to Formula F-c. The compound represented by Formula F-a to Formula F-c may be utilized as a fluorescent dopant material.

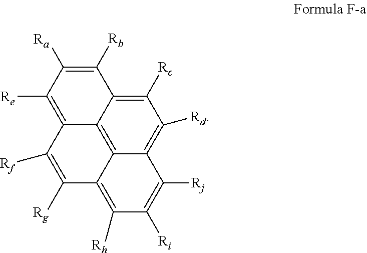

In Formula F-a, two selected from Rₐ to Rⱼ may each independently be substituted with [symbol] NAr₁Ar₂. The rest of Rₐ to Rⱼ which are not substituted with [symbol] NAr₁Ar₂ may each independently be a hydrogen atom, a deuterium atom, a halogen atom, a cyano group, a substituted or unsubstituted amine group, a substituted or unsubstituted alkyl group having 1 to 20 carbons, a substituted or unsubstituted aryl group having 6 to 30 ring-forming carbon atoms, or a substituted or unsubstituted heteroaryl group having 2 to 30 ring-forming carbon atoms. In [symbol] NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group including O or S as a ring-forming atom.

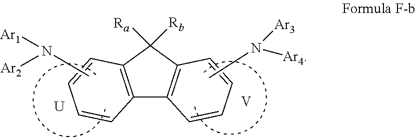

In Formula F-b, Rₐ and R_{b} may each independently be a hydrogen atom, a deuterium atom, a substituted or unsubstituted alkyl group having 1 to 20 carbons, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or form a ring by being coupled to an adjacent group. Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted hetero ring having 2 to 30 ring-forming carbon atoms. In Formula F-b, the number of rings represented by U and V may each independently be 0 or 1.

For example, in Formula F-b, when the number of U or V is 1, one ring constitutes a condensed ring at a portion described as U or V, and when the number of U or V is 0, it refers to a ring described as U or V that is not present. For example, when the number of U is 0 and the number of V is 1, or the number of U is 1 and the number of V is 0, a condensed ring having a fluorene core of Formula F-b may be a tetracyclic compound. In some embodiments, when the number of U and the number of V are all 0, a condensed ring of Formula F-b may be a tricyclic compound. In some embodiments, when the number of U and the number of V are all 1, the condensed ring having a fluorene core of Formula F-b may be a pentacyclic compound.

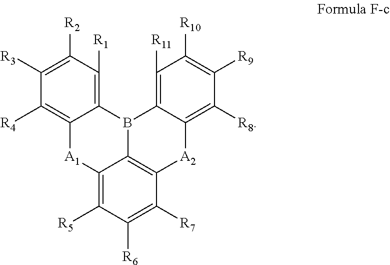

In Formula F-c, A₁ and A₂ may each independently be O, S, Se, or NRₘ, Rₘ may be a hydrogen atom, a deuterium atom, a substituted or unsubstituted alkyl group having 1 to 20 carbons, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbons, a substituted or unsubstituted aryl group having 6 to 30 ring-forming carbon atoms, or a substituted or unsubstituted heteroaryl group having 2 to 30 ring-forming carbon atoms, and/or form a ring by being coupled to an adjacent group.

In Formula F-c, A₁ and A₂ may each independently be coupled to substituents of adjacent rings to form a condensed ring. For example, when A₁ and A₂ are each independently NRₘ, A₁ may be coupled to R₄ or R₅ to form a ring. In some embodiments, A₂ may be coupled to R₇ or R₈ to form a ring.

In an embodiment, the emission layer EML may include, as a dopant material generally utilized/generally available in the art, a styryl derivative (for example, 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E) (diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (for example, 2,5,8,11-tetra-t-butylperylene(TBP)), pyrene and a derivative thereof (for example, 1,1-dipyrene, 1,4-dipyrenylbenzene, and 1,4-bis(N, N-diphenylamino)pyrene), and/or the like.

The emission layer EML may include a phosphorescent dopant material generally utilized/generally available in the art. For example, as a phosphorescent dopant, a metal complex including iridium (Ir), platinum (Pt), osmium (Os), gold (Au), titanium (Ti), zirconium (Zr), hafnium (Hf), europium (Eu), terbium (Tb), or thulium (Tm) may be utilized. For example, iridium(III) bis(4,6-difluorophenylpyridinato-N,C2′)picolinate (Flrpic), Bis(2,4-difluorophenylpyridinato)-tetrakis(1-pyrazolyl)borate iridium(III) (Fir6), or platinum octaethyl porphyrin (PtOEP) may be utilized as a phosphorescent dopant. However, the embodiment of the present disclosure is not limited thereto.

The emission layer EML may include a quantum dot material. A core of the quantum dot may be selected from among a Group II-VI compound, a Group III-VI compound, a Group compound, a Group III-V compound, a Group III-II-V compound, a Group IV-VI compound, a Group IV element, a Group IV compound, and one or more combinations thereof.

The Group II-VI compound may be selected from the group including (e.g., consisting of) a binary compound selected from the group including (e.g., consisting of) CdSe, CdTe, CdS, ZnS, ZnSe, ZnTe, ZnO, HgS, HgSe, HgTe, MgSe, MgS, and one or more compounds or mixtures thereof, a ternary compound selected from the group including (e.g., consisting of) CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and one or more compounds or mixtures thereof, and/or a quaternary compound selected from the group including (e.g., consisting of) HgZnTeS, CdZnSeS, CdZnSeTe, CdZnSTe, CdHgSeS, CdHgSeTe, CdHgSTe, HgZnSeS, HgZnSeTe, HgZnSTe, and one or more compounds or mixtures thereof.

The Group III-VI compound may include a binary compound such as In₂S₃, In₂Se₃, and/or the like, a ternary compound such as InGaS₃, InGaSe₃, and/or the like, or one or more combinations thereof.

The Group I-III-VI compound may be selected from a ternary compound selected from the group including (e.g., consisting of) AgInS, AgInS₂, CuInS, CuInS₂, AgGaS₂, CuGaS₂ CuGaO₂, AgGaO₂, AgAlO₂, and one or more compounds or mixtures thereof, and/or a quaternary compound such as AgInGaS₂, CuInGaS₂, and/or the like.

The Group III-V compound may be selected from the group including (e.g., consisting of) a binary compound selected from the group including (e.g., consisting of) GaN, GaP, GaAs, GaSb, AlN, AlP, AlAs, AlSb, InN, InP, InAs, InSb, and one or more compounds or mixtures thereof, a ternary compound selected from the group including (e.g., consisting of) GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and one or more compounds or mixtures thereof, and a quaternary compound selected from the group including (e.g., consisting of) GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and one or more compounds or mixtures thereof. The Group III-V compound may further include a Group II metal. For example, InZnP and/or the like may be selected as the Group III-II-V compound.

The Group IV-VI compound may be selected from the group including (e.g., consisting of) a binary compound selected from the group including (e.g., consisting of) SnS, SnSe, SnTe, PbS, PbSe, PbTe, and one or more compounds or mixtures thereof, a ternary compound selected from the group including (e.g., consisting of) SnSeS, SnSeTe, SnSTe, PbSeS, PbSeTe, PbSTe, SnPbS, SnPbSe, SnPbTe, and one or more compounds or mixtures thereof, and a quaternary compound selected from the group including (e.g., consisting of) SnPbSSe, SnPbSeTe, SnPbSTe, and one or more compounds or mixtures thereof. The Group IV element may be selected from the group including (e.g., consisting of) Si, Ge, and one or more elements or mixtures thereof. The Group IV compound may be a binary compound selected from the group including (e.g., consisting of) SiC, SiGe, and one or more compounds or mixtures thereof.

In an embodiment, a binary compound, a ternary compound, or a quaternary compound may be present in a particle form at a substantially uniform concentration, or may be present in substantially the same particle form with a partially different concentration distribution. In some embodiments, a binary compound, a ternary compound, or a quaternary compound may have a core/shell structure in which one quantum dot surrounds another quantum dot. In the core/shell structure, a binary compound, a ternary compound, or a quaternary compound may have a concentration gradient in which the concentration of an element present in the shell becomes lower toward the center.

In some embodiments, a quantum dot may have the above core-shell structure including a core having nano-crystals and a shell around (e.g., surrounding) the core. The shell of the quantum dot may serve as a protection layer to prevent or reduce the chemical deformation of the core so as to maintain semiconductor properties, and/or a charging layer to impart electrophoresis properties to the quantum dot. The shell may be a single layer, or multiple layers. An example of the shell of the quantum dot may be a metal or non-metal oxide, a semiconductor compound, or one or more combinations thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄. However, the embodiment of the present disclosure is not limited thereto.

In some embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like. However, the embodiment of the present disclosure is not limited thereto.

A quantum dot may have a full width of half maximum (FWHM) of a light emission wavelength spectrum of about 45 nm or less, about 40 nm or less, or about 30 nm or less, and color purity or color reproducibility may be improved (increased) in the above ranges. In some embodiments, light emitted through such a quantum dot is emitted in all directions, so that a wide viewing angle may be improved (increased).

In some embodiments, although the form of a quantum dot is not limited as long as it is a form generally utilized/generally available utilized in the art, a quantum dot in the form of, for example, substantially spherical, pyramidal, multi-arm, or cubic nanoparticles, nanotubes, nanowires, nanofibers, nanoplate particles, and/or the like may be utilized.

The quantum dot may control the color of emitted light according to the particle size thereof, and accordingly, the quantum dot may have one or more suitable light emission colors such as blue, red, green, and/or the like.

Referring back to FIG. 3 to FIG. 6, the first electrode EL1 has conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, transflective electrode, or reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, Zn, compounds comprising one or more of the foregoing elements, combinations of two or more of the foregoing elements or compounds, mixtures of two or more of the foregoing elements or compounds, and/or oxides thereof.

When the first electrode EL1 is a transmissive electrode, the first electrode EL1 may include a transparent metal oxide, for example, indium tin oxide (ITO), indium zinc oxide (IZO), zinc oxide (ZnO), indium tin zinc oxide (ITZO), and/or the like. When the first electrode EL1 is a transflective electrode or reflective electrode, the first electrode EL1 may include Ag, Mg, Cu, Al, Pt, Pd, Au, Ni, Nd, Ir, Cr, Li, Ca, LiF/Ca (stacking structure of LiF and Ca), LiF/Al (stacking structure of LiF and Al), Mo, Ti, W, and/or one or more compounds or mixtures thereof (for example, a mixture of Ag and Mg). In some embodiments, the first electrode EL1 may have a multi-layered structure including a reflective film or transflective film formed of the above exemplified materials, and a transparent conductive film formed of indium tin oxide (ITO), indium zinc oxide (IZO), zinc oxide (ZnO), indium tin zinc oxide (ITZO), and/or the like.

For example, the first electrode EL1 may have a three-layered structure of ITO/Ag/ITO, but is not limited thereto. In some embodiments, the first electrode EL1 may include any one of the above-described metal materials, a combination of two or more selected from the above-described metal materials, an oxide of any one of the above-described metal materials, and/or the like, but the embodiment of the present disclosure is not thereto. The thickness of the first electrode EL1 may be about 700 Å to about 10000 Å. For example, the thickness of the first electrode EL1 may be about 1000 Å to about 3000 Å.

A hole transport region HTR is provided on the first electrode EL1. The hole transport region HTR may include at least one of the hole injection layer HIL, the hole transport layer HTL, a buffer layer or a light emitting auxiliary layer, or the electron blocking layer EBL. The thickness of the hole transport region HTR may be, for example, about 50 Å to about 15,000 Å.

The hole transport region HTR may have a single-layered structure having a single layer formed of a single material, a single-layered structure having a single layer formed of a plurality of different materials, or a multi-layered structure having a plurality of layers formed of a plurality of different materials. For example, the hole transport region HTR may have a single-layered structure having a single layer of the hole injection layer HIL or the hole transport layer HTL, or a single-layered structure having a single layer formed of a hole injection material and a hole transport material.

Also, the hole transport region HTR may have a single-layered structure having a single layer formed of a plurality of different materials, or have a structure of the hole injection layer HIL/the hole transport layer HTL, the hole injection layer HIL/the hole transport layer HTL/the buffer layer, the hole injection layer HIL/the buffer layer, the hole transport layer HTL/the buffer layer, or the hole injection layer HIL/the hole transport layer HTL/the electron blocking layer EBL, sequentially stacked from the first electrode EL1. However, this is merely an example, and the embodiment of the present disclosure is not limited thereto.

The hole transport region HTR may be formed utilizing one or more suitable methods such as vacuum deposition, spin coating, casting, Langmuir-Blodgett (LB), inkjet printing, laser printing, and/or laser induced thermal imaging (LITI).

The transport region HTR may include a compound represented by Formula H-1.

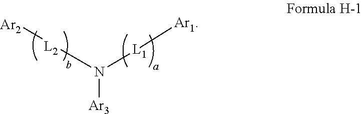

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer from 0 to 10. When a or b is an integer of 2 or greater, a plurality of L₁ and L₂ may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms.

The compound represented by Formula H-1 may be a monoamine compound. In some embodiments, the compound represented by Formula H-1 may be a diamine compound in which at least one selected from among Ar₁ to Ar₃ contains an amine group as a substituent. In some embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one selected from among compounds of Compound Group H. However, the compounds listed in Compound Group H are merely examples. The compound represented by Formula H-1 is not limited to what is listed in Compound Group H.

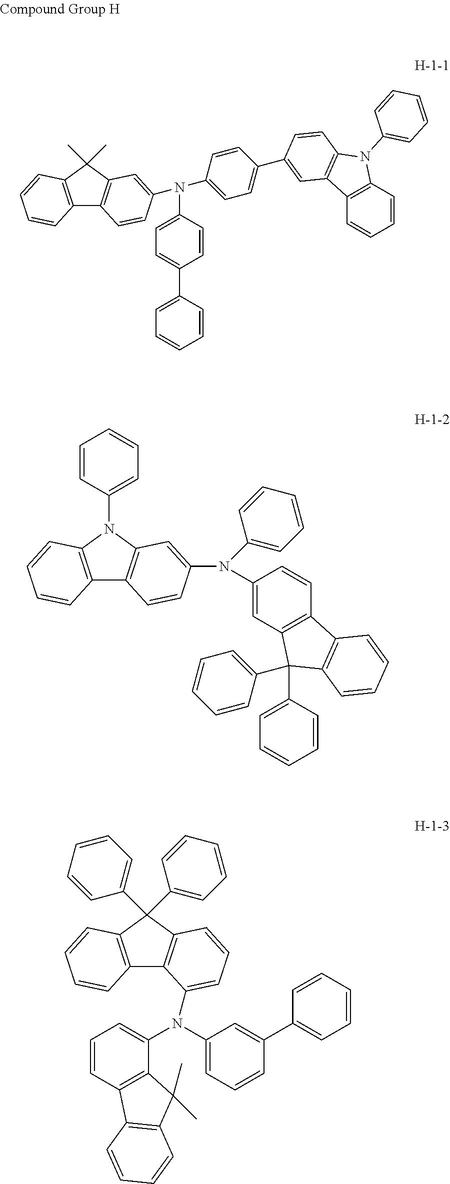 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

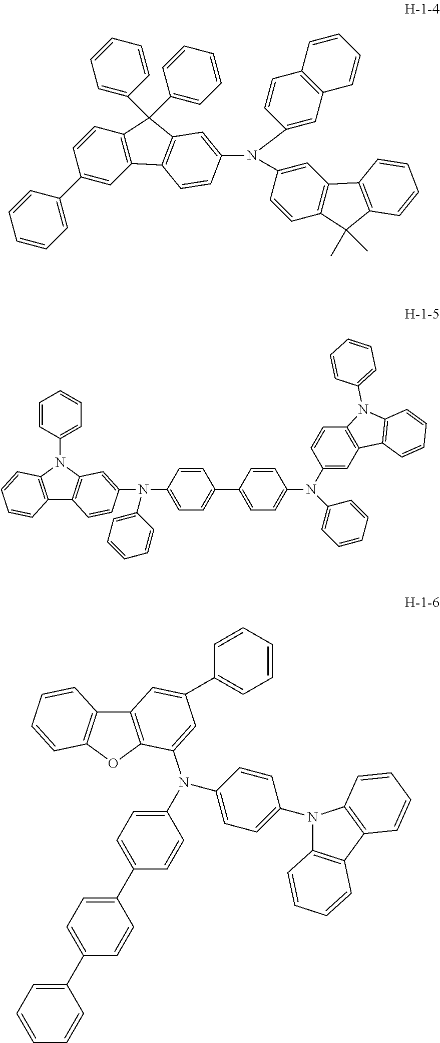 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

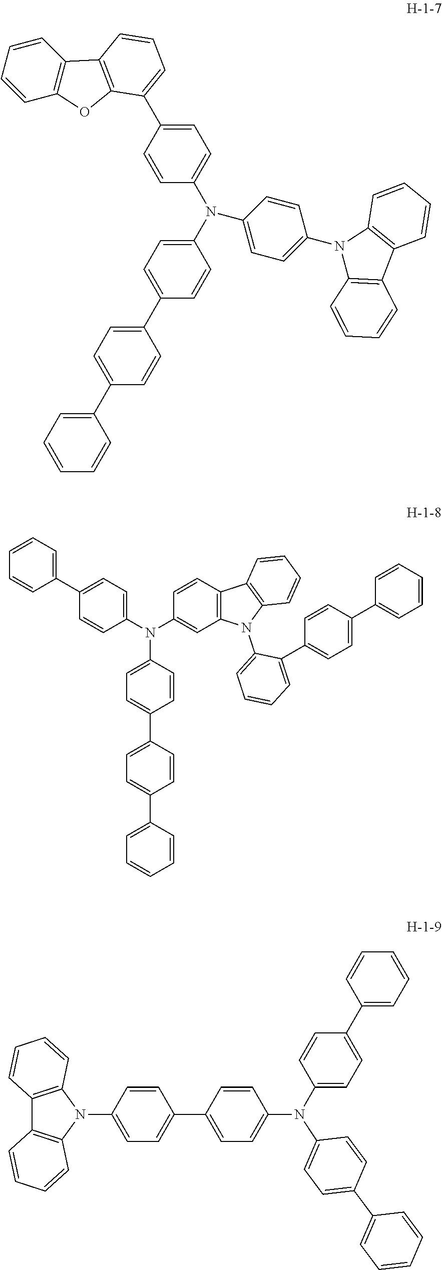 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

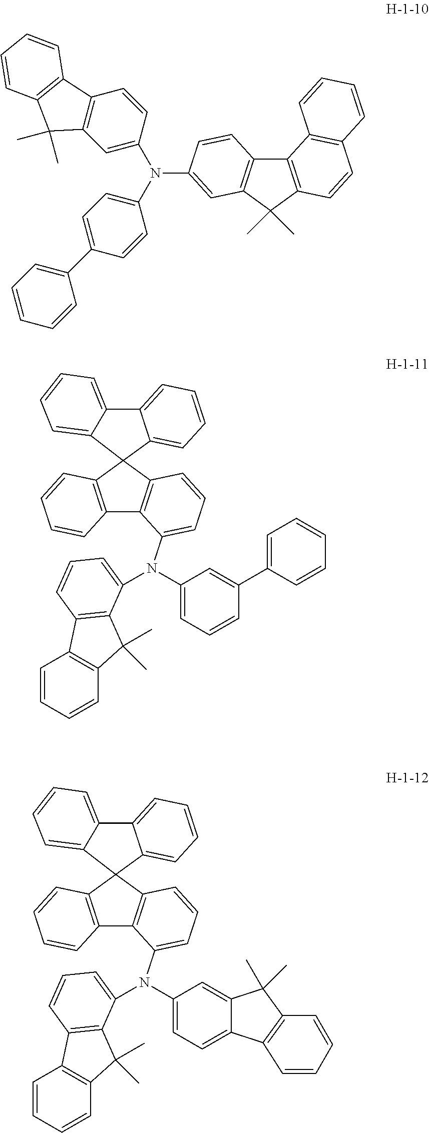

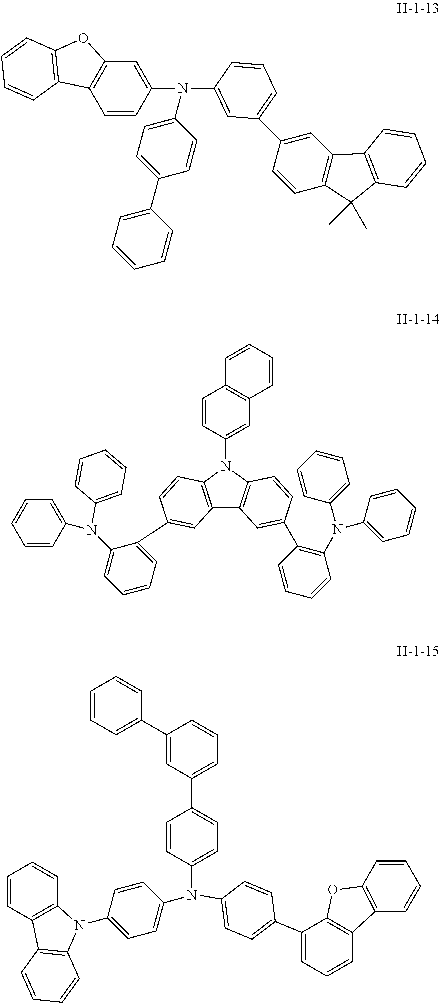 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

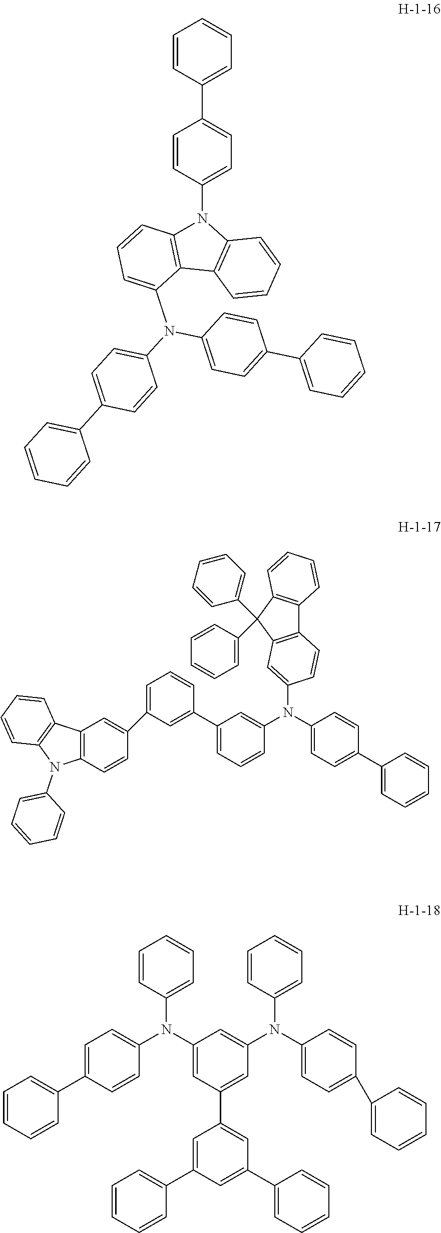 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

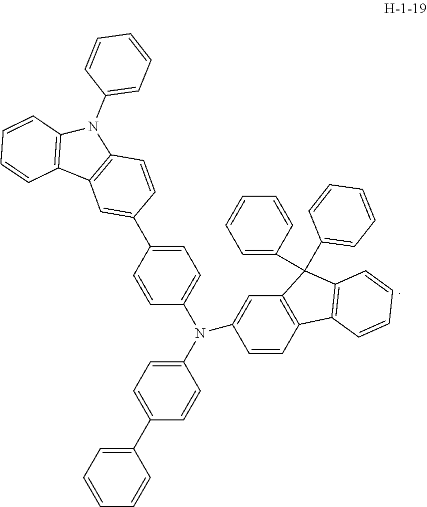 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′, 4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrenesulfonate) (PANI/PSS), N,N′-di(naphthalene-1-yl)-N,N′-diphenyl-benzidine (NPB), triphenylamine-containing polyether ketone (TPAPEK), 4-isopropyl-4′-methyldiphenyliodonium[tetrakis(pentafluorophenyl)borate], dipyrazino[2,3-f: 2′,3′-h] quinoxaline-2,3,6,7,10,11-hexacarbonitrile (HATCN), and/or the like.

In some embodiments, the hole transport region HTR may include a carbazole-based derivative such as N-phenylcarbazole and polyvinylcarbazole, a fluorene-based derivative, a triphenylamine-based derivative such as N,N′-bis(3-methylphenyl)-N,N′-diphenyl-[1,1-biphenyl]-4,4′-diamine (TPD) and 4,4′,4″-tris(N-carbazolyl)triphenylamine (TCTA), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 9-(4-tert-Butylphenyl)-3,6-bis(triphenylsilyl)-9H-carbazole (CzSi), 9-phenyl-9H-3,9′-bicarbazole), 1,3-bis(N-carbazolyl)benzene (mCPCCP), 1,3-bis(1,8-dimethyl-9H-carbazol-9-yl)benzene (mDCP), and/or the like. The hole transport region HTR may include the above-described compounds of the hole transport region in at least one of the hole injection layer HIL, the hole transport layer HTL, or the electron blocking layer EBL.

The thickness of the hole transport region HTR may be about 100 Å to about 10000 Å, for example, about 100 Å to about 5000 Å. When the hole transport region HTR includes the hole injection layer HIL, the thickness of the hole injection layer HIL may be, for example, about 30 Å to about 1000 Å. When the hole transport region HTR includes the hole transport layer HTL, the thickness of the hole transport layer HTL may be about 30 Å to about 1000 Å. When the hole transport region HTR includes the electron blocking layer EBL, the thickness of the electron blocking layer EBL may be about 10 Å to about 1000 Å. When the thicknesses of the hole transport region HTR, the hole injection layer HIL, the hole transport layer HTL, and the electron blocking layer EBL satisfy the above-described ranges, satisfactory (suitable) hole transport properties may be obtained without a substantial increase in driving voltage.

The hole transport region HTR may further include a charge generation material to improve conductivity in addition to the above-mentioned materials. The charge generation material may be substantially uniformly or non-uniformly dispersed in the hole transport region HTR. The charge generation material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may be a halogenated metal compound such as CuI and RbI, a quinone derivative such as tetracyanoquinodimethane (TCNQ) and 2,3,5,6-tetrafluoro-7,7′,8,8′-tetracyanoquinodimethane (F4-TCNQ), a metal oxide such as a tungsten oxide and a molybdenum oxide, a cyano group-containing compound such as dipyrazino[2,3-f: 2′,3′-h] quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but the embodiment of the present disclosure is not limited thereto.

As described above, the hole transport region HTR may further include at least one of the buffer layer or the electron blocking layer EBL in addition to the hole injection layer HIL and the hole transport layer HTL. The buffer layer may increase light emission efficiency by compensating for a resonance distance according to the wavelength of light emitted from the emission layer EML. Materials which may be included in the hole transport region HTR may also be included in the buffer layer. The electron blocking layer EBL is a layer serving to prevent or reduce electron injection from the electron transport region ETR to the hole transport region HTR.

In the light emitting element ED of an embodiment illustrated in FIG. 3 to FIG. 6, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto. The electron transport region ETR may have a single-layered structure having a single layer formed of a single material, a single-layered structure having a single layer formed of a plurality of different materials, or a multi-layered structure having a plurality of layers formed of a plurality of different materials.

For example, the electron transport region ETR may have a single-layered structure having a single layer of an electron injection layer EIL or an electron transport layer ETL, or a single-layered structure having a single layer formed of an electron injection material and an electron transport material. In some embodiments, the electron transport region ETR may have a single-layered structure having a single layer formed of a plurality of different materials, or have a structure of the electron transport layer ETL/the electron injection layer EIL, or a hole blocking layer HBL/the electron transport layer ETL/the electron injection layer EIL, sequentially stacked from the emission layer EML, but the embodiment of the present disclosure is not limited thereto. The thickness of the electron transport region ETR may be, for example, about 1000 Å to about 1500 Å.

The electron transport region ETR may be formed utilizing one or more suitable methods such as vacuum deposition, spin coating, casting, Langmuir-Blodgett (LB), inkjet printing, laser printing, and/or laser induced thermal imaging (LITI).

The electron transport region ETR may include a compound represented by Formula ET-1.

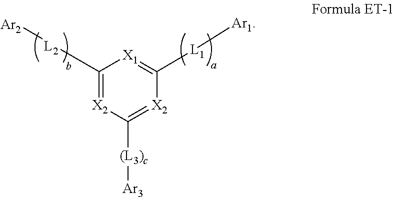

In Formula ET-1, at least one selected from among X₁ to X₃ is N, and the rest (substituents that are not N) are CRₐ. Rₐ may be a hydrogen atom, a deuterium atom, a substituted or unsubstituted alkyl group having 1 to 20 carbons, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbons, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each an integer of 2 or greater, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto. The electron transport region ETR may be, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), and/or one or more compounds or mixtures thereof.

In some embodiments, the electron transport region ETR may include a halogenated metal such as LiF, NaCl, CsF, RbCl, RbI, CuI, and KI, a lanthanum group metal such as Yb, or a co-deposition material of the above halogenated metal and the lanthanum group metal. For example, the electron transport region ETR may include KI:Yb, RbI:Yb, LiF:Yb, and/or the like as the co-deposition material. As the electron transport region ETR, a metal oxide such as Li₂O and BaO, or 8-hydroxyl-Lithium quinolate (Liq) and/or the like may be utilized, but the embodiment of the present disclosure is not limited thereto. The electron transport region ETR may also be composed of a mixture of an electron transport material and an insulating organo metal salt. The organo metal salt may be a material having an energy band gap of about 4 eV or greater. For example, the organo metal salt may include metal acetate, metal benzoate, metal acetoacetate, metal acetylacetonate, and/or metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen), but the embodiment of the present disclosure is not limited thereto.

The electron transport region ETR may include the above-described compounds of the electron transport region in at least one of the electron injection layer EIL, the electron transport layer ETL, or the hole blocking layer HBL.

When the electron transport region ETR includes the electron transport layer ETL, the thickness of the electron transport layer ETL may be about 100 Å to about 1000 Å, for example, about 150 Å to about 500 Å. When the thickness of the electron transport layer ETL satisfies the above-described range, satisfactory (suitable) electron transport properties may be obtained without a substantial increase in driving voltage. When the electron transport region ETR includes the electron injection layer EIL, the thickness of the electron injection layer EIL may be about 1 Å to about 100 Å, or about 3 Å to about 90 Å. When the thickness of the electron injection layer EIL satisfies the above-described range, satisfactory (suitable) electron injection properties may be obtained without a substantial increase in a driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode. The second electrode EL2 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, and/or one or more oxides thereof.

The second electrode EL2 may be a transmissive electrode, transflective electrode, or reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

When the second electrode EL2 is a transflective electrode or reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or one or more compounds or mixtures thereof (for example, AgMg, AgYb, or MgYb). In some embodiments, the second electrode EL2 may have a multi-layered structure including a reflective film or transflective film formed of the above exemplified materials, and a transparent conductive film formed of indium tin oxide (ITO), indium zinc oxide (IZO), zinc oxide (ZnO), indium tin zinc oxide (ITZO), and/or the like. For example, the second electrode EL2 may include any one of the above-described metal materials, a combination of two or more selected from the above-described metal materials, an oxide of any one of the above-described metal materials, and/or the like.

The second electrode EL2 may be connected to an auxiliary electrode. When the second electrode EL2 is connected to the auxiliary electrode, the resistance of the second electrode EL2 may be reduced.

On the second electrode EL2 of the light emitting element ED of an embodiment, the capping layer CPL may be further disposed. The capping layer CPL may include multilayers, or a single layer.

In an embodiment, the capping layer CPL may be an organic layer, or an inorganic layer. For example, when the capping layer CPL includes an inorganic substance, the inorganic substance may include an alkaline metal compound such as LiF, an alkaline earth metal compound such as MgF₂, SiON, SiNx, SiOy, and/or the like.

For example, when the capping layer CPL includes an organic substance, the organic substance may include a-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), and/or the like, and/or may include an epoxy resin, and/or an acrylate such as a methacrylate. However, the embodiment of the present disclosure is not limited thereto. The capping layer CPL may include at least one of the following compounds P1 to P5.

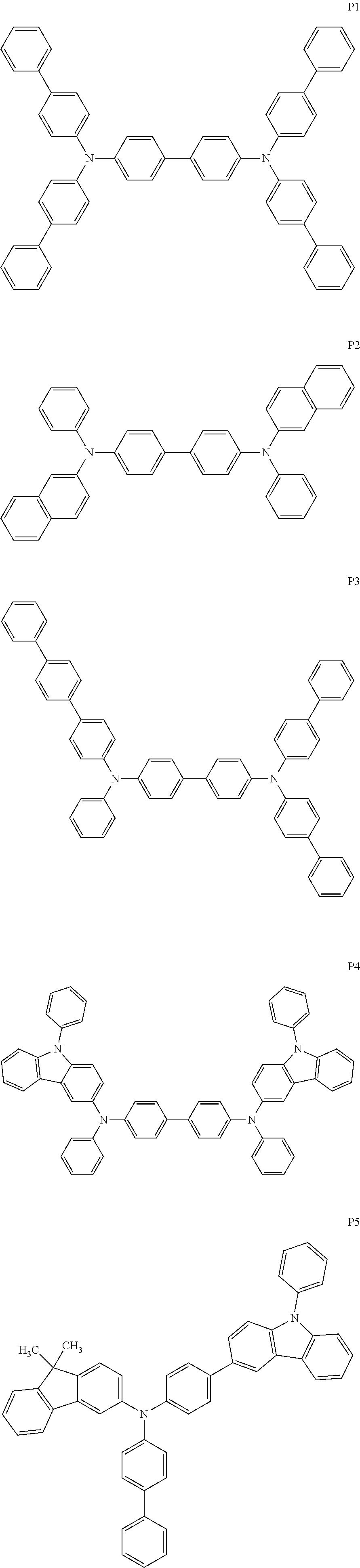 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

The refractive index of the capping layer CPL may be about 1.6 or more. For example, for light in a wavelength region of about 550 nm to about 660 nm, the refractive index of the capping layer CPL may be about 1.6 or more.

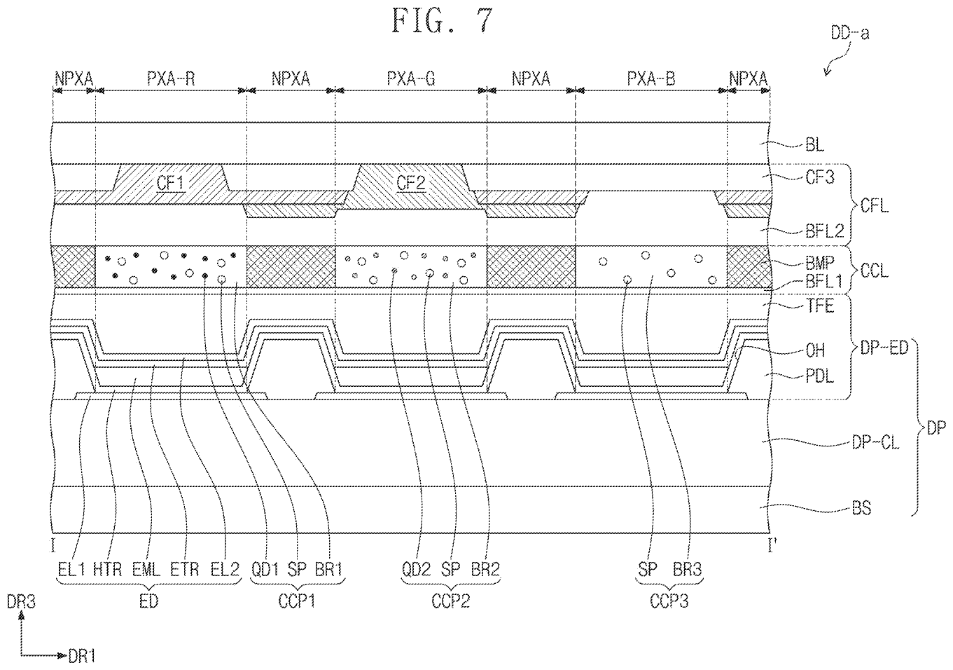

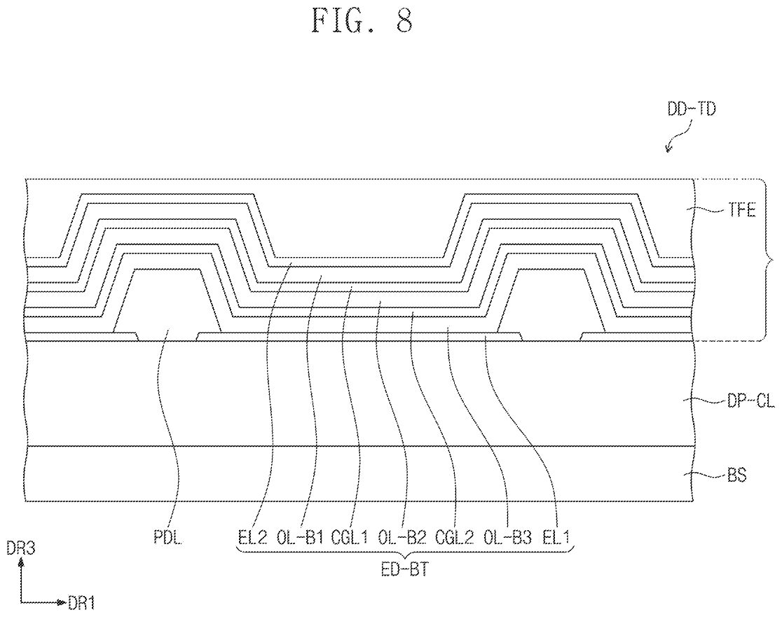

FIG. 7 and FIG. 8 are each a cross-sectional view of a display device according to an embodiment of the present disclosure. Hereinafter, in the description of a display device of an embodiment to be provided with reference to FIG. 7 and FIG. 8, the same contents/explanations as those described above with reference to FIG. 1 to FIG. 6 may not be repeated. Instead, the description will primarily focus on differences.

Referring to FIG. 7, a display device DD according to an embodiment may include a display panel DP including a display element layer DP-ED, a light control layer CCL on the display panel DP, and a color filter layer CFL. Referring to FIG. 7, the display panel DP may include a base layer BS, a circuit layer DP-CL provided on the base layer BS, and a display element layer DP-ED, and the display element layer DP-ED may include the light emitting element ED.

The light emitting element ED may include a first electrode EL1, a hole transport region HTR on the first electrode EL1, an emission layer EML on the hole transport region HTR, an electron transport region ETR on the emission layer EML, and a second electrode EL2 on the electron transport region ETR. The structure of a light emitting element of FIG. 3 to FIG. 6 described above may be applied the same to the structure of the light emitting element ED illustrated in FIG. 7.

Referring to FIG. 7, the emission layer EML may be disposed inside an opening OH defined on a pixel definition film PDL. For example, the emission layer EML separated by the pixel definition film PDL and provided corresponding to each light emitting region PXA-R, PXA-G, and PXA-B may emit (e.g., may each emit) light of the same wavelength region. In the display device DD an embodiment, the emission layer EML may emit blue light. The emission layer EML may be provided as a common layer to all of the light emitting regions PXA-R, PXA-G, and PXA-B.

The light control layer CCL may be on the display panel DP. The light control layer CCL may include a light converting body. The light converting body may be a quantum dot or a fluorescent body, and/or the like. The light converting body may wavelength-convert provided light and emit the same. For example, the light control layer CCL may be a layer including a quantum dot, or a layer including a fluorescent body.

The light control layer CCL may include a plurality of light control units CCP1, CCP2, and CCP3. The light control units CCP1, CCP2, and CCP3 may be spaced apart from (separated from) each other.

Referring to FIG. 7, a dividing pattern BMP may be between the light control units CCP1, CCP2, and CCP3 spaced apart from (separated from) each other, but the embodiment of the present disclosure is not limited thereto. In FIG. 7, the dividing pattern BMP is illustrated as not overlapping the light control units CCP1, CCP2, and CCP3, but edges of the light control units CCP1, CCP2, and CCP3 may overlap at least a portion of the dividing pattern BMP.

The light control layer CCL may include a first light control unit CCP1 including a first quantum dot QD1 configured to convert a first color light provided from the light emitting element ED to a second color light, a second light control unit CCP2 including a second quantum dot QD2 configured to convert the first color light to a third color light, and a third light control unit CCP3 configured to transmit the first color light. In an embodiment, the first light control unit CCP1 may provide red light, which is the second color light, and the second light control unit CCP2 may provide green light, which is the third color light. The third light control unit CCP3 may transmit and provide blue light which is the first color light provided from the light emitting element ED. For example, the first quantum dot QD1 may be a red quantum dot, and the second quantum dot QD2 may be a green quantum dot. The same contents/explanations as those described above may be applied to the quantum dots QD1 and QD2.

In some embodiments, the light control layer CCL may further include a scattering body SP. The first light control unit CCP1 may include the first quantum dot QD1 and the scattering body SP, the second light control unit CCP2 may include the second quantum dot QD2 and the scattering body SP, and the third light control unit CCP3 may not include (e.g., may exclude) a quantum dot but include the scattering body SP.

The scattering body SP may be an inorganic particle. For example, the scattering body SP may include at least one of TiO₂, ZnO, Al₂O₃, SiO₂, or hollow silica. The scattering body SP may include any one selected from among TiO₂, ZnO, Al₂O₃, SiO₂, and hollow silica, or may be a mixture of two or more materials selected from among TiO₂, ZnO, Al₂O₃, SiO₂, and hollow silica.

Each of the first light control unit CCP1, the second light control unit CCP2, and the third light control unit CCP3 may include base resins BR1, BR2, and BR3 which disperse the quantum dots QD1 and QD2 and the scattering body SP. In an embodiment, the first light control unit CCP1 may include the first quantum dot QD1 and the scattering body SP dispersed in a first base resin BR1, the second light control unit CCP2 may include the second quantum dot QD2 and the scattering body SP dispersed in a second base resin BR2, and the third light control unit CCP3 may include the scattering body SP dispersed in a third base resin BR3. The base resins BR1, BR2, and BR3 are media in which the quantum dots QD1 and QD2 and the scattering body SP are dispersed, and may be formed of one or more suitable resin compositions which may be generally referred to as a binder. For example, the base resins BR1, BR2, and BR3 may each be an acrylic resin, a urethane-based resin, a silicone-based resin, an epoxy resin, and/or the like. The base resins BR1, BR2, and BR3 may each be a transparent resin. In an embodiment, the first base resin BR1, the second base resin BR2, and the third base resin BR3 may be the same or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the light control units CCP1, CCP2, CCP3 from being exposed to moisture/oxygen. The barrier layer BFL1 may cover the light control units CCP1, CCP2, and CCP3. In some embodiments, a barrier layer BFL2 may be provided between the light control units CCP1, CCP2, CCP3 and the color filter layer CFL.

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and/or silicon oxynitride, and/or a thin metal film having light transmittance, and/or the like. The barrier layers BFL1 and BFL2 may further include an organic film. The barrier layers BFL1 and BFL2 may be formed of a single layer or a plurality of layers.

In the display device DD of an embodiment, the color filter layer CFL may be on the light control layer CCL. For example, the color filter layer CFL may be directly on the light control layer CCL. In this embodiment, the barrier layer BFL2 may not be provided.

The color filter layer CFL may include filters CF1, CF2, and CF3. The color filter layer CFL may include a first filter CF1 for transmitting the second color light, a second filter CF2 for transmitting the third color light, and a third filter CF3 for transmitting the first color light. For example, the first filter CF may be a red filter, the second filter CF2 may be a green filter, and the third filter CF3 may be a blue filter. Each of the filters CF1, CF2, and CF3 may include a polymer photosensitive resin and a pigment or dye. The first filter CF1 may include a red pigment and/or a red dye, the second filter CF2 may include a green pigment and/or a green dye, and the third filter CF3 may include a blue pigment and/or a blue dye. The embodiment of the present disclosure is not limited thereto. The third filter CF3 may not include (e.g., may exclude) any pigment or dye. The third filter CF3 may include a polymer photosensitive resin but may not include (e.g., may exclude) any pigment or dye. The third filter CF3 may be transparent. The third filter CF3 may be formed of a transparent photosensitive resin.

In some embodiments, in an embodiment, the first filter CF1 and the second filter CF2 may be a yellow filter. The first filter CF1 and the second filter CF2 may be provided as one body without being distinguished from each other. The first to third filters CF1, CF2, and CF3 may be disposed corresponding to a red light emitting region PXA-R, a green light emitting region PXA-G, and a blue light emitting region PXA-B, respectively.

The color filter layer CFL may further include a light blocking part. The light blocking part may be a black matrix. The light blocking part may be formed by including an organic light blocking material or an inorganic light blocking material which includes a black pigment and/or a black dye. The light blocking part may prevent or reduce a light leakage phenomenon, and distinguish boundaries between adjacent filters CF1, CF2, and CF3.

On the color filter layer CFL, a base substrate BL may be disposed. The base substrate BL may be a member which provides a base surface on which the color filter layer CFL, the light control layer CCL, and/or the like are disposed. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In some embodiments, the base substrate BL may not be provided in an embodiment.

FIG. 8 is a cross-sectional view showing a portion of a display device according to an embodiment of the present disclosure. FIG. 8 illustrates a cross-sectional view of a portion corresponding to the display panel DP of FIG. 7. In a display device DD-TD of an embodiment, a light emitting element ED-BT may include a plurality of light emission structures OL-B1, OL-B2, and OL-B3. The light emitting element ED-BT may include a first electrode EL1 and a second electrode EL2 facing each other, and the plurality of light emission structures OL-B1, OL-B2, and OL-B3 sequentially stacked and provided in a thickness direction between the first electrode EL1 and the second electrode EL2. Each of the light emission structures OL-B1, OL-B2, and OL-B3 may include the emission layer EML (see FIG. 7), and a hole transport region HTR and an electron transport region ETR disposed with the emission layer EML (see FIG. 7) interposed therebetween. For example, the light emitting element ED-BT included in the display device DD-TD of an embodiment may be a light emitting element of a tandem structure including a plurality of emission layers.

In the embodiment illustrated in FIG. 8, light emitted from each of the light emission structures OL-B1, OL-B2, and OL-B3 may all be blue light. However, the embodiment of the present disclosure is not limited thereto, and the wavelength region of light emitted from each of the light emission structures OL-B1, OL-B2, and OL-B3 may be different from each other. For example, the light emitting element ED-BT including a plurality of light emission structures OL-B1, OL-B2, and OL-B3 emitting light of different wavelength regions may emit white light (e.g., combined white light).

Between adjacent light emission structures OL-B1, OL-B2, and OL-B3, charge generation layers CGL1 and CGL2 may be disposed. The charge generation layers CGL1 and CGL2 may include a p-type or kind charge generation layer (e.g., a P-charge generation layer) and/or an n-type or kind charge generation layer (e.g., a N-charge generation layer).

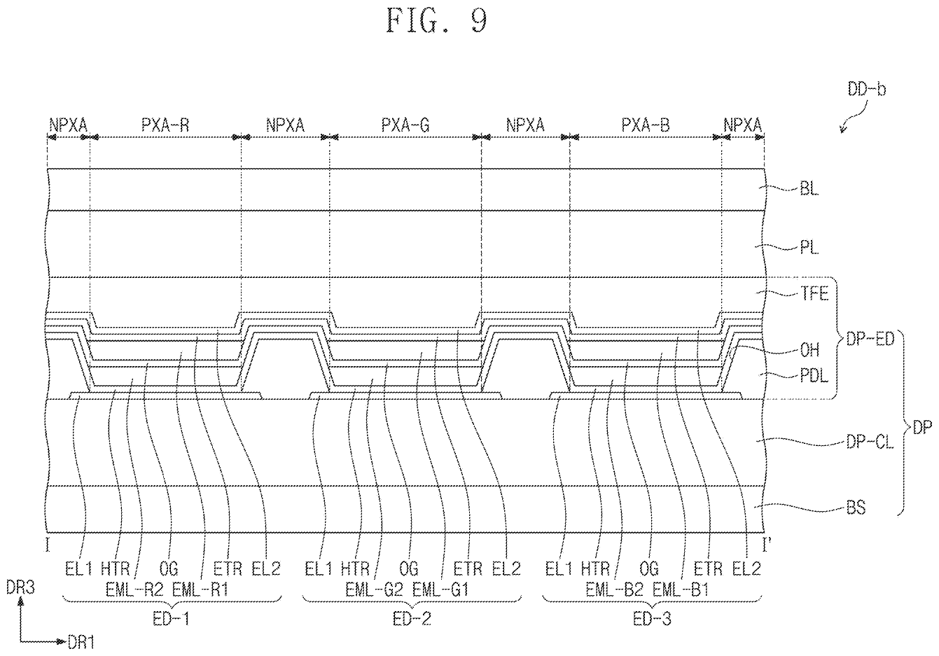

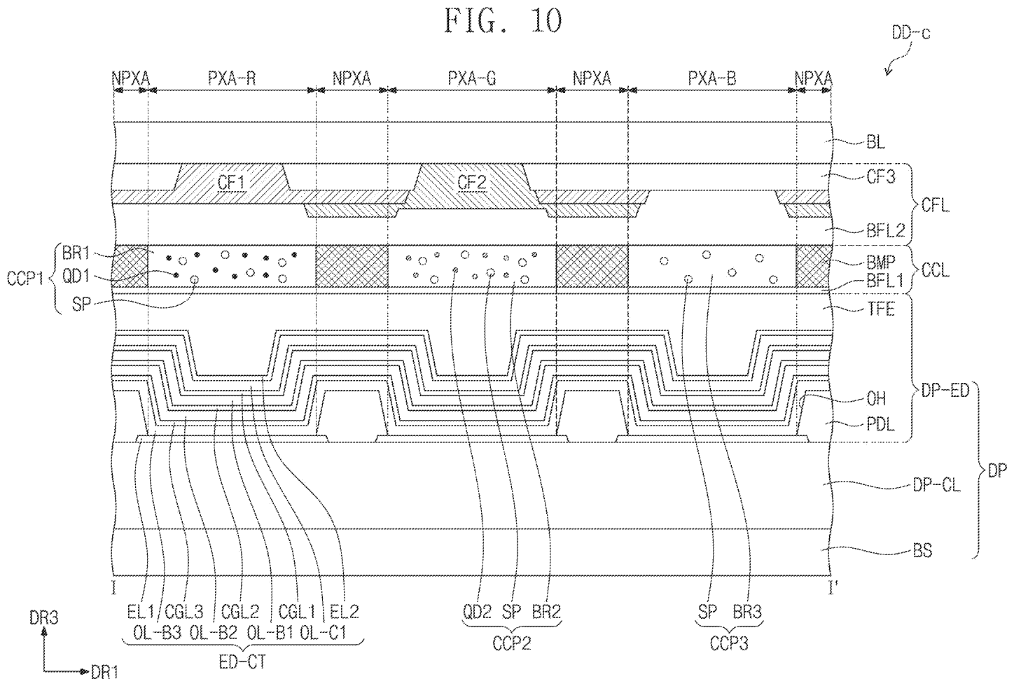

Referring to FIG. 9, a display device DD-b according to an embodiment may include light emitting elements ED-1, ED-2, and ED-3 in which two emission layers are stacked. When compared to the display device DD of an embodiment illustrated in FIG. 2, there is a difference with the embodiment illustrated in FIG. 9 in that each of first to third light emitting elements ED-1, ED-2, and ED-3 includes two emission layers stacked in a thickness direction. In each of the first to third light emitting elements ED-1, ED-2, and ED-3, the two emission layers may emit light of the same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. For example, at least one of the first blue emission layer EML-B1 or the second blue emission layer EML-B2 may include the organometallic compound of an embodiment. Between the first red emission layer EML-R1 and the second red emission layer EML-R2, between the first green emission layer EML-G1 and the second green emission layer EML-G2, and between the first blue emission layer EML-B1 and the second blue emission layer EML-B2, a light emitting auxiliary unit OG may be disposed.

The light emitting auxiliary unit OG may include a single layer or multiple layers. The light emitting auxiliary unit OG may include a charge generation layer. For example, the light emitting auxiliary unit OG may include an electron transport region, a charge generation layer, and a hole transport region sequentially stacked. The light emitting auxiliary unit OG may be provided a common layer throughout the first to third light emitting elements ED-1, ED-2, and ED-3. However, the embodiment of the present disclosure is not limited thereto. The light emitting auxiliary unit OG may be patterned and provided in the opening OH defined on the pixel definition film PDL.

The first red emission layer EML-R1, the first green emission layer EML-G1, and the first blue emission layer EML-B1 may be between a hole transport region HTR and a light emitting auxiliary unit OG. The second red emission layer EML-R2, the second green emission layer EML-G2, and the second blue emission layer EML-B2 may be between the light emitting auxiliary unit OG and an electron transport region ETR.

For example, the first light emitting element ED-1 may include a first electrode EL1, a hole transport region HTR, the second red emission layer EML-R2, a light emitting auxiliary unit OG, the first red emission layer EML-R1, an electron transport region ETR, and a second electrode EL2 sequentially stacked (in the stated order). The second light emitting element ED-2 may include a first electrode EL1, a hole transport region HTR, the second green emission layer EML-G2, a light emitting auxiliary unit OG, the first green emission layer EML-G1, an electron transport region ETR, and a second electrode EL2 sequentially stacked. The third light emitting element ED-3 may include a first electrode EL1, a hole transport region HTR, the second blue emission layer EML-B2, a light emitting auxiliary unit OG, the first blue emission layer EML-B1, an electron transport region ETR, and a second electrode EL2 sequentially stacked.

On the display element layer DP-ED, an optical auxiliary layer PL may be disposed. The optical auxiliary layer PL may include a polarizing layer. The optical auxiliary layer PL may be disposed on the display panel DP to control reflective light in the display panel DP caused by external light. Alternatively, in a display device of an embodiment, the optical auxiliary layer PL may not be provided.

Unlike FIG. 8 and FIG. 9, FIG. 10 illustrates that a display device DD-c includes four light emission structures OL-B1, OL-B2, OL-B3, and OL-C1. A light emitting element ED-CT may include a first electrode EL1 and a second electrode EL2 facing each other, and first to fourth light emission structures OL-B1, OL-B2, OL-B3, and OL-C1 sequentially stacked in a thickness direction between the first electrode EL1 and the second electrode EL2. Between the first to fourth light emission structures OL-B1, OL-B2, OL-B3, and OL-C1, charge generation layers CGL1, CGL2, and CGL3 may be disposed. The charge generation layers CGL1, CGL2, and CGL3 may include a p-type or kind charge generation layer and/or an n-type or kind charge generation layer.

Among the four light emission structures, the first to third light emission structures OL-B1, OL-B2, and OL-B3 may emit blue light, and the fourth light emission structure OL-C1 may emit green light. For example, at least one of the first to third light emission structures OL-B1, OL-B2, or OL-B3 may include the organometallic compound of an embodiment. However, the embodiment of the present disclosure is not limited thereto, and the first to fourth light emission structures OL-B1, OL-B2, OL-B3, and OL-C1 may emit light of different wavelength regions.

Hereinafter, referring to Examples and Comparative Examples, an organometallic compound according to an embodiment of the present disclosure, and a light emitting element of an embodiment will be described in more detail. In some embodiments, Examples below are for illustrative purposes only to facilitate the understanding of the present disclosure, and thus, the scope of the present disclosure is not limited thereto.

### Examples

### 1. Synthesis of Organometallic Compound of Example

First, a method for synthesizing an organometallic compound according to an embodiment of the present disclosure will be described in more detail with reference to methods for synthesizing compounds PBD-1 and PBD-3. In some embodiments, the method for synthesizing an organometallic compound described hereinafter is merely an example, and the method for synthesizing a compound according to an embodiment of the present disclosure is not limited to the following example.

### (1) Synthesis of Compound PBD-1

An organometallic compound PBD-1 according to an embodiment may be synthesized by steps of Reaction Equation 1 to Reaction Equation 3.

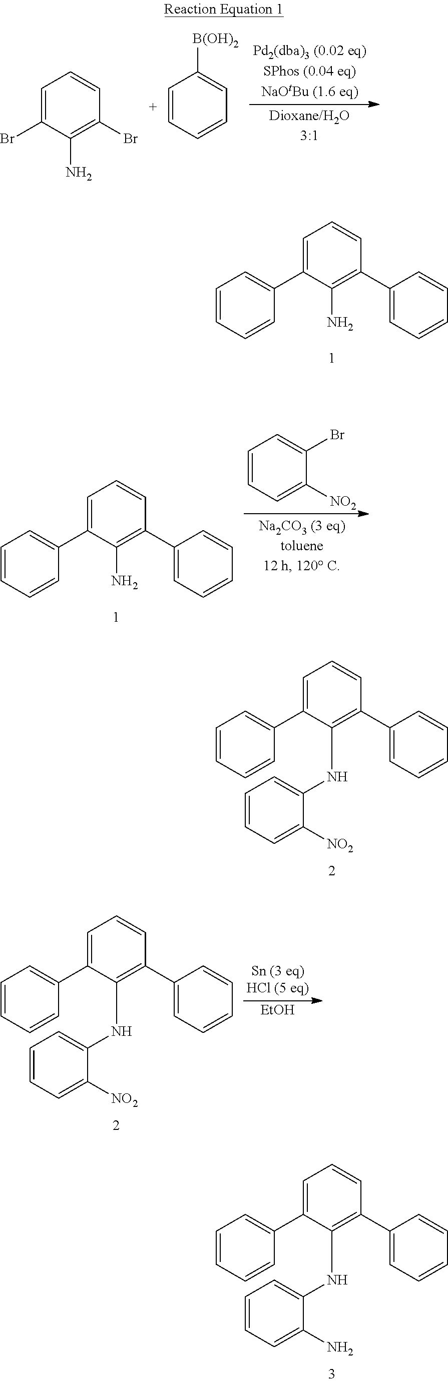

### Synthesis of Intermediate 1

2,6-dibromoaniline (20 g, 1 eq), Pd₂(dba)₃ (0.02 eq), NaOtBu (1.6 eq), and SPhos (0.04 eq) were placed in a round flask, and dioxane/H₂O (3:1, 120 mL) was added thereto and stirred. Phenylboronic acid (2.2 eq) was added thereto, and then refluxed and stirred for 12 hours. After the completion of the reaction, the reactant was subjected to silica filtration with methylene chloride, and then the solvent was removed. After column purification with Mc:Hx (methylene chloride:hexane=1:3) followed drying, Intermediate 1 (yield 89%) was synthesized. (C₁₈H₁₅N [M]+: Calculated: 245.1, Measured: 244)

### Synthesis of Intermediate 2

In a round-bottom flask, Intermediate 1 (20 g, 1 eq), and Na₂CO₃ (3 eq) were added and dissolved in 120 mL of toluene. A 2 M solution in which 1-bromo nitrobenzene (1.2 eq) is dissolved in toluene was added dropwise for 10 minutes, followed by stirring at 120° C. for 12 hours. After the completion of the reaction, H₂O was added for quenching, and then methylene chloride was added thereto, followed by separating only the organic layer utilizing a separatory funnel. Drying was performed with magnesium sulfate (MgSO₄), and after column purification with MC:EA (methylene chloride:ethyl acetate=2:1) followed by drying, Intermediate 2 (yield 78%) was synthesized. (C₂₄H₄₈N₂O₂ [M]+: Calculated: 366.1, Measured: 365)

### Synthesis of Intermediate 3

In a round-bottom flask, Intermediate 2 (20 g, 1 eq), Sn (3 eq), and HCl (5 eq) were added and dissolved in 200 mL of ethanol. After refluxing and stirring for 6 hours, 100 mL of 1 M solution of NH₄OH was added for quenching. The reactant was subjected to silica filtration with methylene chloride, and then the solvent was removed. Drying was performed with magnesium sulfate, and after column purification with MC (methylene chloride):Hx (1:1) followed by drying, Intermediate 3 (yield 88%) was synthesized. (C₂₄H₂₀N₂ [M]+: Calculated: 336.1, Measured: 335)

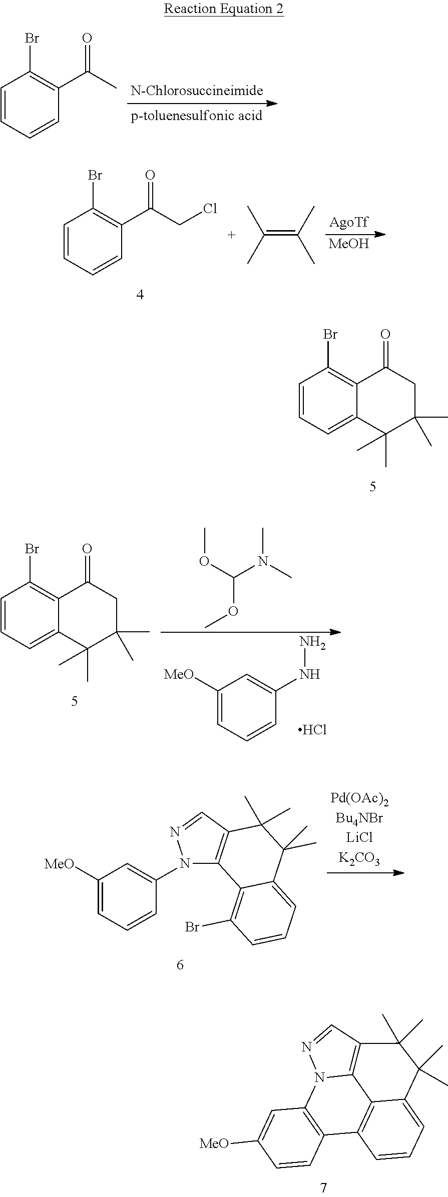

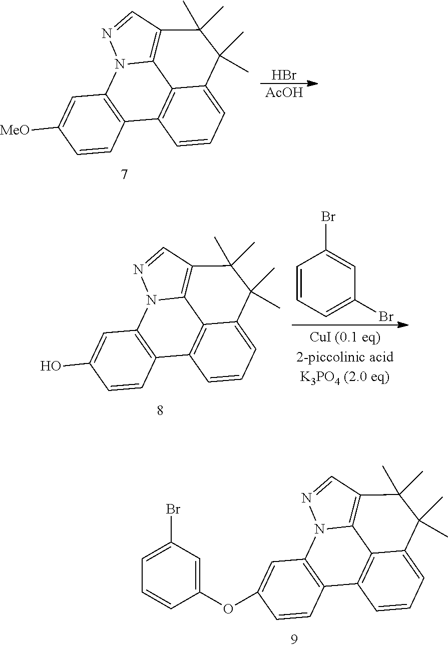

### Synthesis of Intermediate 4

In a round-bottom flask, 2-bromoacetophenone (10 g, 1 eq) was added and dissolved in p-toluenesulfonic acid (100 mL). After creating a dark condition, N-chlorosuccineimide (1.2 eq) was added thereto and stirred for 4 hours. After the completion of the reaction, H₂O and EA were added for quenching, and then only the organic layer was separated utilizing a separatory funnel. Drying was performed with magnesium sulfate, and after column purification with MC:EA (2:1) followed by drying, Intermediate 4 (yield 88%) was synthesized. (C₈H₆BrClO [M]+: Calculated: 231.9, Measured: 231)

### Synthesis of Intermediate 5

In a round-bottom flask, Intermediate 4 (10 g, 1 eq) and silver trifluoromethanesulfonate (AgOTf) (0.1 eq) were dissolved in methanol (75 mL). 2,3-dimethyl-2-butene (1.1 eq) was added thereto, and then a freeze-pump-thaw process was performed 3 times to completely remove air, followed by irradiating light utilizing a 350 nm UV light. After 24 hours, the reaction mixture was concentrated, and then after column purification with n-pentane followed drying, Intermediate 5 (yield 52%) was synthesized. (C₁₄H₁₇BrO [M]+: Calculated: 280.1, Measured: 279)

### Synthesis of Intermediate 6

In a round-bottom flask, Intermediate 5 (10 g) and 1,1-dimethoxy-N,N-dimethylmethanamine (2 eq) were dissolved in tetrahydrofuran (THF). (3-methoxyphenyl)hydrazine hydrochloride (1.2 eq) was added thereto, and then refluxed and stirred for 12 hours. After the completion of the reaction, ethyl acetate/H₂O was added thereto and stirred for 30 minutes, followed by separating only the organic layer utilizing a separatory funnel. After drying with magnesium sulfate, silica filtration was performed with methylene chloride, and then the resulting solid was filtered utilizing methanol and then dried. The dried solid was boiled and dissolved in toluene (100 mL), and then ether:hexane=1:2 (100 mL) was added dropwise for solidification. Again, the solid was dissolved in methylene chloride (400 mL), and then slowly recrystallized by adding hexane (400 mL) to synthesize Intermediate 6 (yield 30%). (C₂₂H₂₃BrN₂O [M]+: Calculated: 410.1, Measured: 409)

### Synthesis of Intermediate 7

In a round-bottom flask, Intermediate 6 (10 g), K₂CO₃ (2.0 eq), LiCl (1.05 eq), nBu₄NBr (1.1 eq), and Pd(OAc)₂ (0.05 eq) were added and dissolved in N,N-dimethylformamide (DMF) (200 mL). After being stirred at 110° C. for 18 hours, the mixture solution was placed in ice/water (500 mL). Diethyl ether was added thereto, and then only the organic layer was separated utilizing a separatory funnel, followed by drying utilizing magnesium sulfate. The dried solid was dissolved in a small amount (a quantity sufficient to dissolve the solid) of THF, and after column purification with MC:Hx (1:2) followed by drying, Intermediate 7 (yield 85%) was synthesized. (C₂₂H₂₂N₂O [M]+: Calculated: 330.2, Measured: 329)

### Synthesis of Intermediate 8

In a round-bottom flask, Intermediate 7 (10 g) and hydrobromic acid (50 mL, 48%) were added and dissolved in acetic acid. The mixture was refluxed and stirred for 2 days, and then cooled to room temperature. The residual solvent was removed, and a K₂CO₃ solution was added for neutralization. The precipitate was filtered, washed with water, and then dried to synthesize Intermediate 8 (yield 91%). (C₂₁H₂₀N₂O [M]+: Calculated: 316.2, Measured: 315)

### Synthesis of Intermediate 9

In a round-bottom flask, Intermediate 8 (10 g), 1,3-dibromobenzene (1.2 eq), CuI (0.1 eq), 2-picolinic acid (1.1 eq), K₃PO₄ (2.0 eq), and THF (400 mL) were added, and then refluxed and stirred overnight. After the completion of the reaction, ethyl acetate/H₂O was added thereto and stirred for 30 minutes, followed by separating only the organic layer utilizing a separatory funnel. After drying with magnesium sulfate, silica filtration was performed with methylene chloride, and then the resulting solid was filtered utilizing methanol and then dried. The dried solid was boiled and dissolved in toluene (100 mL), and then ether:hexane=1:1 (100 mL) was added dropwise for solidification. Again, the solid was dissolved in methylene chloride (400 mL), and then slowly recrystallized by adding hexane (400 mL) to synthesize Intermediate 9 (yield 85%). (C₂₇H₂₃BrN₂O [M]+: Calculated: 470.1, Measured: 469)

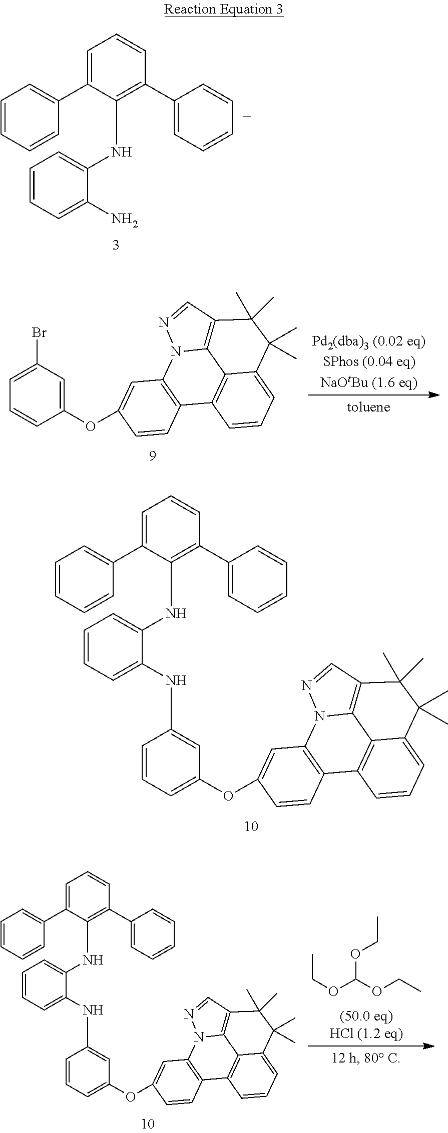

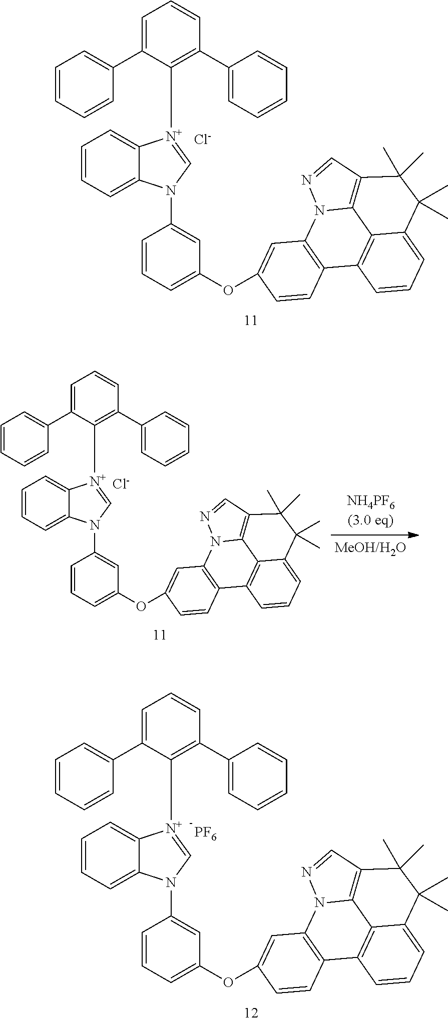

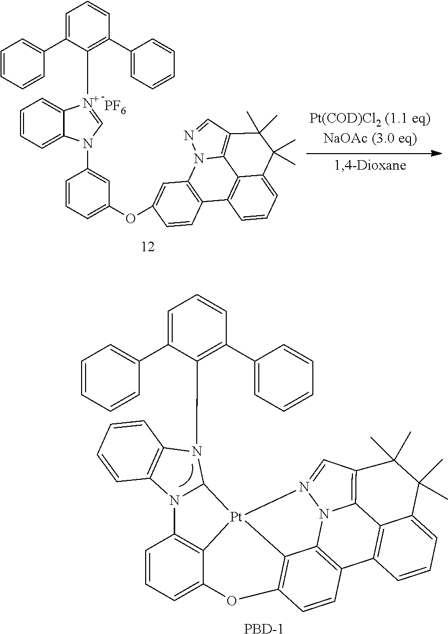

### Synthesis of Intermediate 10

In a round-bottom flask, Intermediate 3 (8 g), Intermediate 9 (1.0 eq), tris(dibenzylideneacetone)dipalladium(0) (Pd₂(dba)₃, 0.02 eq), SPhos (0.04 eq), NaOtBu (1.6 eq), and toluene (100 mL) were added, and then refluxed (120° C.). After being stirred for 4 hours, the reactant was subjected to silica filtration with methylene chloride, and then the solvent was removed. After column purification with hexane:methylene chloride (4:1) and solidification with methanol, the reactant was filtered and dried to synthesize Intermediate 10 (yield 80%). (C₅₁H₄₂N₄O [M]+: Calculated: 726.3, Measured: 725)

### Synthesis of Intermediate 11

In a round-bottom flask, Intermediate 10 (7 g) and triethoxyethane (50 eq) were dissolved in THF. HCl (1 M solution, 1.2 eq) was added thereto, and then refluxed (80° C.) and stirred for 12 hours. After the completion of the reaction, ethyl acetate/H₂O was added thereto and stirred for 30 minutes, followed by separating only the organic layer utilizing a separatory funnel. After drying with magnesium sulfate, silica filtration was performed with methylene chloride, and then the resulting solid was filtered utilizing methanol and then dried. The dried solid was boiled and dissolved in toluene (100 mL) and then ether:hexane=1:2 (100 mL) was added dropwise for solidification. Again, the solid was dissolved in methylene chloride (400 mL), and then slowly recrystallized by adding hexane (400 mL) to synthesize Intermediate 11 (yield 90%). (C₅₂H₄₁ClN₄O [M]+: Calculated: 772.3, Measured: 771)

### Synthesis of Intermediate 12

In a round-bottom flask, Intermediate 11 (5 g) was dissolved in methanol/H₂O (2:1, 100 mL), and then NH₄PF₆ (ammonium hexafluorophosphate, 3.0 eq) was added thereto. After stirring at room temperature for 4 hours, H₂O was added and stirred, and then the resulting solid was filtered. Thereafter, the dried solid was dissolved in methylene chloride to remove the solvent after magnesium sulfate treatment. After silica filtration with methylene chloride, the solvent was removed, and then after solidification with methanol and drying, Intermediate 12 (yield 95%) was synthesized. (C₅₂H₄₁F₆N₄OP [M]+: Calculated: 882.3, Measured: 881)

### Synthesis of Compound PBD-1

In a round-bottom flask, Intermediate 12 (4 g), Pt(COD)Cl₂ (1.1 eq), and NaOAc (3.0 eq) were dissolved in 1,4-dioxane (50 mL), and then refluxed for 96 hours. H₂O was added thereto and stirred, and then the resulting solid was filtered. After washing three times with H₂O, the dried solid was subjected to column purification utilizing MC:Hx (1:1) to synthesize Compound PBD-1 (yield 30%). (C₅₂H₃₉N₄OPt [M]+: Calculated: 930.3, Measured: 929) (Elemental Analysis for calcd: C, 67.09; H, 4.22; N, 6.02; 0, 1.72; Pt, 20.95)

### (2) Synthesis of Compound PBD-3

An organometallic compound PBD-3 according to an embodiment may be synthesized by steps of Reaction Equation 4.

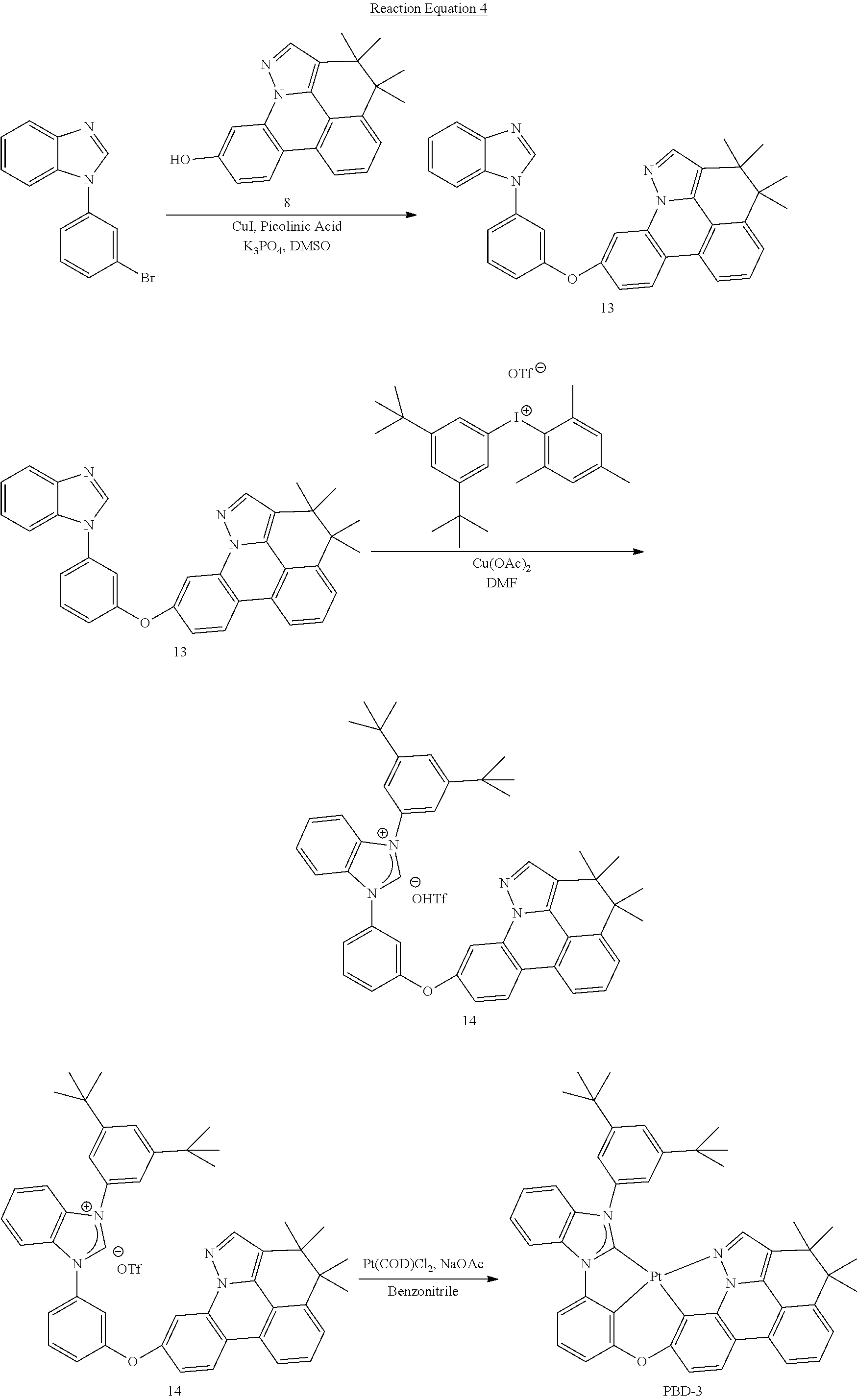

### Synthesis of Intermediate 13

In a round-bottom flask, 1-(3-bromophenyl)-1H-benzo[d]imidazole (5 g), Intermediate 8 (1.1 eq), CuI (0.2 eq), picolinic acid (0.4 eq), and K₃PO₄ (3 eq) were added and dissolved in 150 mL of dimethyl sulfoxide (DMSO). The mixture was stirred at 120° C. for 12 hours, cooled to room temperature, and then added with a NH₄Cl saturated aqueous solution and EA, followed by separating only the organic layer utilizing a separatory funnel. Drying was performed with magnesium sulfate, and after column purification with Mc:Hx (1:1), Intermediate 13 (yield 65%) was synthesized. (C₃₄H₂₈N₄O [M]+: Calculated: 508.2, Measured: 507)

### Synthesis of Intermediate 14

In a round-bottom flask, Intermediate 13 (5 g), (3,5-di-tert-butylphenyl)(mesityl)iodonium triflate (1.5 eq), and copper acetate (Cu(OAc)₂, 0.1 eq) were added and dissolved in 100 mL of DMF. The mixture was stirred at 110° C. for 6 hours, cooled to room temperature, and then added with a NH₄Cl saturated aqueous solution and EA, followed by separating only the organic layer utilizing a separatory funnel. Drying was performed with magnesium sulfate, and after column purification with Mc:Hx (2:1), Intermediate 14 (yield 82%) was synthesized. (C₄₈H₅₁N₄O [M]+: Calculated: 699.4, Measured: 698)

### Synthesis of Compound PBD-3

In a round-bottom flask, Intermediate 14 (4 g), Pt(COD)Cl₂ (1.1 eq), and NaOAc (3.0 eq) were dissolved in benzonitrile (50 ml), and then refluxed (180° C.) for 96 hours. H₂O was added thereto and stirred, and then the resulting solid was filtered. After washing three times with H₂O, the dried solid was subjected to column purification utilizing MC:Hx (1:1) to synthesize Compound PBD-3 (yield 50%). (C₄₈H₄₇N₄OPt [M]+: Calculated: 890.3, Measured: 889) (Elemental Analysis for calcd: C, 64.70; H, 5.32; N, 6.29; 0, 1.80; Pt, 21.89)

### 2. Manufacturing and Evaluation of Light Emitting Element

### (1) Manufacturing of Light Emitting Element

A light emitting element including the organometallic compound of an embodiment or a Comparative Example compound in a emission layer was manufactured by the following method. Light emitting elements of Examples 1 to 4 were respectively manufactured utilizing Compounds PBD-1 and PBD-3, each of which is the organometallic compound of an embodiment, as a dopant material of a emission layer. Light emitting elements of Comparative Examples 1 and 2 were manufactured utilizing Comparative Example compound D1 as a dopant material of a emission layer.

As a first electrode, an ITO glass substrate was cut to a size of 50 mm×50 mm×0.5 mm, and ultrasonically cleaned for 10 minutes each utilizing isopropyl alcohol and pure water, and then irradiated with ultraviolet rays for 10 minutes and exposed to ozone to be cleaned. The glass substrate was installed in a vacuum deposition device.

m-MTDATA was vacuum deposited in an upper portion of the substrate to a thickness of about 40 Å to form a hole injection layer, and then, NPB was vacuum deposited to a thickness of about 10 Å to form a hole transport layer. In an upper portion of the hole transport layer, a hole transporting host material, an electron transporting host material, and a dopant were concurrently (e.g., simultaneously) deposited at a weight ratio of 4.5:4.5:1 to form a emission layer to a thickness of about 400 Å. As the hole transporting host material, HTH-1, or HTH-2, which are the compounds of the present disclosure, was utilized, and as the electron transporting host material, ETH-1, or ETH-2, which are the compounds of the present disclosure, was utilized.

In an upper portion of the emission layer, ETL1 was deposited to a thickness of about 300 Å to form an electron transport layer, and Al was deposited to a thickness of about 1200 Å to form a second electrode.

Materials Utilized when Manufacturing Light Emitting Elements

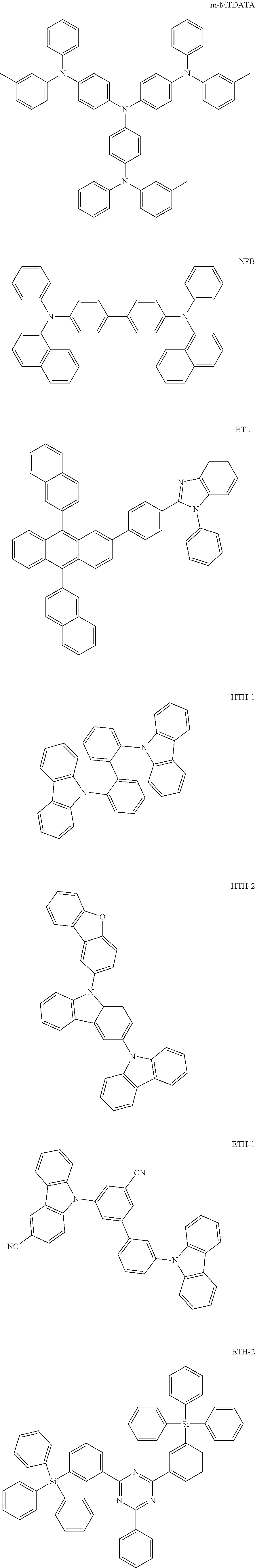

Compounds of Examples and Comparative Examples utilized in Examples 1 to 4, and Comparative Examples 1 and 2 are shown in Table 1.

TABLE 1
222891/411598

| Comparative Example compounds D1 | 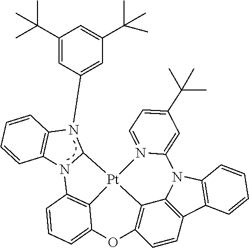 | D1 | — | | |
|---|---|---|---|---|---|
| Compound PBD-1 | 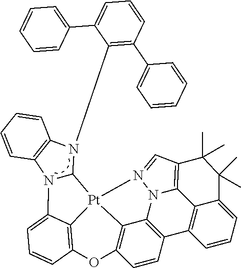 | PBD-1 | Compound PBD-3 | 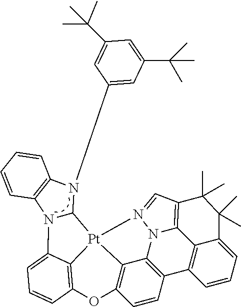 | PBD-3 |

### (2) Evaluation of Properties of Light Emitting Element

Table 2 shows the evaluation of lifespan (T₉₀) for the light emitting elements of Examples and Comparative Examples. The lifespan (T₉₀) is the measurement of time taken to decrease to 90% of the initial luminance. The current density at 1000 cd/m² of the light emitting element of each of Examples and Comparative Examples was measured utilizing Keithley MU 236 and a luminance meter PR650, and then the change in luminance was measured utilizing a photodiode while applying a corresponding current to measure the lifespan of the element.

TABLE 2

| Example of | Hole | Electron | | |
|---|---|---|---|---|
| manufacturing | transporting | transporting | | Lifespan |
| element | host | host | Dopant | (T₉₀, hr) |
| Example 1 | HTH-1 | ETH-1 | Compound | 24 |
| | | | PBD-1 | |
| Example 2 | HTH-2 | ETH-2 | Compound | 30 |
| | | | PBD-1 | |
| Example 3 | HTH-1 | ETH-1 | Compound | 19 |
| | | | PBD-3 | |
| Example 4 | HTH-2 | ETH-2 | Compound | 22 |
| | | | PBD-3 | |
| Comparative | HTH-1 | ETH-1 | Comparative | 11 |
| Example 1 | | | Example | |
| | | | compound D1 | |
| Comparative | HTH-2 | ETH-2 | Comparative | 16 |
| Example 2 | | | Example | |
| | | | compound D1 | |

Referring to Table 2, when compared to the light emitting elements of Comparative Examples 1 and 2, it can be seen that the light emitting elements of Examples 1 to 4 each relatively have an excellent or suitable lifespan. The light emitting elements of Comparative Examples 1 and 2 each exhibit a lifetime of 6 hours or less, and the light emitting elements of Examples 1 to 4 each exhibit a lifetime of 19 hours or more. Each of the light emitting elements of Examples 1 to 4 includes Compound PBD-1 or PBD-3, and Compound PBD-1 and PBD-3 are each the organometallic compound of an embodiment. The organometallic compound of an embodiment includes a substituted carbene imidazole group and a substituted pyrazole group, and a substituent of the substituted pyrazole group may be coupled to a substituent of an adjacent phenyl group to form a condensed ring. Accordingly, the organometallic compound of an embodiment may have improved material stability. In some embodiments, a light emitting element including the organometallic compound of an embodiment may exhibit long lifespan properties.

The light emitting elements of Comparative Examples 1 and 2 include Comparative Example compound D1 as a dopant material, and Comparative Example compound D1 does not include a pyrazole group. Accordingly, it is determined that the light emitting elements of Comparative Examples 1 and 2 including Comparative Example compound D1 each did not relatively have an improved lifespan.

A light emitting element of an embodiment may include a first electrode, a second electrode on the first electrode, and a emission layer between the first electrode and the second electrode. The emission layer may include an organometallic compound of an embodiment. The organometallic compound of an embodiment includes a substituted carbene imidazole group and a substituted pyrazole group, and a substituent of the substituted pyrazole group may be coupled to a substituent of an adjacent phenyl group to form a condensed ring. Accordingly, the organometallic compound of an embodiment may exhibit excellent or suitable stability. The light emitting element including the organometallic compound of an embodiment with excellent or suitable material stability may exhibit long lifespan properties.

A light emitting element of an embodiment includes an organometallic compound of an embodiment, and thus, may exhibit long lifespan properties.

The organometallic compound of an embodiment may contribute to improving the lifespan of the light emitting element.

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

The light emitting device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A light emitting element comprising:
a first electrode;
a second electrode on the first electrode; and
an emission layer between the first electrode and the second electrode, and comprising an organometallic compound represented by Formula 1: 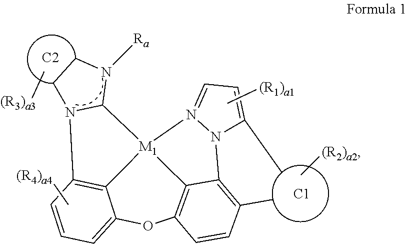
wherein in Formula 1,
M₁ is Pt or Pd,
Rₐ is a substituted or unsubstituted aryl group having 6 to 30 ring-forming carbon atoms,
C1 ring group and C2 ring group are each independently a substituted or unsubstituted aryl group having 6 to 30 ring-forming carbon atoms,
a1 is an integer from 0 to 2,
a2 and a3 are each independently an integer from 0 to 4,
a4 is an integer from 0 to 3, and
each of R₁ to R₄ is independently a hydrogen atom, a deuterium atom, a substituted or unsubstituted alkyl group having 1 to 20 carbons, a substituted or unsubstituted aryl group having 6 to 30 ring-forming carbon atoms, or a substituted or unsubstituted heteroaryl group having 2 to 30 ring-forming carbon atoms, and/or forms a ring by being coupled to an adjacent group, wherein R₁ and R₂ are coupled to each other to form a ring.

2. The light emitting element of claim 1, wherein Formula 1 is represented by Formula 1-1: 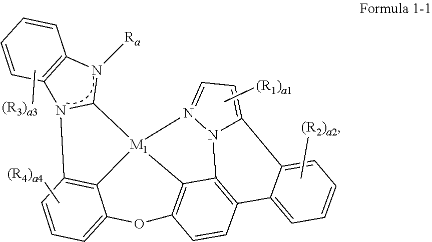
wherein in Formula 1-1, M₁, a1 to a4, R₁ to R₄, and Rₐ are the same as defined in Formula 1.

3. The light emitting element of claim 2, wherein Formula 1-1 is represented by Formula 1-1A: 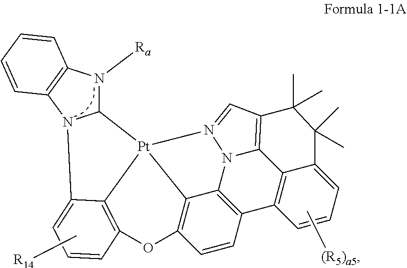
wherein in Formula 1-1A,
a5 is an integer from 0 to 3,
R₅ is a hydrogen atom, a deuterium atom, a substituted or unsubstituted alkyl group having 1 to 30 carbons, a substituted or unsubstituted aryl group having 6 to 30 ring-forming carbon atoms, or a substituted or unsubstituted heteroaryl group having 2 to 30 ring-forming carbon atoms,
R₁₄ is a hydrogen atom, a deuterium atom, or a substituted or unsubstituted alkyl group having 1 to 10 carbon atoms, and
Rₐ is the same as defined in Formula 1-1.

4. The light emitting element of claim 3, wherein in Formula 1-1A, R₅ is represented by any one selected from among R5-1 to R5-3: 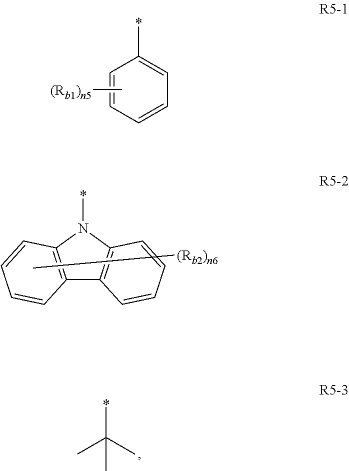
wherein:
in R5-1, n5 is an integer from 0 to 5;
in R5-2, n6 is an integer from 0 to 8; and
in R5-1 to R5-2, R_{b1} and R_{b2} are each independently a hydrogen atom, a deuterium atom, a substituted or unsubstituted alkyl group having 1 to 30 carbon atoms, or a substituted or unsubstituted aryl group having 6 to 30 ring-forming carbon atoms.

5. The light emitting element of claim 1, wherein in Formula 1, R₃ and R₄ are coupled to each other to form a ring.

6. The light emitting element of claim 1, wherein in Formula 1, Rₐ is represented by Formula RAA: 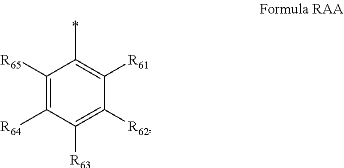
wherein in Formula RAA, R₆₁ to R₆₅ are each independently a hydrogen atom, a deuterium atom, a substituted or unsubstituted methyl group, a substituted or unsubstituted t-butyl group, or a substituted or unsubstituted phenyl group.

7. The light emitting element of claim 1, wherein the emission layer is configured to emit phosphorescent light.

8. The light emitting element of claim 1, wherein the emission layer comprises a hole transporting host, an electron transporting host, and a dopant, and wherein the dopant comprises the organometallic compound.

9. The light emitting element of claim 8, wherein the emission layer further comprises a thermally activated delayed fluorescence compound.

10. The light emitting element of claim 8, wherein the hole transporting host comprises a compound represented by Formula T-1: 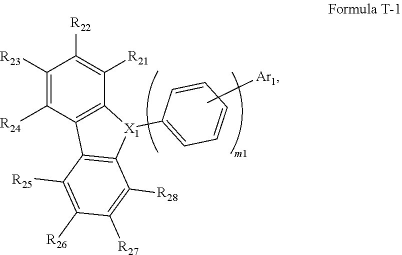
wherein in Formula T-1,
m1 is an integer from 0 to 2,
X₁ is CR₂₉ or N,
R₂₁ to R₂₉ are each independently a hydrogen atom, a deuterium atom, a substituted or unsubstituted aryl group having 6 to 60 ring-forming carbon atoms, or a substituted or unsubstituted heteroaryl group not having N as a ring-forming atom and having 2 to 60 ring-forming carbon atoms, and
Ar₁ is a substituted or unsubstituted aryl group having 6 to 60 ring-forming carbon atoms, or a substituted or unsubstituted heteroaryl group having N as a ring-forming atom and having 2 to 60 ring-forming carbon atoms.

11. The light emitting element of claim 8, wherein the electron transporting host comprises a compound represented by Formula T-2: 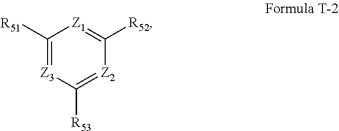
wherein in Formula T-2,
Z₁ to Z₃ are each independently CR₅₄ or N, and
each of R₅₁ to R₅₄ is independently a hydrogen atom, a deuterium atom, a cyano group, a substituted silyl group, a substituted or unsubstituted aryl group having 6 to 30 ring-forming carbon atoms, or a substituted or unsubstituted heteroaryl group having 2 to 30 ring-forming carbon atoms, and/or forms a ring by being coupled to an adjacent group.

12. The light emitting element of claim 8, wherein the hole transporting host comprises a compound of Compound Group 2:

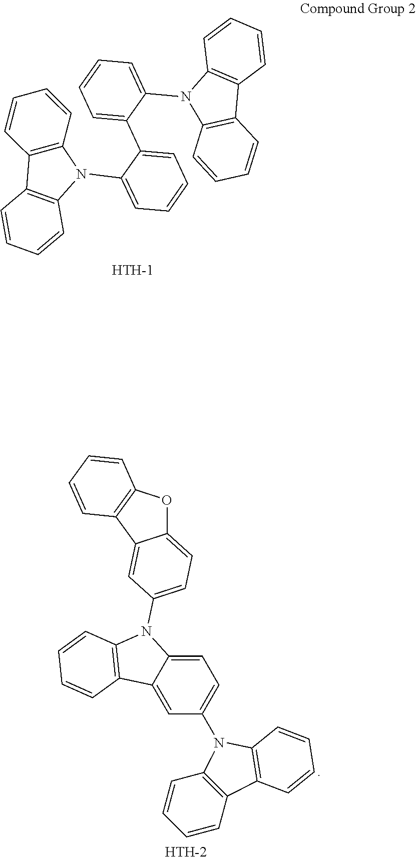

13. The light emitting element of claim 8, wherein the electron transporting host comprises a compound of Compound Group 3:

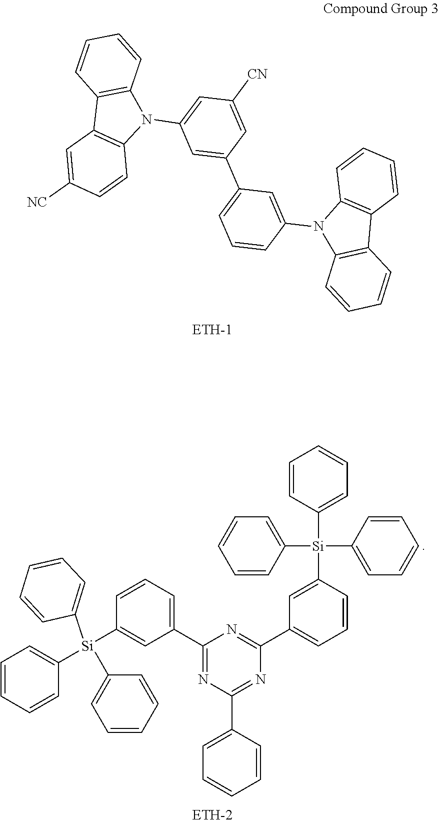 [SMILES: N#Cc1cc(-c2cccc(-n3c4ccccc4c4ccccc43)c2)cc(-n2c3ccccc3c3cc(C#N)ccc32)c1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

14. The light emitting element of claim 1, wherein the organometallic compound is represented by any one selected from among compounds of Compound Group 1: 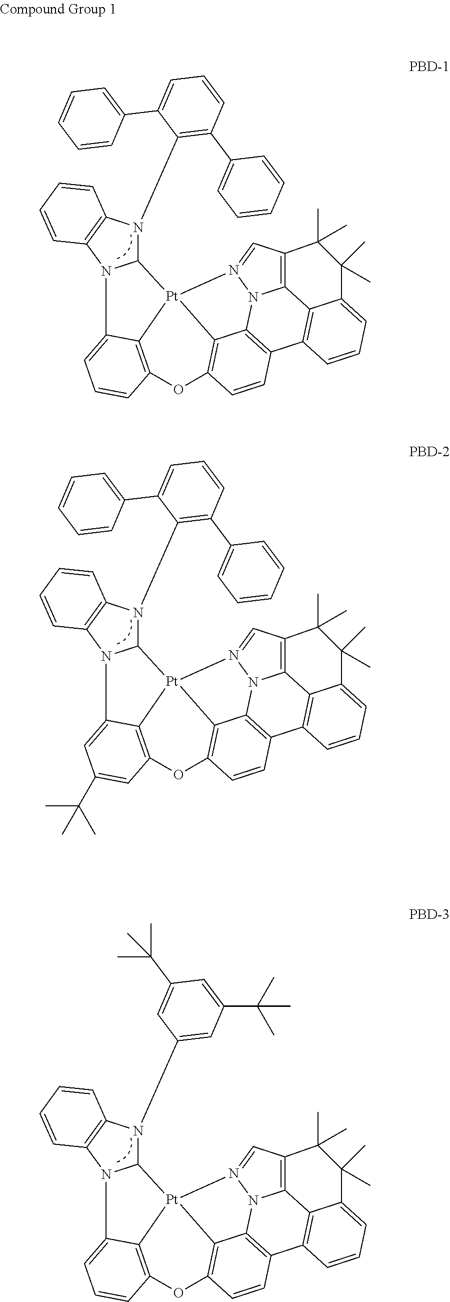 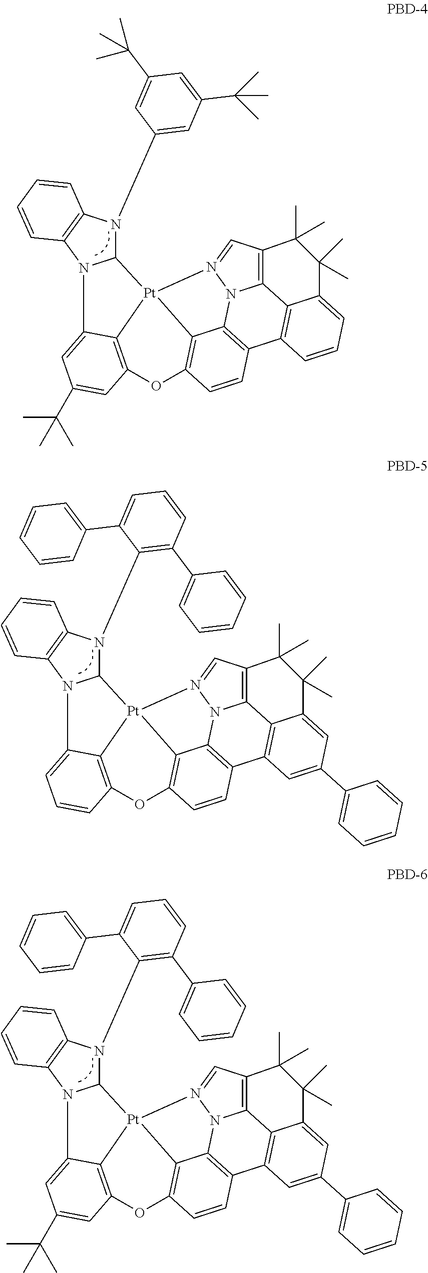 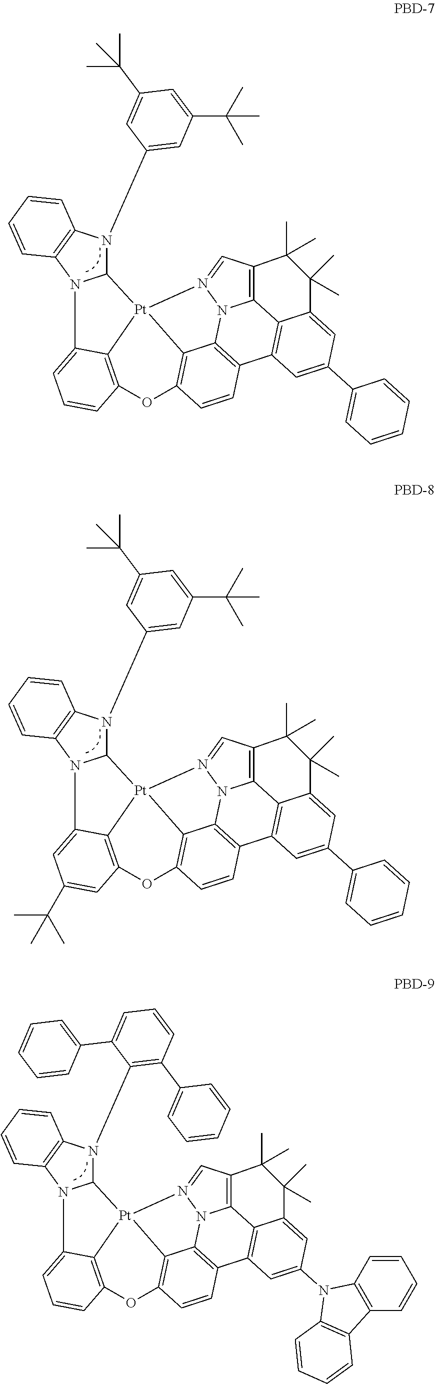 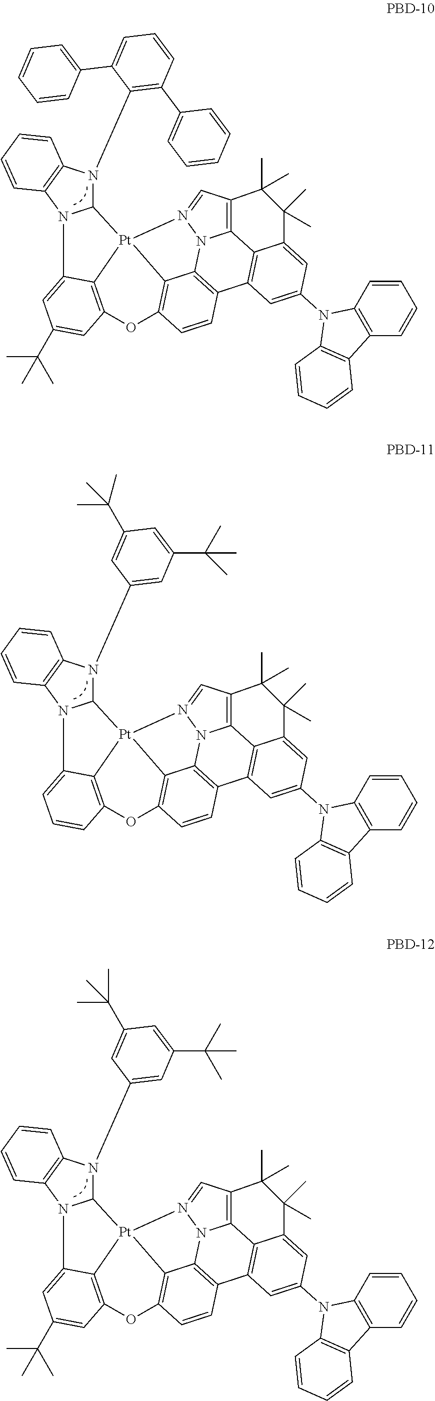 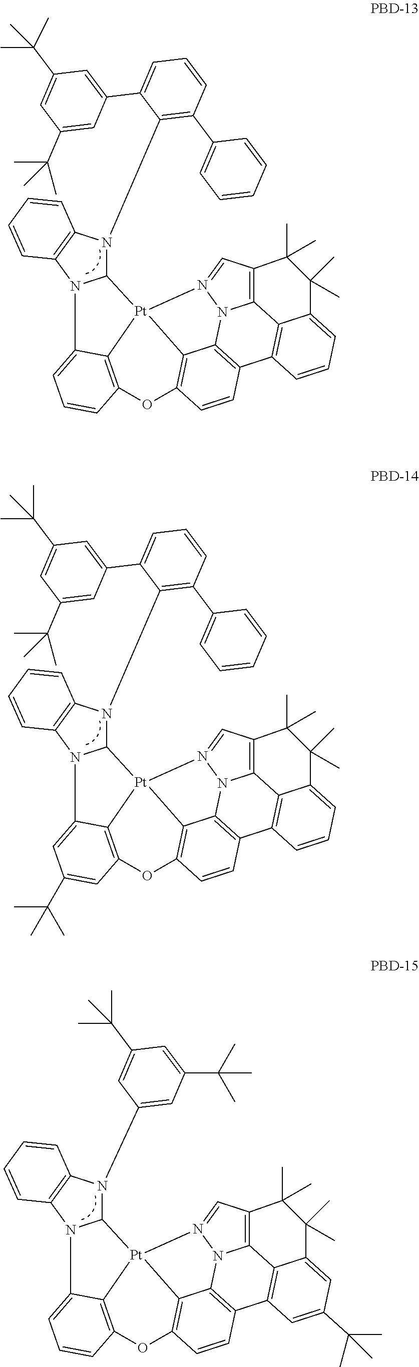 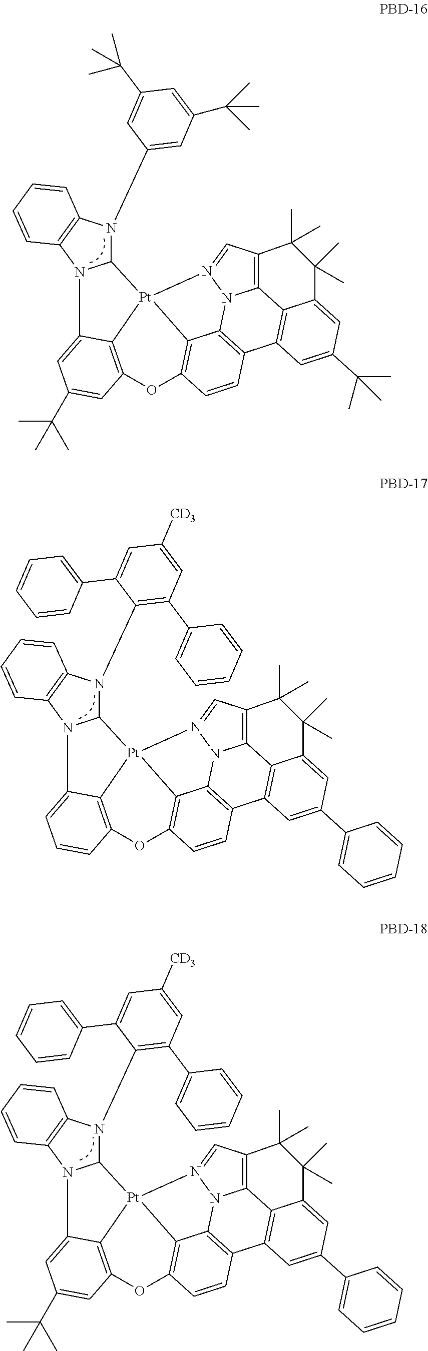 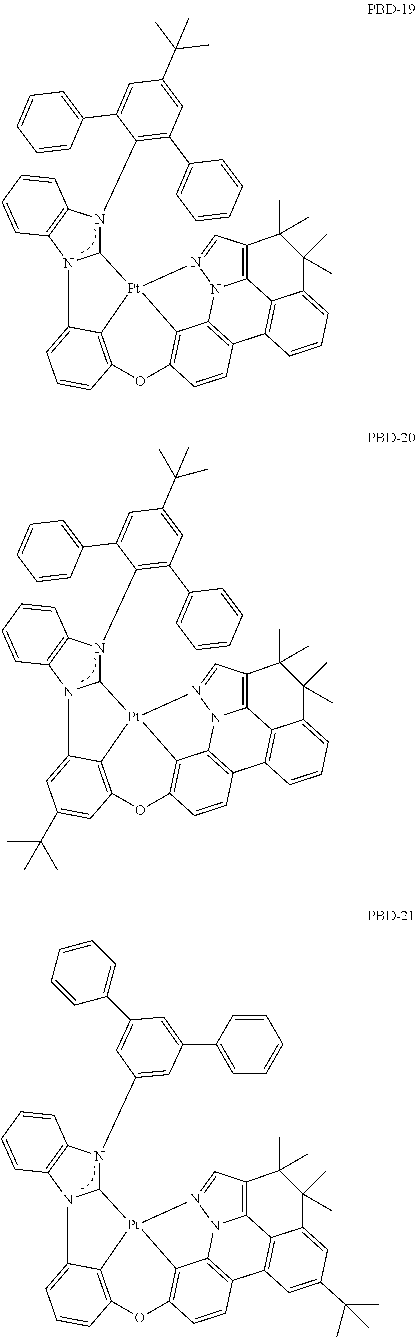 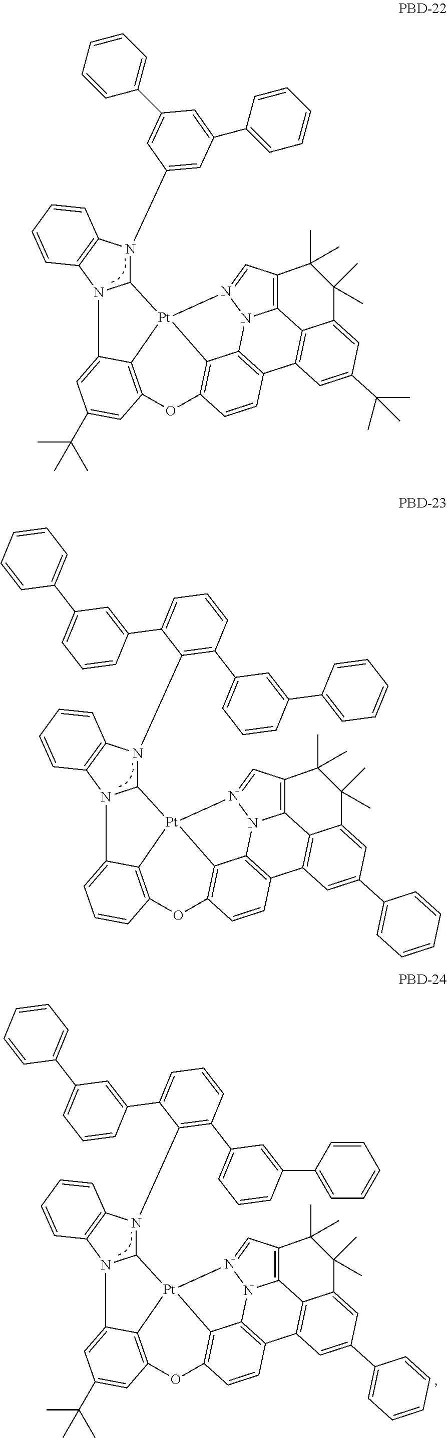
wherein in Compound Group 1, D is a deuterium atom.

15. An organometallic compound represented by Formula 1: 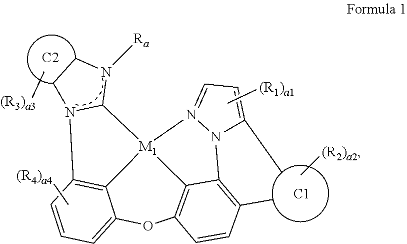
wherein in Formula 1,
M₁ is Pt or Pd,
Rₐ is a substituted or unsubstituted aryl group having 6 to 30 ring-forming carbon atoms,
C1 ring group and C2 ring group are each independently a substituted or unsubstituted aryl group having 6 to 30 ring-forming carbon atoms,
a1 is an integer from 0 to 2,
a2 and a3 are each independently an integer from 0 to 4,
a4 is an integer from 0 to 3, and
each of R₁ to R₄ is independently a hydrogen atom, a deuterium atom, a substituted or unsubstituted alkyl group having 1 to 20 carbons, a substituted or unsubstituted aryl group having 6 to 30 ring-forming carbon atoms, or a substituted or unsubstituted heteroaryl group having 2 to 30 ring-forming carbon atoms, and/or forms a ring by being coupled to an adjacent group, wherein R₁ and R₂ are coupled to each other to form a ring.

16. The light emitting element of claim 15, wherein Formula 1 is represented by Formula 1-1: 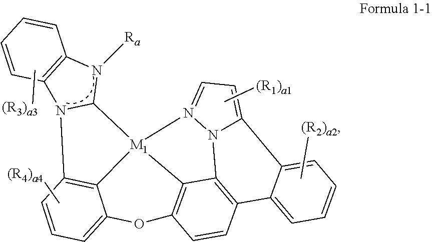
wherein in Formula 1-1, M₁, a1 to a4, R₁ to R₄, and Rₐ are the same as defined in Formula 1.

17. The light emitting element of claim 16, wherein Formula 1-1 is represented by Formula 1-1A: 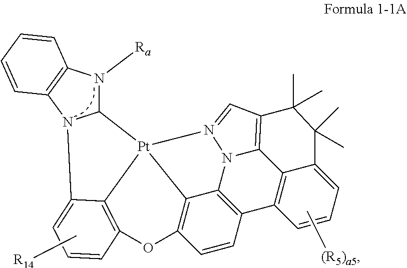
wherein in Formula 1-1A,
a5 is an integer from 0 to 3,
R₅ is a hydrogen atom, a deuterium atom, a substituted or unsubstituted alkyl group having 1 to 30 carbons, a substituted or unsubstituted aryl group having 6 to 30 ring-forming carbon atoms, or a substituted or unsubstituted heteroaryl group having 2 to 30 ring-forming carbon atoms,
R₁₄ is a hydrogen atom, a deuterium atom, or a substituted or unsubstituted alkyl group having 1 to 10 carbon atoms, and
Rₐ is the same as defined in Formula 1-1.

18. The light emitting element of claim 17, wherein in Formula 1-1A, R₅ is represented by any one selected from among R5-1 to R5-3: 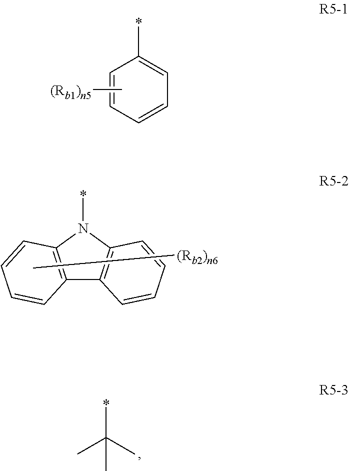
wherein:
in R5-1, n5 is an integer from 0 to 5;
in R5-2, n6 is an integer from 0 to 8; and
in R5-1 to R5-2, R_{b1} and R_{b2} are each independently a hydrogen atom, a deuterium atom, a substituted or unsubstituted alkyl group having 1 to 30 carbon atoms, or a substituted or unsubstituted aryl group having 6 to 30 ring-forming carbon atoms.

19. The light emitting element of claim 15, wherein in Formula 1, Rₐ is represented by Formula RAA: 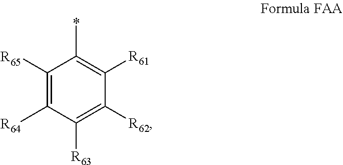
wherein in Formula RAA, R₆₁ to R₆₅ are each independently a hydrogen atom, a deuterium atom, a substituted or unsubstituted methyl group, a substituted or unsubstituted t-butyl group, or a substituted or unsubstituted phenyl group.

20. The light emitting element of claim 15, wherein Formula 1 is represented by any one selected from among compounds of Compound Group 1: 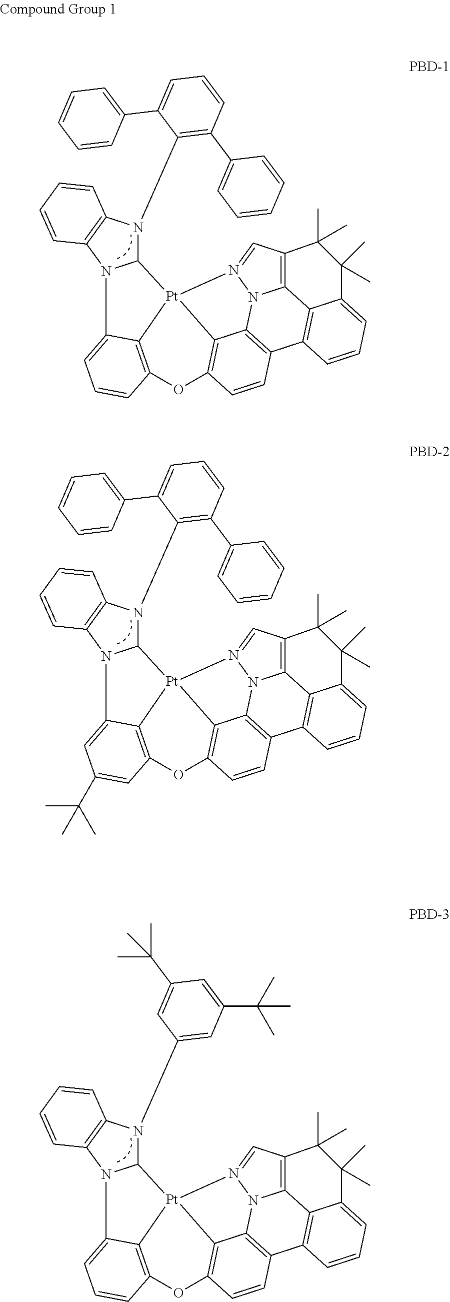 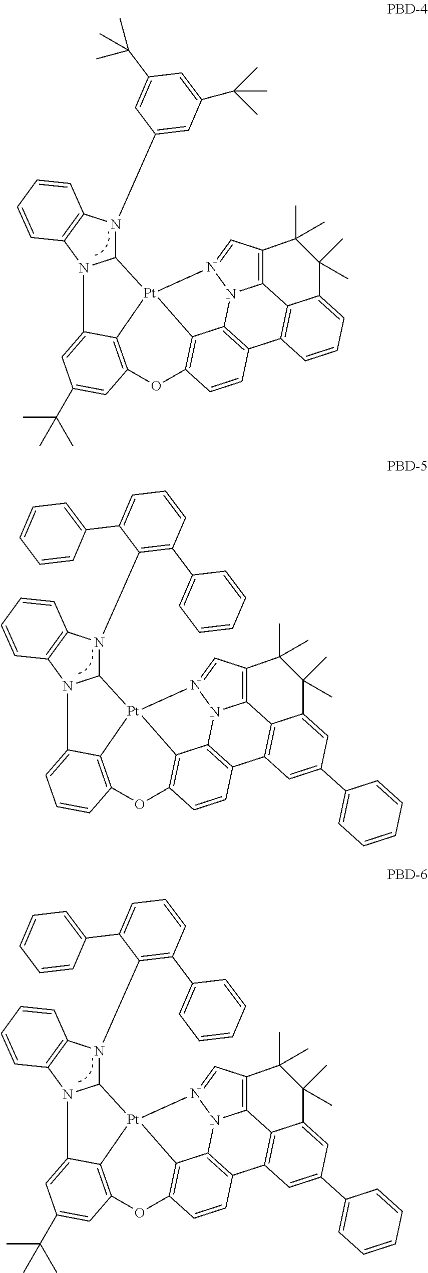 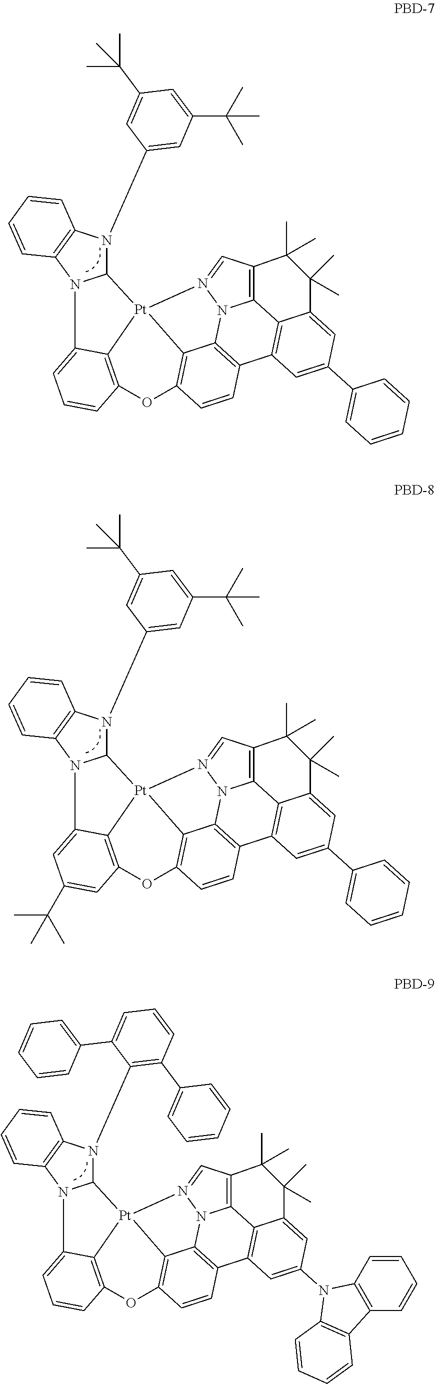 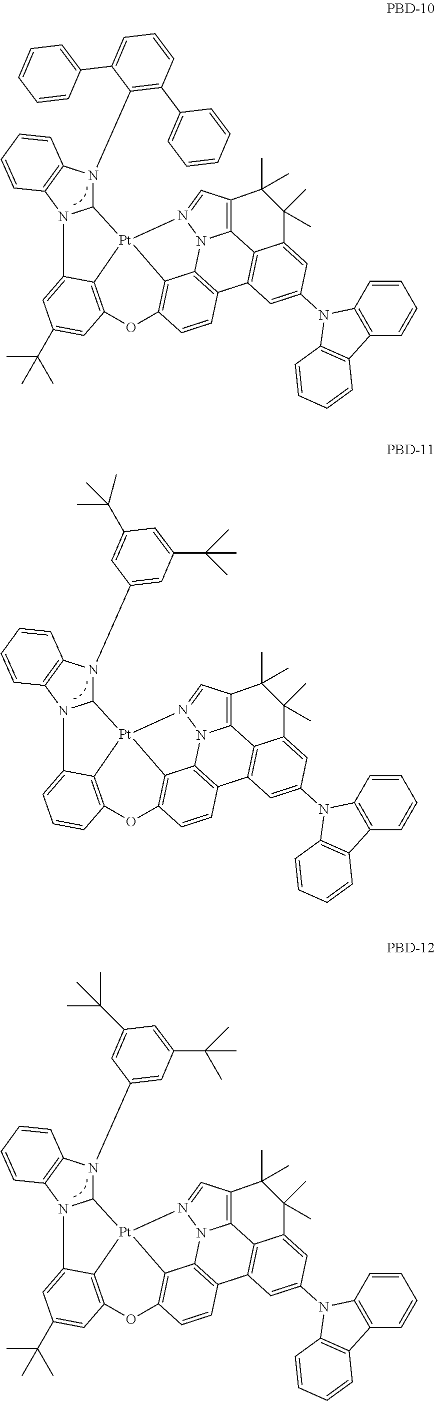 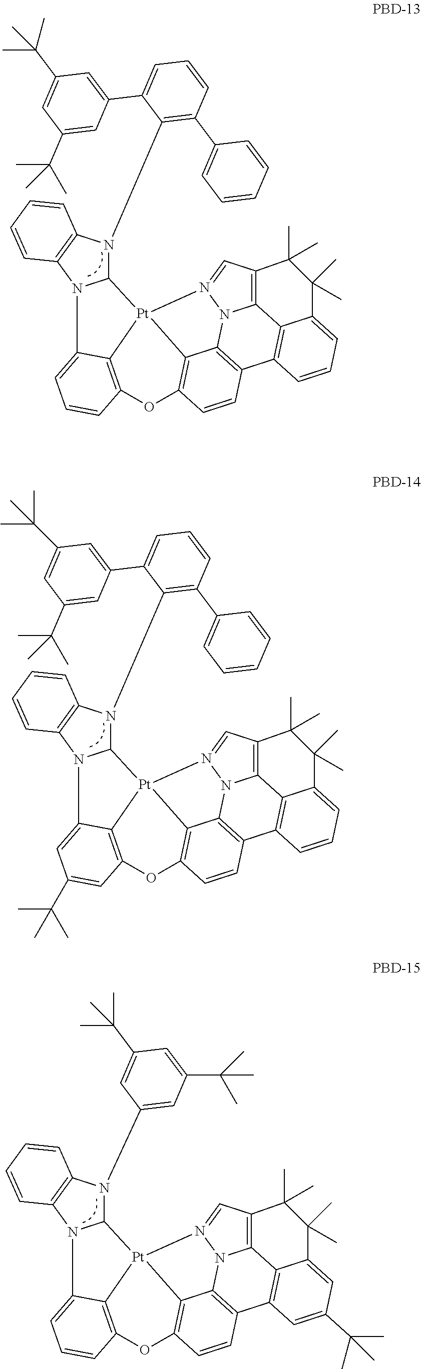 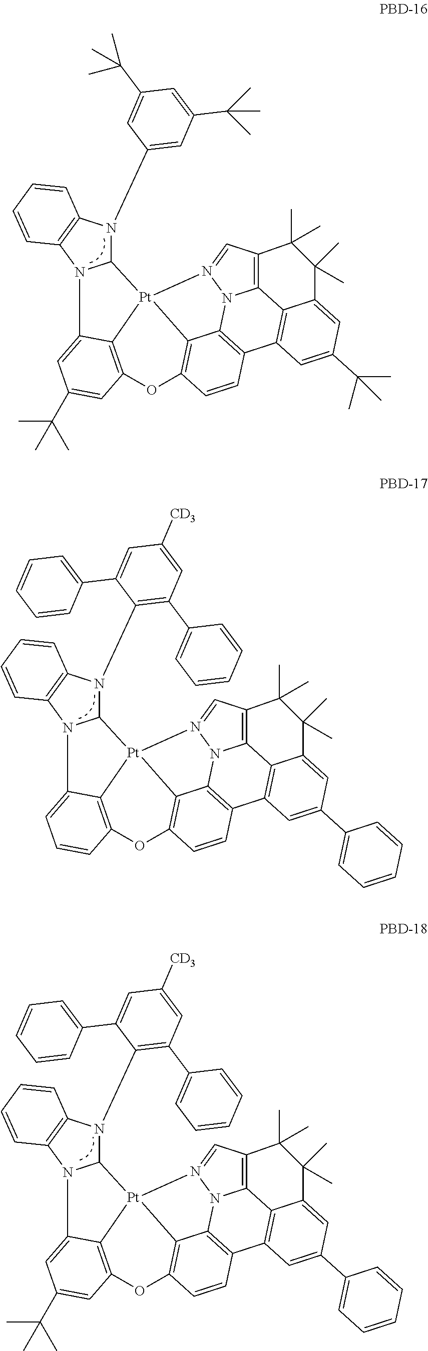 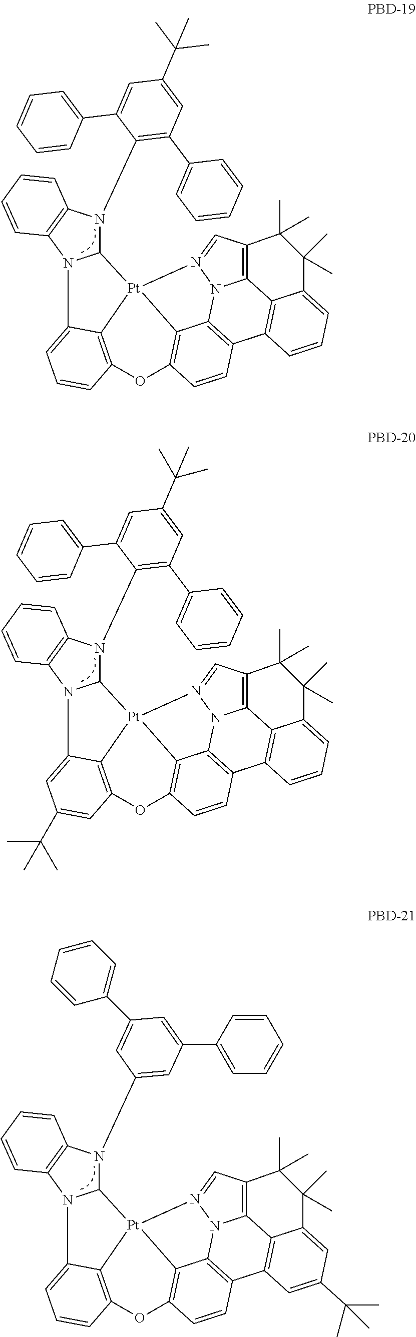 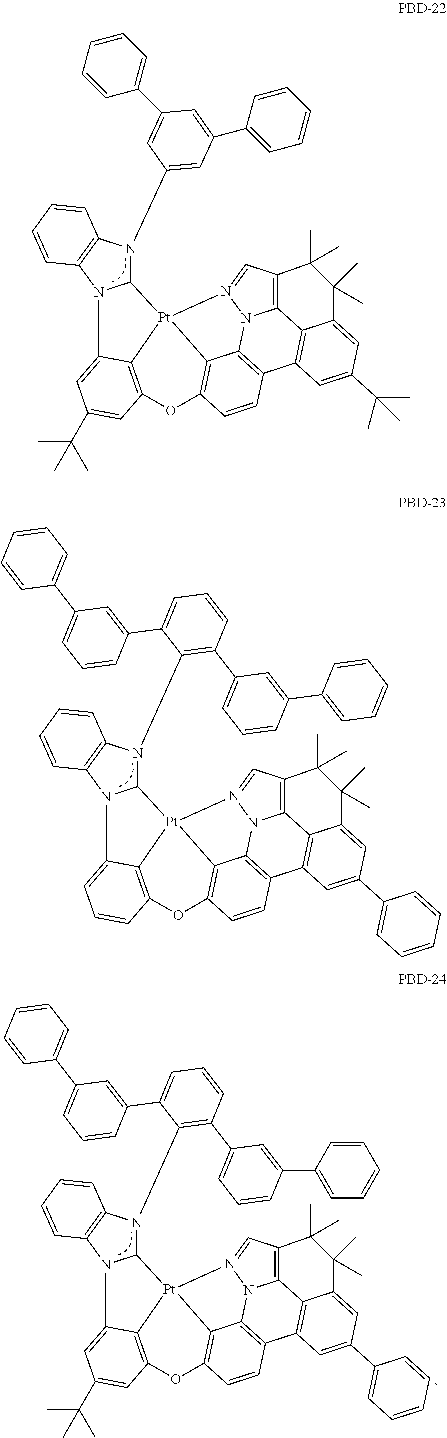
wherein in Compound Group 1, D is a deuterium atom.
